(19) United States
(12) Patent Application Publication
(10) Pub. No.: US 2026/0271499 A1
(43) Pub. Date: Sep. 10, 2026

(54) SEMICONDUCTOR NANOPARTICLE, PRODUCTION METHOD THEREOF, ELECTROLUMINESCENT DEVICE AND DISPLAY DEVICE INCLUDING THE SAME

(71) Applicants: SAMSUNG ELECTRONICS CO., LTD., Suwon-si (KR); Samsung Display Co., Ltd., Yongin-si (KR)

(72) Inventors: Hyundong HA, Suwon-si (KR); YONG SEOK HAN, Suwon-si (KR); Hogeun CHANG, Suwon-si (KR); JAEYONG LEE, Suwon-si (KR); DAEUN YOON, Suwon-si (KR); JIHYUN MIN, Suwon-si (KR); KWANGHEE KIM, Suwon-si (KR); Sungjun KOH, Suwon-si (KR)

(21) Appl. No.: 19/558,649

(22) Filed: Mar. 6, 2026

(30) Foreign Application Priority Data
Mar. 6, 2025 (KR) 10-2025-0029322

(51) Int. Cl. H10K 50/115; B82Y 20/00; B82Y 40/00

(52) U.S. Cl. CPC H10K 50/115; B82Y 20/00; B82Y 40/00

(57) ABSTRACT

A method of preparing a semiconductor nanoparticle, a semiconductor nanoparticle, an ink composition and an electroluminescent device. The method includes: providing a reaction medium including an organic solvent; adding a zinc precursor, a sulfur precursor, and a particle including a first semiconductor nanocrystal to the reaction medium; heating the reaction medium to a reaction temperature to provide the semiconductor nanoparticle; and adding a metal halide to the reaction medium including the semiconductor nanoparticle, wherein the metal halide includes an organozinc halide and an aluminum halide.

### CROSS-REFERENCE TO RELATED APPLICATION

This application claims priority to Korean Patent Application No. 10-2025-0029322 filed in the Korean Intellectual Property Office on Mar. 6, 2025, and all the benefits accruing therefrom under 35 U.S.C. § 119, the content of which in its entirety is herein incorporated by reference.

### BACKGROUND

### 1. Field

The present disclosure relates to semiconductor nanoparticles, methods of making the semiconductor nanoparticles, and a device including the semiconductor nanoparticles, including an electroluminescent device or a display device.

### 2. Description of the Related Art

A semiconductor nanoparticle (e.g., semiconductor nanocrystal particle) may emit light. For example, a quantum dot including a semiconductor nanocrystal may exhibit a quantum confinement effect, exhibiting luminous properties. Light emission of the semiconductor nanoparticle may occur, for instance, when an excited electron, either by light excitation or by application of a voltage, transitions from a conduction band to a valence band. The semiconductor nanoparticle may be configured to emit light of a desired wavelength region by controlling a size, composition, or a combination thereof.

A nanoparticle may be used in a light emitting device (e.g., an electroluminescent device) and a display device including the nanoparticle.

### SUMMARY

An embodiment provides a semiconductor nanoparticle that can exhibit an improved property (e.g., electroluminescent properties and a longer device lifetime).

An embodiment relates to a method for manufacturing the semiconductor nanoparticle.

An embodiment provides a light emitting device for example, capable of emitting light by applying a voltage to a semiconductor nanoparticle (e.g., a quantum dot).

An embodiment provides a display device (e.g., a quantum dot light emitting diode (“QD-LED”) display) including the semiconductor nanoparticle as a light emitting material in a blue pixel, a red pixel, and/or a green pixel.

In an embodiment, a method of preparing a semiconductor nanoparticle includes,
providing a reaction medium including an organic solvent;
adding a zinc precursor, a sulfur precursor, and a particle including a first semiconductor nanocrystal to the reaction medium,
heating the reaction medium to a reaction temperature to provide a semiconductor nanoparticle; and
adding e.g., with mixing, a metal halide to the reaction medium including the semiconductor nanoparticle,
wherein the metal halide includes an organozinc halide and an aluminum halide.

The reaction medium may further include an organic ligand. The first semiconductor nanocrystal may include zinc, selenium, and optionally tellurium. The first semiconductor nanocrystal may include a first zinc chalcogenide that includes zinc, selenium, and optionally tellurium.

The particle may further include a second semiconductor nanocrystal. The second semiconductor nanocrystal may include zinc and selenium (or include a second zinc chalcogenide that includes zinc and selenium).

The particle may not include an indium phosphide.

The zinc precursor may include a first zinc precursor including a first organic ligand and zinc, e.g., a zinc ion, and a second zinc precursor including a second organic ligand different from the first organic ligand and zinc. e.g., a zinc ion. The first organic ligand and the second organic ligand may include a carboxylate group.

The first organic ligand may have a molecular weight of greater than or equal to about 90 g/mol, or greater than or equal to about 100 g/mol and less than or equal to about 260 g/mol, less than or equal to about 230 g/mol, less than or equal to about 210 g/mol, less than or equal to about 205 g/mol, less than or equal to about 200 g/mol, or less than or equal to about 170 g/mol.

The second organic ligand may have a molecular weight of greater than about 200 g/mol, greater than or equal to about 225 g/mol, greater than or equal to about 250 g/mol, or greater than or equal to about 280 g/mol, and less than or equal to about 500 g/mol, or less than or equal to about 250 g/mol.

The first organic ligand may include a substituted or unsubstituted C6 to C12 aromatic hydrocarbon group, a substituted or unsubstituted C3 to C12, C5 to C9, C4 to C8, or C6 to C7 linear or branched aliphatic hydrocarbon group (e.g., an alkyl group, an alkenyl group, or an alkynyl group), or a combination thereof.

The first organic ligand may include a hexanoate moiety substituted with a C1-C3 alkyl group, a butanoate moiety substituted with a C1-C3 alkyl group, a pentanoate moiety substituted with a C1-C3 alkyl group, an octanoate moiety substituted with a C1-C4 alkyl group, or a combination thereof. The first organic ligand may include a hexanoate group, a methylbutanoate group, a butyloctanoate group, or a combination thereof.

The second organic ligand may include a linear or branched aliphatic hydrocarbon group of C13-C25, C14-C23, C15-C22, C16-C21, C17-C20, or C18-C19 (e.g., an alkyl group, an alkenyl group, or an alkynyl group). The second organic ligand may include an aliphatic hydrocarbon group of C17 or more.

The second organic ligand may, for example, include one or more, or two or more carbon-carbon double bond within the aliphatic hydrocarbon group chain.

The first organic ligand may include a branched alkyl group, and the second organic ligand may include a linear alkenyl group.

In an embodiment, the adding and the mixing of the metal halide may be carried out at a first temperature, and the first temperature may be lower than the reaction temperature. A difference between the first temperature and the reaction temperature may be greater than or equal to about 10° C. and less than or equal to about 100° C.

The first temperature may be greater than or equal to about 100° C. and less than or equal to about 280° C.

The adding of the metal halide may occur after the first zinc precursor and/or the second zinc precursor contacts or reacts with the sulfur precursor.

The organozinc halide may include a C6 to C30 aromatic moiety.

The organozinc halide may include a compound represented by Chemical formula 1:

R—Zn—X Chemical formula 1
wherein R is a substituted or unsubstituted C3 to C50 (or C5 to C20) hydrocarbon group (e.g., an aliphatic, alicyclic, or aromatic hydrocarbon group), and X is a halogen (e.g., F, Cl, Br, or I).

In Chemical formula 1, R may be substituted with a halogen, a C1 to C10 hydrocarbon group (e.g., an aliphatic hydrocarbon group such as an alkyl group, an alkenyl group, or an alkynyl group), a cyanide group, or a combination thereof.

The organozinc halide may include a substituted or unsubstituted benzylzinc halide (e.g., a chloride or a bromide), a substituted or unsubstituted phenylalkylzinc halide (e.g., a chloride or a bromide), a substituted or unsubstituted phenylalkenylzinc halide (e.g., a chloride or a bromide), a substituted or unsubstituted (e.g., linear or branched) alkylzinc halide (e.g., a chloride or a bromide), or a combination thereof.

The aluminum halide may include an aluminum chloride, an aluminum bromide, an aluminum iodide, or a combination thereof.

In the method of an embodiment, an amount of the metal halide may be greater than or equal to about 0.01 moles, greater than or equal to about 0.05 moles, greater than or equal to about 0.1 moles, greater than or equal to about 0.15 moles, greater than or equal to about 0.5 moles, greater than or equal to about 1 mole, greater than or equal to about 5 moles, greater than or equal to about 10 moles, greater than or equal to about 50 moles, or greater than or equal to about 100 moles, per 1 mole of the zinc precursor.

In the method of an embodiment, the amount of the metal halide may be less than or equal to about 100 moles, less than or equal to about 70 moles, less than or equal to about 40 moles, less than or equal to about 10 moles, less than or equal to about 3 moles, less than or equal to about 1 mole, less than or equal to about 0.4 moles, less than or equal to about 0.2 moles, less than or equal to about 0.06 moles, or less than or equal to about 0.03 moles, per 1 mole of the zinc precursor.

An amount of the aluminum halide may be greater than or equal to about 0.1 moles, or greater than or equal to about 0.5 moles and less than or equal to about 20 moles, or less than or equal to about 15 moles, per 1 mole of the organozinc halide.

In an embodiment, a semiconductor nanoparticle includes zinc, selenium, and sulfur, wherein the semiconductor nanoparticle includes a first semiconductor nanocrystal; and a semiconductor nanocrystal shell disposed on the first semiconductor nanocrystal and including zinc and sulfur, the first semiconductor nanocrystal includes zinc and selenium, the semiconductor nanoparticle does not include cadmium, the semiconductor nanoparticle further includes aluminum, and in the semiconductor nanoparticle, a mole ratio of aluminum to zinc is greater than or equal to about 0.001:1, or greater than or equal to about 0.01:1 and less than or equal to about 0.1:1, or less than or equal to about 0.05:1.

The semiconductor nanoparticle may further include an organic ligand (e.g., an organic ligand system including a plurality of organic ligands).

When identified by thermogravimetric analysis, an organic content (e.g., corresponding to a mass loss at a temperature of greater than or equal to about 200° C. and less than or equal to about 550° C.) of the semiconductor nanoparticle may be greater than or equal to about 7 wt % and less than or equal to about 10.5 wt %, based on a total weight of the semiconductor nanoparticle. The organic content may be, based on the total weight of the semiconductor nanoparticle, greater than or equal to about 7.5 wt %, or greater than or equal to about 8 wt % and less than or equal to about 10 wt %, or less than or equal to about 9.7 wt %.

In the semiconductor nanoparticle, a mole ratio of aluminum to zinc may be greater than or equal to about 0.005:1, or greater than or equal to about 0.012:1, and less than or equal to about 0.04:1.

In the semiconductor nanoparticle, a mole ratio of aluminum to selenium may be greater than or equal to about 0.001:1, or greater than or equal to about 0.005:1 and less than or equal to about 0.074:1, or less than or equal to about 0.07:1.

In the semiconductor nanoparticle, a mole ratio of aluminum to sulfur may be greater than or equal to about 0.001:1, or greater than or equal to about 0.01:1 and less than or equal to about 0.1:1.

The semiconductor nanoparticle may include a first organic ligand having a carboxylate moiety; and a second organic ligand having a carboxylate moiety and different from the first organic ligand. The semiconductor nanoparticle may exhibit, in gas chromatography (GC) analysis, a first peak assigned to the first organic ligand and a second peak assigned to the second organic ligand. An area percentage of the first peak relative to the second peak may be greater than or equal to about 1%, greater than or equal to about 5%, greater than or equal to about 10%, and less than or equal to about 300%, less than or equal to about 150%, or less than or equal to about 100%.

The second organic ligand may have a molecular weight that is greater than that of the first organic ligand. The second organic ligand may have a carbon number of greater than or equal to about 15, greater than or equal to about 16, or greater than or equal to about 17.

The semiconductor nanoparticle or the semiconductor nanocrystal shell may include a zinc selenide, a zinc selenide telluride, a zinc selenide sulfide, a zinc sulfide, or a combination thereof. The semiconductor nanocrystal shell may include a first shell layer; and a second shell layer disposed on the first shell layer. The first shell layer may include a zinc selenide, a zinc selenide telluride, a zinc selenide sulfide, or a combination thereof. The second shell layer may include a zinc selenide sulfide, a zinc sulfide, or a combination thereof.

The semiconductor nanoparticle may not include lead. The semiconductor nanoparticle may not include copper. The semiconductor nanoparticle or the first semiconductor nanocrystal may not include an indium phosphide or a Group III-V compound.

The semiconductor nanoparticle may be configured to emit first light.

The first light may exhibit a blue light spectrum. The first light may have a full width at half maximum of a peak emission wavelength of greater than or equal to about 1 nm and less than or equal to about 55 nm. A peak emission wavelength of the first light or the blue light may be greater than or equal to about 440 nm and less than or equal to about 480 nm.

The semiconductor nanoparticle may be configured to emit blue light. The blue light may have a peak emission wavelength of greater than or equal to about 440 nm, greater than or equal to about 450 nm, greater than or equal to about 460 nm, or greater than or equal to about 465 nm, and less than or equal to about 480 nm, or less than or equal to about 475 nm. In an embodiment, a peak emission wavelength of the first light or the semiconductor nanoparticle may be greater than or equal to about 500 nm, or greater than or equal to about 510 nm and less than or equal to about 580 nm, or less than or equal to about 540 nm. In an embodiment, a peak emission wavelength of the first light or the semiconductor nanoparticle may be greater than or equal to about 600 nm, or greater than or equal to about 610 nm and less than or equal to about 680 nm, or less than or equal to about 635 nm.

In a thermogravimetric analysis of the semiconductor nanoparticle, a residue content at greater than or equal to about 550° C. may be greater than or equal to about 82%, greater than or equal to about 87%, greater than or equal to about 88%, greater than or equal to about 89%, or greater than or equal to about 89% and less than or equal to about 99%, less than or equal to about 93%, or less than or equal to about 91%, based on a total weight of the semiconductor nanoparticle.

The semiconductor nanoparticle may be dispersed in a liquid vehicle including an organic solvent having a boiling point of greater than or equal to about 120° C. (or greater than or equal to about 180° C.) to form a dispersion, and may exhibit, in dynamic light scattering analysis of the dispersion, a DLS particle diameter of less than about 300 nm. The DLS particle diameter may be less than or equal to about 200 nm, less than or equal to about 100 nm, or less than or equal to about 50 nm. The DLS particle diameter may be greater than or equal to about 10 nm, or greater than or equal to about 15 nm.

The semiconductor nanoparticle may exhibit, when left standing at room temperature for 3 days in the dispersion state, a quantum efficiency retention rate of greater than or equal to about 20%, greater than or equal to about 23%, or greater than or equal to about 25%.

In an embodiment, an electroluminescent device includes a first electrode and a second electrode that are spaced apart from each other, and an emission layer disposed between the first electrode and the second electrode, wherein the emission layer includes the semiconductor nanoparticle described herein.

Details of the semiconductor nanoparticle are as described herein.

The emission layer may be configured to emit first light by application of a voltage.

Details of the first light are as described herein. In an embodiment, a (electroluminescent or photoluminescent) peak emission wavelength of the first light or the semiconductor nanoparticle may be greater than or equal to about 440 nm, or greater than or equal to about 460 nm and less than or equal to about 480 nm, or less than or equal to about 470 nm.

In an embodiment, a peak emission wavelength of the first light or the semiconductor nanoparticle may be greater than or equal to about 500 nm, or greater than or equal to about 510 nm and less than or equal to about 580 nm, or less than or equal to about 540 nm. In an embodiment, a peak emission wavelength of the first light or the semiconductor nanoparticle may be greater than or equal to about 600 nm, or greater than or equal to about 610 nm and less than or equal to about 680 nm, or less than or equal to about 635 nm.

The first electrode may be an anode, and the second electrode may be a cathode.

The electroluminescent device may further include a charge auxiliary layer between the emission layer and the first electrode, between the emission layer and the second electrode, or both.

The electroluminescent device may further include a hole auxiliary layer between the emission layer and the first electrode. The electroluminescent device may further include an electron auxiliary layer between the emission layer and the second electrode.

The charge auxiliary layer may include a hole auxiliary layer including an organic compound, an electron auxiliary layer including metal oxide fine particles, or a combination thereof.

The electroluminescent device may have a maximum luminance of greater than or equal to about 10,000 candela per square meter (cd/m²), greater than or equal to about 30,000 cd/m², or greater than or equal to about 50,000 cd/m².

The electroluminescent device may have a maximum external quantum efficiency of greater than or equal to about 9%, greater than or equal to about 10%, or greater than or equal to about 11%.

An embodiment relates to an electronic device or a display device/apparatus including the electroluminescent device.

The display device or the electronic device may include a virtual reality display device, an augmented reality display device, a portable terminal device, a monitor, a notebook computer, a television, an electronic signboard, a camera, or an automotive electronic component.

According to an embodiment, the semiconductor nanoparticle may, for example, implement improved lifetime characteristics when applied to an electroluminescent device, and may exhibit dispersion characteristics suitable for being provided as an ink composition.

### BRIEF DESCRIPTION OF THE DRAWINGS

The above and other advantages and features of this disclosure will become more apparent by describing in further detail exemplary embodiments thereof with reference to the accompanying drawings.

FIG. 1 is a schematic cross-sectional view of an embodiment of a quantum dot light emitting diode (“QD-LED”) device.

FIG. 2 is a schematic cross-sectional view of an embodiment of a QD-LED device.

FIG. 3 is a schematic cross-sectional view of an embodiment of a QD-LED device.

FIG. 4 is a schematic cross-sectional view of a QD-LED device according to an embodiment.

FIG. 5 is a schematic cross-sectional view of a light emitting device (RGB pixel) according to an embodiment.

FIG. 6 is a schematic front view of a display panel according to an embodiment.

FIG. 7 is a schematic cross-sectional view of the display panel of FIG. 6 taken along line IV-IV.

FIG. 8 shows results of infrared spectroscopic analysis of a semiconductor nanoparticle synthesized in Preparation Example 1 and a semiconductor nanoparticle synthesized in Comparative Preparation Example 1.

### DETAILED DESCRIPTION

Advantages and characteristics of this disclosure, and a method for achieving the same, will become evident referring to the following exemplary embodiments together with the attached drawings (Figures). This invention, however, may be embodied in many different forms, the invention (claims) should not be construed as being limited to the embodiments set forth herein. Rather, these embodiments are provided so that this disclosure will be thorough and complete, and will fully convey the scope of the invention and claims to those skilled in the art. Like reference numerals refer to like elements throughout.

In order to clearly explain the present disclosure, parts irrelevant to the description are omitted, and the same reference numerals are assigned to the same or similar elements throughout the specification. In the drawings, the thickness of layers, films, panels, regions, etc., are exaggerated for clarity. And in the drawings, for convenience of description, the thickness of some layers and regions are exaggerated. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In addition, it will be understood that when an element such as a layer, film, region, or substrate is referred to as being “on” another element, it may be directly on the other element or intervening elements may also be present. In contrast, when an element is referred to as being “directly on” another element, there are no intervening elements present. Also, to be disposed “on” the reference portion means to be disposed above or below the reference portion and does not necessarily mean “above”.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

It will be understood that, although the terms “first,” “second,” “third,” etc., may be used herein to describe various elements, components, regions, layers and/or sections, these elements, components, regions, layers and/or sections should not be limited by these terms. These terms are only used to distinguish one element, component, region, layer or section from another element, component, region, layer, or section. Thus, “a first element,” “component,” “region,” “layer,” or “section” discussed below could be termed a second element, component, region, layer, or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as being limited to “a” or “an.” “Or” means “and/or.”

As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

As used herein, the term “cross-sectional” means a case in which a cross-section of a given object is cut, for example, in a substantially vertical direction and is viewed laterally.

Unless otherwise defined, all terms (including technical and scientific terms) used herein have the same meaning as commonly understood by one of ordinary skill in the art to which this disclosure belongs. It will be further understood that terms, such as those defined in commonly used, e.g., non-technical, dictionaries, should be interpreted as having a meaning that is consistent with their meaning in the context of the relevant art and the present disclosure, and will not be interpreted in an idealized or overly formal sense unless expressly so defined herein.

As used herein, values of a work function, a conduction band, or a lowest unoccupied molecular orbital (LUMO) (or valence band, or highest occupied molecular orbital (HOMO)) energy level is expressed as an absolute value from a vacuum level. In addition, when the work function or the energy level is referred to be “deep,” “high” or “large,” the work function or the energy level has a large absolute value based on “0 electron volt (eV)” of the vacuum level, while when the work function or the energy level is referred to be “shallow,” “low,” or “small,” the work function or energy level has a small absolute value based on “0 electron volt (eV)” of the vacuum level. In an aspect, work function herein refers to a minimum energy required to remove an electron from e.g., a solid metal (e.g., a metal surface) to vacuum (e.g., immediately outside the solid surface).

As used herein, the term “first absorption peak” refers to a main excitonic peak appearing first from the longest wavelength region of a ultraviolet-visual (UV-Vis) absorption spectrum (i.e., appearing in the lowest energy region in the UV-Vis absorption spectrum), and the term “first absorption peak wavelength” or “wavelength of the first absorption peak” refers to the wavelength at which the first absorption peak reaches a maximum intensity.

As used herein, the average (value) may be mean or median. In an embodiment, the average (value) may be a mean value.

As used herein, the term “peak emission wavelength” is the wavelength at which a given emission spectrum of the light reaches its maximum.

As used herein, the term “Group” may refer to a group of Periodic Table.

As used herein, “Group I” refers to Group IA and Group IB, and examples may include Li, Na, K, Rb, and Cs, but are not limited thereto.

As used herein, “Group II” refers to Group IIA and Group IIB, and examples of Group II metal may be Cd, Zn, Hg, and Mg, but are not limited thereto.

As used herein, “Group III” refers to Group IIIA and Group IIIB, and examples of Group IIIA metal may be Al, In, Ga, and Tl, and examples of Group IIIB may be scandium, yttrium, or the like, but are not limited thereto.

As used herein, “Group IV” refers to Group IVA and Group IVB, and examples of a Group IVA metal may be Si, Ge, and Sn, and examples of Group IVB metal may be titanium, zirconium, hafnium, or the like, but are not limited thereto.

As used herein, “Group V” includes Group VA and includes nitrogen, phosphorus, arsenic, antimony, and bismuth, but is not limited thereto.

As used herein, “Group VI” includes Group VIA and includes sulfur, selenium, and tellurium, but is not limited thereto.

As used herein, “metal” includes a semi-metal such as Si.

As used herein, a number of carbon atoms in a group or a molecule may be referred to as a subscript (e.g., C6-50) or as C6-C50.

As used herein, when a definition is not otherwise provided, “substituted” refers to replacement of at least one hydrogen of a compound or a group with a corresponding substituent including a C1-C30 alkyl group, a C2-C30 alkenyl group, a C2-C30 alkynyl group, a C6-C30 aryl group, a C7-C30 alkylaryl group, a C1-C30 alkoxy group, a C1-C30 heteroalkyl group, a C3-C30 heteroaryl group, a C3-C30 cycloalkyl group, a C3-C15 cycloalkenyl group, a C6-C30 cycloalkynyl group, a C2-C30 heterocycloalkyl group, a halogen (—F, —Cl, —Br, or —I), a hydroxy group (—OH), a nitro group (—NO₂), a cyano group (—CN), an amino group (—NRR′ wherein R and R′ are each independently hydrogen or a C1-C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O)OR, wherein R is a C1-C6 alkyl group or a C6-C12 aryl group), a carboxyl group (—COOH) or a salt thereof (—C(═O)OM, wherein M is an organic or inorganic cation), a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), or a combination thereof.

As used herein, when a definition is not otherwise provided, “hydrocarbon” or “hydrocarbon group” refers to a compound or a group including carbon and hydrogen (e.g., alkyl, alkenyl, alkynyl, or aryl group). The hydrocarbon group may be a monovalent group or a group having a valence of greater than one formed by removal of one or more hydrogen atoms from an alkane, an alkene, an alkyne, or an arene group. In the hydrocarbon or hydrocarbon group, at least one, methylene may be replaced by an oxide moiety, a carbonyl moiety, an ester moiety, —NH—, or a combination thereof. Unless otherwise stated to the contrary, the hydrocarbon or the hydrocarbon group (alkyl, alkenyl, alkynyl, or aryl) may have 1 to 60, 2 to 32, 3 to 24, or 4 to 12 carbon atoms.

As used herein, when a definition is not otherwise provided, “alkyl” refers to a linear or branched saturated monovalent hydrocarbon group (methyl, ethyl, hexyl, etc.). In an embodiment, an alkyl group may have from 1 to 50 carbon atoms, or 1 to 18 carbon atoms, or 1 to 12 carbon atoms.

As used herein, when a definition is not otherwise provided, “alkenyl” refers to a linear or branched monovalent hydrocarbon group having a carbon-carbon double bond. In an embodiment, an alkenyl group may have from 2 to 50 carbon atoms, or 2 to 18 carbon atoms, or 2 to 12 carbon atoms.

As used herein, when a definition is not otherwise provided, “alkynyl” refers to a linear or branched monovalent hydrocarbon group having a carbon-carbon triple bond. In an embodiment, an alkynyl group may have from 2 to 50 carbon atoms, or 2 to 18 carbon atoms, or 2 to 12 carbon atoms.

As used herein, when a definition is not otherwise provided, “aryl” refers to a group having a carbocyclic aromatic system. When the aryl group includes a plurality of rings, the plurality of rings may be fused to each other. Examples include a phenyl group and a naphthyl group. In an embodiment, an aryl group may have 6 to 50 carbon atoms, or 6 to 18 carbon atoms, or 6 to 12 carbon atoms.

As used herein, when a definition is not otherwise provided, “hetero” refers to inclusion of 1 to 3 heteroatoms, e.g., N, O, P, Si, B, Se, Ge, Te, S, or a combination thereof.

As used herein, “heteroaryl” refers to an aromatic system having at least one N, O, P, Si, B, Se, Ge, Te, S, or a combination thereof as a ring forming atom. Examples of heteroaryl groups include a pyridinyl group, a pyrimidinyl group, a pyrazinyl group, a pyridazinyl group, a triazinyl group, a quinolinyl group, and an isoquinolinyl group. When the heteroaryl group includes a plurality of rings, the plurality of rings may be fused to each other. In an embodiment, the heteroaryl group may have 3 to 50 carbon atoms, or 6 to 18 carbon atoms, or 6 to 12 carbon atoms.

As used herein, when a definition is not otherwise provided, “alkoxy” refers to an alkyl group linked to oxygen (e.g., alkyl-O—) for example, a methoxy group, an ethoxy group, or a sec-butyloxy group.

The term “cycloalkyl group” as used herein refers to a monovalent monocyclic saturated hydrocarbon group. Examples thereof include a cyclopropyl group, a cyclobutyl group, a cyclopentyl group, a cyclohexyl group, and a cycloheptyl group. In an embodiment, the cycloalkyl group may have 3 to 50 carbon atoms, or 3 to 18 carbon atoms, or 3 to 12 carbon atoms.

The term “heterocycloalkyl group” as used herein refers to a monovalent monocyclic group including at least one N, O, P, Si, B, Se, Ge, Te, S, or a combination thereof as a ring-forming atom in addition to the carbon atoms that are ring-forming atoms. Examples thereof include a tetrahydrofuranyl group and a tetrahydrothiophenyl group. In an embodiment, the heterocycloalkyl group may have 2 to 50 carbon atoms, or 2 to 18 carbon atoms, or 2 to 12 carbon atoms.

The term “cycloalkenyl group” as used herein refers to a monovalent monocyclic hydrocarbon group that has at least one carbon-carbon double bond in its ring, wherein the molecular structure as a whole is non-aromatic. Examples thereof include a cyclopentenyl group, a cyclohexenyl group, and a cycloheptenyl group. In an embodiment, the cycloalkenyl group may have 3 to 50 carbon atoms, or 3 to 18 carbon atoms, or 3 to 12 carbon atoms.

The term “heterocycloalkenyl group” as used herein refers to a monovalent monocyclic group including at least one N, O, P, Si, B, Se, Ge, Te, S, or a combination thereof as a ring-forming atom, and at least one double bond in its ring, wherein the molecular structure as a whole is non-aromatic. Examples of the heterocycloalkenyl group include a 2,3-dihydrofuranyl group and a 2,3-dihydrothiophenyl group. In an embodiment, the heterocycloalkenyl group may have 2 to 50 carbon atoms, or 2 to 18 carbon atoms, or 2 to 12 carbon atoms.

The term “arylalkyl group” refers to an alkyl group substituted with an aryl group. An example of an arylalkyl group is a benzyl group (i.e., —CH₂-phenyl).

The term “alkylaryl group” refers to an aryl group substituted with an alkyl group. An example of an alkylaryl group is a tolyl group.

As used herein, when a definition is not otherwise provided, “amine” is a compound represented by NR₃, wherein each R is independently hydrogen, a C1-C12 alkyl group, a C7-C20 alkylaryl group, a C7-C20 arylalkyl group, or a C6-C18 aryl group.

As used herein, the expression “not including cadmium (or other harmful heavy metal)” means that a concentration of cadmium (or another heavy metal deemed harmful) may be less than or equal to about 100 parts per million by weight (ppmw), less than or equal to about 50 ppmw, less than or equal to about 10 ppmw, less than or equal to about 1 ppmw, less than or equal to about 0.1 ppmw, less than or equal to about 0.01 ppmw, or zero. In an embodiment, substantially no amount of cadmium (or other toxic heavy metal) may be present or, if present, an amount of cadmium (or other heavy metal) may be less than or equal to a detection limit or as an impurity level of a given analysis tool (e.g., an inductively coupled plasma atomic emission spectroscopy instrument).

Unless mentioned to the contrary, a numerical range recited herein is inclusive. Unless mentioned to the contrary, a numerical range recited herein includes any real number within the endpoints of the stated range and includes the endpoints thereof. In this specification, a numerical endpoint or an upper or lower limit value (e.g., recited either as a “greater than or equal to value” “at least value” or a “less than or equal to value” or recited with “from” or “to”) may be used to form a numerical range of a given feature. In other words, the upper and lower endpoints set forth for various numerical values may be independently combined to provide a range.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, ±5%, ±3%, or ±1% of the stated value.

As used herein, a nanoparticle is a structure having at least one region or characteristic dimension with a nanoscale dimension. In an embodiment, a dimension (or an average dimension) of the nanostructure is less than or equal to about 500 nanometers (nm), less than or equal to about 300 nm, less than or equal to about 250 nm, less than or equal to about 150 nm, less than or equal to about 100 nm, less than or equal to about 50 nm, or less than or equal to about 30 nm, and may be greater than about 0.1 nm or greater than about 1 nm. In an embodiment, the nanoparticle may have any suitable shape. The nanoparticle (e.g., a semiconductor nanoparticle or a metal oxide nanoparticle) may include a nanowire, a nanorod, a nanotube, a branched nanostructure, a nanotetrapod, a nanotripod, a nanobipod, a nanodot, a multi-pod type shape such as at least two pods, or the like and is not limited thereto. The nanoparticle may be, e.g., substantially crystalline, substantially monocrystalline, polycrystalline, (for example, at least partially) amorphous, or a combination thereof.

In an embodiment, a semiconductor nanoparticle such as a quantum dot may exhibit quantum confinement or exciton confinement. As used herein, the term “quantum dot” or “semiconductor nanostructure” is not limited in a shape thereof unless otherwise defined. A semiconductor nanoparticle or a quantum dot may have a size smaller than a Bohr excitation diameter for a bulk crystal material having an identical composition and may exhibit a quantum confinement effect. The semiconductor nanoparticle or the quantum dot may emit light corresponding to a bandgap energy thereof by controlling a size of a nanocrystal acting as an emission center.

As used herein, the term “T50” is a time (hours, h) taken until the brightness (e.g., luminance) of a given device decreases to 50% of the initial brightness (100%) as, e.g., when, the given device is started to be driven, e.g., operated, at a predetermined initial brightness (e.g., 146 nit or 650 nit). As used herein, the term “T90” is a time (h) taken until the brightness (e.g., luminance) of a given device decreases to 90% of the initial brightness (100%) as the given device is started to be driven at a predetermined initial brightness (e.g., 146 nit or 650 nit).

As used herein, the phrase “external quantum efficiency (EQE)” is a ratio of the number of photons emitted from a light-emitting diode (LED) to the number of electrons passing through the device and may be a measurement as to how efficiently a given device converts electrons to photons and allows the photons to escape. The EQE may be determined by the following equation:

EQE=(efficiency of injection)×((solid-state) quantum yield)×(efficiency of extraction)
wherein the efficiency of injection is a proportion of electrons passing through the device that are injected into the active region, the quantum yield is a proportion of all electron-hole recombinations in the active region that are radiative and produce photons, and the efficiency of extraction is a proportion of photons generated in the active region that escape from the given device.

As used herein, a maximum EQE is a greatest value of the EQE.

As used herein, a maximum luminance is the highest value of luminance for a given device.

As used herein, the phrase “quantum efficiency” may be used interchangeably with the phrase, quantum yield. In an embodiment, the quantum efficiency may be a relative quantum yield or an absolute quantum yield, for example, which may be readily measured by any suitable, e.g., commercially available, equipment. The quantum efficiency (or quantum yield) may be measured in a solution state or a solid state (in a composite). In an embodiment, “quantum yield (or quantum efficiency)” may be a ratio of photons emitted to photons absorbed, e.g., by a nanostructure or population of nanostructures. In an embodiment, the quantum efficiency may be determined by any suitable method. For example, there may be two methods for measuring the fluorescence quantum yield or efficiency: the absolute method and the relative method.

The absolute method directly obtains the quantum yield by detecting all sample fluorescence through the use of an integrating sphere. In the relative method, the fluorescence intensity of a standard sample (e.g., a standard dye) may be compared with the fluorescence intensity of an unknown sample to calculate the quantum yield of the unknown sample. Coumarin 153, Coumarin 545, Rhodamine 101 inner salt, Anthracene, and Rhodamine 6G may be used as standard dye, depending on the photoluminescence (PL) wavelengths thereof, but are not limited thereto.

As used herein, the term “dispersion” refers to a dispersion in which a dispersed phase is a solid, and a continuous medium includes a liquid or a solid different from the dispersed phase. In an embodiment, the ink composition may be in a form of a dispersion. Herein, the “dispersion” may be a colloidal dispersion in which the dispersed phase has a dimension of greater than or equal to about 1 nm, for example, greater than or equal to about 2 nm, greater than or equal to about 3 nm, or greater than or equal to about 4 nm to several micrometers (μm) or less, (e.g., less than or equal to about 2 μm, less than or equal to about 1 μm, less than or equal to about 900 nm, less than or equal to about 800 nm, less than or equal to about 700 nm, less than or equal to about 600 nm, or less than or equal to about 500 nm).

A bandgap energy of a semiconductor nanoparticle may vary with a size and a composition of a nanocrystal. For example, as a size of the semiconductor nanoparticle increases, the bandgap energy of the semiconductor nanoparticle may become smaller, e.g., narrower, and the semiconductor nanoparticle may emit light having an increased wavelength. A semiconductor nanocrystal may be used as a light-emitting material in various fields such as in, a display device, an energy device, or a bio light-emitting device.

In the light-emitting layer (or referred to as an emission layer), a quantum dot capable of exhibiting a practically applicable level of an electroluminescent property may include a harmful heavy metal such as cadmium (Cd), lead, mercury, or a combination thereof. Accordingly, it is desirable to provide a light-emitting device or a display device having a emission layer substantially free of the harmful heavy metal. In a QD-LED, satisfactory electroluminescent properties may be based on a cadmium-based (i.e., cadmium-containing) LED, and there is room for improvement in a QD-LED device using an environmentally-friendly quantum dot and, for example, emitting blue light that does not include cadmium or other harmful heavy metals.

The semiconductor nanoparticle according to an embodiment is environmentally friendly, may emit light of a desired wavelength (e.g., a blue light) with improved luminous efficiency, and may exhibit an improved stability to the external environment. The electroluminescent device according to an embodiment includes the semiconductor nanoparticle and is a self-emissive light emitting device configured to emit a desired light by applying a voltage with or without a separate light source. The light emitting device and the display device of an embodiment are desired from an environmental point of view.

Inorganic-based semiconductor nanoparticles are applied as light emitting materials in electronic devices, for example, electroluminescent devices. A semiconductor nanoparticle-based electroluminescent device (e.g., QD light emitting diodes, QD-LEDs) utilizes electroluminescence of semiconductor nanoparticles through injection and recombination of electrons and holes in semiconductor nanoparticles such as quantum dots, and thus have high applicability to various electronic devices (e.g., display devices). The semiconductor nanoparticle-based electroluminescent device does not require a separate backlight and may be provided in a thin structure. Research aimed at improving performance of electroluminescent devices by modifying semiconductor nanoparticles has also been actively conducted. Studies for providing such QD-LED devices by low-cost solution processes such as inkjet printing are also in progress.

A semiconductor nanoparticle includes a ligand, (e.g., an organic ligand) on a surface, and thus may include a relatively increased content of organics. Such an organic content included in the semiconductor nanoparticle may be identified, for example, by appropriate analytical means such as thermogravimetric analysis. A surface ligand with the relatively increased amount may provide dispersibility of semiconductor nanoparticles in solution processes. Nevertheless, the present inventors have found that, such ligands present on a surface of the semiconductor nanoparticle may hinder charge injection during driving of an electroluminescent device and thus may be disadvantageous in terms of device performance (efficiency and lifetime). In order to control the amount of organic material (organic content), introduction of an inorganic ligand may be considered. However, the present inventors have also found that it is not easy to introduce an inorganic ligand into semiconductor nanoparticles in a desired amount.

The present inventors have also found that the semiconductor nanoparticle obtained by reacting synthesized semiconductor nanoparticle including an organic ligand with an inorganic ligand (e.g., a zinc chloride) at a predetermined temperature may exhibit a controlled ligand composition (e.g., a mixture of inorganic ligands and organic ligands), but a light emitting device including the same may suffer difficulty in achieving a desired level of improvement in properties, for example, lifetime characteristics.

The present inventors have found that a prepared semiconductor nanoparticle may not exhibit desired dispersion characteristics with respect to a subsequent process, for example, a liquid vehicle for an inkjet process (e.g., a predetermined organic solvent having a boiling point of greater than or equal to about 120° C., or greater than or equal to about 180° C., such as an organic solvent including cyclohexyl benzene).

According to an embodiment, a semiconductor nanoparticle prepared according to the method described herein may exhibit a ligand composition different from that obtained in the related art, and therefore may exhibit novel properties not previously described or associated with semiconductor nanoparticle in the art. Such a semiconductor nanoparticle, when included in a light emitting device, for example, an electroluminescent device, may contribute to improvement of a lifetime characteristic of the device.

In an embodiment, a method of preparing a semiconductor nanoparticle includes,
providing a reaction medium including an organic solvent;
adding a zinc precursor, a sulfur precursor, and a particle including a first semiconductor nanocrystal to the reaction medium;
heating the reaction medium to a reaction temperature to provide or obtain a semiconductor nanoparticle; and
adding, e.g., with mixing, a metal halide to the reaction medium including the semiconductor nanoparticle.

The metal halide includes an organozinc halide and an aluminum halide. The adding and mixing of the metal halide may be carried out at a first temperature. The first temperature may be greater than or equal to about 100° C. and less than or equal to about 280° C.

The method of an embodiment may synthesize a semiconductor nanocrystal having a size of several nanometers through a wet chemical process. In the wet chemical process, precursor materials are reacted in an organic solvent to grow crystal particles, and an organic solvent or a ligand compound coordinates to a surface of the semiconductor nanocrystal to control growth of the crystal.

In an embodiment, the method of preparing the semiconductor nanoparticle includes preparing a particle including a first semiconductor nanocrystal and, optionally, a second semiconductor nanocrystal.

With respect to the first semiconductor nanocrystal and the second semiconductor nanocrystal, reference may be made to what is described herein. In an embodiment, the first semiconductor nanocrystal may include a metal including indium, zinc, or a combination thereof, and a nonmetal including phosphorus, selenium, tellurium, sulfur, or a combination thereof. The first semiconductor nanocrystal may include InP, InZnP, ZnSe, ZnSeS, ZnSeTe, or a combination thereof. The first semiconductor nanocrystal may include zinc and selenium and, optionally, may further include tellurium (including a first chalcogenide). The first semiconductor nanocrystal may include ZnTeₓSe₁₋ₓ, wherein x is greater than about 0, greater than or equal to about 0.001, greater than or equal to about 0.003, greater than or equal to about 0.005, greater than or equal to about 0.007, greater than or equal to about 0.009, greater than or equal to about 0.01, greater than or equal to about 0.03, greater than or equal to about 0.05, or greater than or equal to about 0.09, and less than or equal to about 0.1, less than or equal to about 0.05, less than or equal to about 0.04, less than or equal to about 0.03, less than or equal to about 0.02, less than or equal to about 0.01, or less than or equal to about 0.008. In embodiments, the semiconductor nanoparticle may have a core-shell structure, and the core-shell structure may include a first semiconductor nanocrystal and a semiconductor nanocrystal shell (e.g., a second semiconductor nanocrystal) disposed on the first semiconductor nanocrystal. The core (e.g., the first semiconductor nanocrystal) may further include sulfur or may not include sulfur.

The first semiconductor nanocrystal or the core may not include a Group III-V compound. The first semiconductor nanocrystal or the core may not include indium phosphide, indium zinc phosphide, or a combination thereof.

In an embodiment, the second semiconductor nanocrystal may include a metal including indium, zinc, or a combination thereof, and a nonmetal element including phosphorus, selenium, tellurium, sulfur, or a combination thereof. The second semiconductor nanocrystal may include ZnSe, ZnSeS, ZnS, ZnTeSe, or a combination thereof. In an embodiment, when present, the second semiconductor nanocrystal may include zinc and selenium (e.g., ZnSe, ZnSeS, or a combination thereof). The second semiconductor nanocrystal may be disposed on the first semiconductor nanocrystal (or a core including the same). The second semiconductor nanocrystal may be an intermediate shell layer of the semiconductor nanoparticle.

In the method of an embodiment, preparation of the particle including the first semiconductor nanocrystal and, optionally, the second semiconductor nanocrystal is not particularly limited and may be appropriately selected.

In an embodiment, the first semiconductor nanocrystal or the core including the first semiconductor nanocrystal may include a zinc chalcogenide including zinc, selenium, and tellurium, and the first semiconductor nanocrystal or the core may be obtained by preparing a zinc precursor solution including a zinc precursor and an organic ligand; preparing a selenium precursor and a tellurium precursor; heating the zinc precursor solution to a core formation reaction temperature; and adding the selenium precursor and the tellurium precursor, optionally together with an organic ligand, and proceeding a core formation reaction.

In an embodiment, the first semiconductor nanocrystal or a core including the first semiconductor nanocrystal may be formed by a hot injection method in which a solution including a metal precursor such as an indium precursor and optionally a ligand is heated to a high temperature (e.g., to a temperature of greater than or equal to about 200° C.) and a phosphorus precursor is injected. In an embodiment, the core may be produced by a heating up method in which a phosphorus precursor is injected at a predetermined temperature and the temperature of the reaction system is raised.

In the core formation reaction, a ratio between the precursors (e.g., the molar ratio of selenium precursor to tellurium precursor) or the reaction time may be appropriately selected considering the emission wavelength of the final semiconductor nanoparticle, the reactivity of the precursors, and the reaction temperature. The core formation reaction temperature may be appropriately selected. The core formation reaction temperature may be greater than or equal to about 240° C., greater than or equal to about 250° C., greater than or equal to about 260° C., greater than or equal to about 270° C., or greater than or equal to about 280° C., for example, greater than or equal to about 290° C. The reaction temperature for core formation may be in the range of about 280° C. to about 340° C., for example, about 290° C. to about 330° C., or about 300° C. to about 320° C. The reaction time for core formation may be adjusted considering the desired core size and the reactivity of the precursors and is not particularly limited. For example, the reaction time may be greater than or equal to about 5 minutes, greater than or equal to about 30 minutes, or greater than or equal to about 50 minutes, but is not limited thereto. For example, the reaction time may be less than or equal to about 2 hours, but is not limited thereto. The formed core may be separated from the reaction system (e.g., by nonsolvent precipitation) or may not be separated. The separated core may be washed, if desired, and added to subsequent reactions.

The semiconductor nanoparticle of an embodiment may further include a second semiconductor nanocrystal or an intermediate shell layer including the second semiconductor nanocrystal, and the method of forming the second semiconductor nanocrystal or the intermediate shell layer including the second semiconductor nanocrystal is not particularly limited and may be appropriately selected.

In an embodiment of the method, the forming of the second semiconductor nanocrystal (or intermediate shell layer including the same) on the first semiconductor nanocrystal may include mixing (reacting) a zinc precursor with a chalcogen precursor (e.g., a selenium precursor and optionally a sulfur precursor) in the presence of an organic solvent and the first semiconductor nanocrystal at a reaction temperature.

The organic ligand, the organic solvent, and the precursors are not particularly limited and may be appropriately selected.

The organic solvent may include a C6-C22 primary amine such as a hexadecylamine, a C6-C22 secondary amine such as dioctylamine, a C6-C40 tertiary amine such as a trioctyl amine, a nitrogen-containing heterocyclic compound such as pyridine, a C6-C40 olefin such as octadecene, a C6-C40 aliphatic hydrocarbon such as hexadecane, octadecane, or squalane, an aromatic hydrocarbon substituted with a C6-C30 alkyl group such as phenyldodecane, phenyltetradecane, or phenyl hexadecane, a primary, secondary, or tertiary phosphine (e.g., trioctyl phosphine) substituted with at least one (e.g., 1, 2, or 3) C6-C22 alkyl group, a phosphine oxide (e.g. trioctylphosphine oxide) substituted with a (e.g., 1, 2, or 3) C6-C22 alkyl group, a C12-C22 aromatic ether such as phenyl ether or benzyl ether, or a combination thereof.

The organic ligand may coordinate the surfaces of the prepared semiconductor nanoparticles and allow the semiconductor nanoparticles to be well dispersed in the solution. The organic ligand may include RCOOH, RNH₂, R₂NH, R₃N, RSH, RH₂PO, R₂HPO, R₃PO, RH₂P, R₂HP, R₃P, ROH, RCOOR′, RPO(OH)₂, R₂POOH (wherein R and R′ independently include substituted or unsubstituted C1 or more, C6 or more, or C10 or more and C40 or less, C35 or less, or C25 or less aliphatic hydrocarbon group, or substituted or unsubstituted C6-C40 aromatic hydrocarbon group, or a combination thereof), or a combination thereof. The ligands may be used alone or as a combination of two or more compounds.

A type of the indium precursor is not particularly limited and may be selected appropriately. The indium precursor may include an indium powder, an alkylated indium compound, an indium alkoxide, an indium carboxylate, an indium nitrate, an indium perchlorate, an indium sulfate, an indium acetylacetonate, an indium halide, an indium cyanide, an indium hydroxide, an indium oxide, an indium peroxide, an indium carbonate, an indium acetate, or a combination thereof. The indium precursor may include an indium carboxylate such as indium oleate and indium myristate, an indium acetate, an indium hydroxide, an indium chloride, an indium bromide, an indium iodide, or a combination thereof.

A type of a phosphorus precursor is not particularly limited and may be appropriately selected. The phosphorus precursor may include tris(trimethylsilyl) phosphine, tris(dimethylamino) phosphine, triethylphosphine, tributylphosphine, trioctylphosphine, triphenylphosphine, tricyclohexylphosphine, dimethylaminophosphine, diethylaminophosphine, or a combination thereof.

Examples of the organic ligand may include methane thiol, ethane thiol, propane thiol, butane thiol, pentane thiol, hexane thiol, heptane thiol, octane thiol, nonanethiol, decanethiol, dodecane thiol, hexadecane thiol, octadecane thiol, benzyl thiol; methyl amine, ethyl amine, propyl amine, butyl amine, pentyl amine, hexyl amine, octyl amine, dodecyl amine, hexadecyl amine, octadecyl amine, dimethyl amine, diethyl amine, dipropyl amine; methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid; substituted or unsubstituted methyl phosphine (e.g., trimethyl phosphine, methyldiphenyl phosphine, or the like), substituted or unsubstituted ethyl phosphine (e.g., triethyl phosphine, ethyldiphenyl phosphine, or the like), substituted or unsubstituted propyl phosphine, substituted or unsubstituted butyl phosphine, substituted or unsubstituted pentyl phosphine, substituted or unsubstituted octylphosphine (e.g., trioctylphosphine (TOP)), or the like; a phosphine oxide such as substituted or unsubstituted methyl phosphine oxide (e.g., trimethyl phosphine oxide, methyldiphenylphosphine oxide, or the like), substituted or unsubstituted ethyl phosphine oxide (e.g., triethyl phosphine oxide, ethyldiphenyl phosphine oxide, or the like), substituted or unsubstituted propyl phosphine oxide, substituted or unsubstituted butyl phosphine oxide, substituted or unsubstituted octylphosphine oxide (e.g., trioctylphosphine oxide (TOPO), or the like); diphenyl phosphine, a triphenyl phosphine, or an oxide compound thereof; a C5-C20 alkylphosphinic acid such as hexylphosphinic acid, octylphosphinic acid, dodecanephosphinic acid, tetradecanephosphinic acid, hexadecanephosphinic acid, or octadecanephosphinic acid; a C5-C20 alkyl phosphonic acid; or the like, but embodiments are not limited thereto. The organic ligand may be used alone or as a combination of two or more.

The zinc precursor may be a Zn metal powder, ZnO, an alkylated Zn compound (e.g., a C2-C30 dialkyl zinc such as diethyl zinc), a Zn alkoxide (e.g., a zinc ethoxide), a Zn carboxylate (e.g., a zinc acetate), a Zn nitrate, a Zn perchlorate, a Zn sulfate, Zn acetylacetonate, a Zn halide (e.g., a zinc chloride), a Zn cyanide, a Zn hydroxide, a Zn carbonate, a Zn peroxide, or a combination thereof. Examples of the zinc precursor may be dimethyl zinc, diethyl zinc, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, or a combination thereof.

The selenium precursor may include selenium-trioctylphosphine (“Se-TOP”), selenium-tributylphosphine (“Se-TBP”), selenium-triphenylphosphine (“Se-TPP”), selenium-diphenylphosphine (“Se-DPP”), or a combination thereof, but is not limited thereto.

The tellurium precursor may include tellurium-tributylphosphine (“Te-TBP”), tellurium-triphenylphosphine (“Te-TPP”), tellurium-diphenylphosphine (“Te-DPP”), or a combination thereof, but is not limited thereto.

The sulfur precursor may be hexane thiol, octane thiol, decane thiol, dodecane thiol, hexadecane thiol, mercapto propyl silane, sulfur-trioctylphosphine (“S-TOP”), sulfur-tributylphosphine (“S-TBP”), sulfur-triphenylphosphine (“S-TPP”), sulfur-trioctylamine (“S-TOA”), a bis(trialkylsilyl) sulfide, a bis(trialkylsilylalkyl) sulfide e.g., bis(trimethylsilylmethyl) sulfide, ammonium sulfide, sodium sulfide, or a combination thereof.

The particle including a first semiconductor nanocrystal and, optionally, a second semiconductor nanocrystal may be separated and washed in a manner described herein prior to being subjected to a subsequent reaction (e.g., a formation reaction of a semiconductor nanocrystal shell containing zinc and sulfur). The separated and washed particle may be dispersed in an appropriate organic solvent (e.g., an aromatic solvent such as toluene or an aliphatic hydrocarbon solvent such as octane) and added to a subsequent reaction.

In the method of an embodiment, in the presence of the particle including the first semiconductor nanocrystal and, optionally, the second semiconductor nanocrystal, a zinc precursor (e.g., a zinc carboxylate) and a sulfur precursor are contacted (e.g., reacted), for example, at a reaction temperature for a predetermined time, in a reaction medium including an organic solvent, and by the reaction, a shell layer (a semiconductor nanocrystal shell layer) including zinc and sulfur may be formed on the particle. The sulfur precursor used for formation of the ZnS shell layer is as described herein. In an embodiment, the sulfur precursor may include a thiol compound (e.g., a monothiol compound having an alkyl group of C1-C30, C5-C24, or C8-C12, such as dodecanethiol).

In the semiconductor nanocrystal shell, the conventional synthesis method for providing a zinc sulfide-based shell layer (e.g., an outermost shell layer) have utilized a zinc carboxylate (e.g., zinc oleate) having a relatively long organic chain. The present inventors have found that such a long-chain zinc carboxylate has a relatively slow reaction rate, making it difficult to provide a desired quality (uniform) ZnS shell. Additionally, a long-chain carboxylate derived from the zinc precursor may be included as a long-chain ligand on the surface of a resulting semiconductor nanoparticle, which may not have an adverse effect the luminescence efficiency in solution state or photoluminescent type devices, but can act as an insulator in a electroluminescent device to hinder charge injection and to cause device performance degradation. For reducing the organic content, it is possible to consider modifying a surface of the semiconductor nanoparticle with a metal halide (e.g., zinc chloride). However, the inventors have found that a resulting semiconductor nanoparticle obtained from such a modification may not exhibit a desired level of dispersibility in an organic solvent, and thus there has still remained technical difficulties in forming a emission layer of an electroluminescent device via a solution process.

Surprisingly, the inventors have found that the semiconductor nanoparticle produced by the method described herein, in forming the shell layer including zinc and sulfur, can exhibit a desired dispersibility for a subsequent emission layer formation process and the emission layer including the semiconductor nanoparticle can contribute to an improved property and a prolonged lifespan for a resulting electroluminescent device.

In an embodiment, the zinc precursor (a zinc carboxylate) may include a first zinc precursor (e.g., a first zinc carboxylate) including a first organic ligand and zinc, e.g., a zinc ion, and a second zinc precursor (e.g., a second zinc carboxylate) including a second organic ligand and zinc, e.g., a zinc ion. For example, in forming a semiconductor nanocrystal shell (or an outermost shell layer) including a zinc sulfide, a zinc precursor having a relatively low acid dissociation constant pKa (e.g., less than or equal to about 8, or less than or equal to about 7.5), for example, a zinc precursor (e.g., the first zinc precursor) having a carboxylate moiety derived from a carboxylic acid, may be used in combination with a zinc precursor (the second zinc precursor) including a carboxylate moiety derived from a carboxylic acid having a relatively high acid dissociation constant pKa (e.g., greater than or equal to about 8.8, or greater than or equal to about 9 and less than or equal to about 12).

A zinc precursor having a long-chain carboxylate (e.g., the second zinc precursor) may exhibit a significant difference in pKa from the first zinc precursor. Such a combination of zinc precursors (i.e., the first and the second zinc precursors) may not only contribute to uniform growth of the ZnS shell layer, but also optimize a total organic content of a ligand system disposed at the outermost layer of the semiconductor nanoparticle. The semiconductor nanoparticle thus prepared may contribute to lifetime extension by preventing device degradation as well as providing an electroluminescent device to exhibit improved electroluminescent properties.

According to an embodiment, by combining the first and second zinc precursors during synthesis of a semiconductor nanoparticle, it is possible to provide a high-quality shell coating at a desired coating rate and to provide a semiconductor nanoparticle having an optimized ligand composition. Without wishing to be bound by any theory, in an embodiment, combined use of the first zinc precursor and the second zinc precursor is considered to allow a shelling reaction rate to be controlled within a desired range and to reduce lattice strain at a growth interface of the semiconductor nanocrystal shell.

In an embodiment, the combined use of the first zinc precursor and the second zinc precursor may contribute to suppressing aggregation of particles that may be caused by an addition of a metal halide. The semiconductor nanoparticle thus prepared may include a ligand system as described and may implement dispersion characteristics required for solution preparation processes such as an inkjet process as well as possibly minimizing negative effects on electroluminescent properties and device lifetime.

The first zinc precursor may include zinc, e.g., a zinc ion, and a first organic ligand having a carboxylate moiety, and may be obtained by a reaction between a carboxylic acid corresponding to the first organic ligand (hereinafter, a first carboxylic acid) and an appropriate zinc compound (e.g., a zinc acetate). The second zinc precursor may include zinc, e.g., a zinc ion, and a second organic ligand having a carboxylate moiety and being different from the first organic ligand. The latter of which may be obtained by a reaction between a carboxylic acid corresponding to the second organic ligand (hereinafter, a second carboxylic acid) and an appropriate zinc compound (e.g., zinc acetate). The appropriate zinc compound may include zinc precursors exemplified for the core and the ZnSe formation.

A molecular weight (or a carbon number) of the second organic ligand may be greater than that of the first organic ligand.

The first organic ligand may have a molecular weight of greater than or equal to about 90 g/mol, greater than or equal to about 100 g/mol, greater than or equal to about 105 g/mol, greater than or equal to about 110 g/mol, greater than or equal to about 115 g/mol, greater than or equal to about 120 g/mol, greater than or equal to about 125 g/mol, greater than or equal to about 130 g/mol, greater than or equal to about 140 g/mol, greater than or equal to about 150 g/mol, greater than or equal to about 160 g/mol, greater than or equal to about 170 g/mol, greater than or equal to about 180 g/mol, greater than or equal to about 190 g/mol, or greater than or equal to about 200 g/mol. The first organic ligand may have a molecular weight of less than or equal to about 257 g/mol, less than or equal to about 230 g/mol, less than or equal to about 225 g/mol, less than or equal to about 220 g/mol, less than or equal to about 215 g/mol, less than or equal to about 210 g/mol, less than or equal to about 200 g/mol, less than or equal to about 190 g/mol, less than or equal to about 180 g/mol, less than or equal to about 170 g/mol, less than or equal to about 160 g/mol, less than or equal to about 155 g/mol, less than or equal to about 150 g/mol, less than or equal to about 145 g/mol, less than or equal to about 140 g/mol, or less than or equal to about 130 g/mol.

The first organic ligand may include a (aliphatic, aromatic, or alicyclic) hydrocarbon group. The hydrocarbon group of the first organic ligand may include a substituted or unsubstituted C6 to C18 aromatic hydrocarbon group, or a substituted or unsubstituted linear or branched aliphatic hydrocarbon group of C2 to C16, C2 to C14, C3 to C12, C4 to C10, C5 to C9, C4 to C8, or C6 to C7 (e.g., an alkyl group, an alkenyl group, or an alkynyl group). The first organic ligand may include a branched alkyl group. The first organic ligand may include a propanoate moiety, an isopropanoate moiety, a butyrate moiety, a butyrate moiety having one or more C1 to C3 alkyl groups (e.g., a carboxylate moiety of methylbutanoic acid or a carboxylate moiety of ethylbutanoic acid), a valerate (or pentanoate ester) moiety, a valerate moiety substituted with one or more C1 to C4 alkyl groups (e.g., a carboxylate moiety of methylvaleric acid or a carboxylate moiety of propylpentanoic acid), a hexanoate moiety, a hexanoate moiety substituted with one or more C1 to C5 alkyl groups (e.g., a carboxylate moiety of ethylhexanoic acid), an octanoate moiety, an octanoate moiety substituted with a C1 to C6 alkyl group (e.g., a carboxylate moiety of butyloctanoic acid), or a combination thereof.

In an embodiment, a first zinc precursor may include zinc, e.g., a zinc ion, and two different first organic ligands coordinated to the zinc as long as the first organic ligands satisfy the conditions above. For example, a first zinc precursor may include zinc, and e.g., a first organic ligand with a propanoate moiety and a first organic ligand with a butyrate moiety having one or more C1 to C3 alkyl groups. Accordingly, the first zinc precursor may include a mixed ligand set with two different first organic ligands.

The first organic ligand includes a carboxylate moiety (e.g., a carboxylate anion) represented by Chemical formula A, and a total number of carbon atoms included in the first organic ligand is 3 to 15, or 4 to 13, or 5 to 11, or 6 to 10:

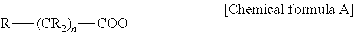

In Chemical formula A, R may be the same or different and each independently is hydrogen or a C1 to C6 or C2 to C4 or C3 to C5 alkyl group (e.g., a methyl group, an ethyl group, a propyl group, a butyl group, a pentyl group, or a hexyl group), and n is an integer of 1 to 14, or 2 to 12, or 3 to 10, or 4 to 8.

As noted, a second zinc precursor may include a second organic ligand, different from the first organic ligand. The second organic ligand may have a molecular weight or a number of carbon atoms greater than that of the first organic ligand. A difference between a molecular weight of the second organic ligand and a molecular weight of the first organic ligand may be greater than or equal to about 50 g/mol, greater than or equal to about 75 g/mol, greater than or equal to about 80 g/mol, greater than or equal to about 90 g/mol, greater than or equal to about 100 g/mol, greater than or equal to about 120 g/mol, greater than or equal to about 130 g/mol, or greater than or equal to about 150 g/mol. The difference between the molecular weight of the second organic ligand and the molecular weight of the first organic ligand may be less than or equal to about 240 g/mol, less than or equal to about 220 g/mol, less than or equal to about 200 g/mol, less than or equal to about 180 g/mol, less than or equal to about 160 g/mol, less than or equal to about 150 g/mol, less than or equal to about 140 g/mol, less than or equal to about 130 g/mol, less than or equal to about 120 g/mol, less than or equal to about 100 g/mol, or less than or equal to about 90 g/mol.

The second organic ligand may have a molecular weight of greater than about 200 g/mol, greater than or equal to about 210 g/mol, greater than or equal to about 215 g/mol, greater than or equal to about 220 g/mol, greater than or equal to about 225 g/mol, greater than or equal to about 230 g/mol, greater than or equal to about 235 g/mol, greater than or equal to about 240 g/mol, greater than or equal to about 245 g/mol, greater than or equal to about 250 g/mol, greater than or equal to about 255 g/mol, greater than or equal to about 260 g/mol, greater than or equal to about 265 g/mol, greater than or equal to about 270 g/mol, or greater than or equal to about 280 g/mol. The second organic ligand may have a molecular weight of less than or equal to about 500 g/mol, less than or equal to about 450 g/mol, less than or equal to about 440 g/mol, less than or equal to about 430 g/mol, less than or equal to about 420 g/mol, less than or equal to about 410 g/mol, less than or equal to about 400 g/mol, less than or equal to about 390 g/mol, less than or equal to about 380 g/mol, less than or equal to about 370 g/mol, less than or equal to about 360 g/mol, less than or equal to about 350 g/mol, less than or equal to about 340 g/mol, or less than or equal to about 250 g/mol.

The second organic ligand may include a linear or branched aliphatic hydrocarbon group of C12 to C25, C13 to C23, C14 to C22, C16 to C21, C17 to C20, or C18 to C19 (e.g., an alkyl group, an alkenyl group, or an alkynyl group). The second organic ligand may include a tetradecyl group, a tetradecenyl group, a pentadecyl group, a pentadecenyl group, a hexadecyl group, a hexadecenyl group, a heptadecyl group, a heptadecenyl group, an octadecyl group, an octadecenyl group, an octadecadienyl group, an octadecatrienyl group, or a combination thereof.

In an embodiment, the second zinc precursor may include zinc, e.g., a zinc ion, and two different second organic ligands coordinated to the zinc as long as the second organic ligands satisfy the conditions above. For example, a second zinc precursor may include zinc, and e.g., a second organic ligand with a tetradecyl group, and a second organic ligand with an octadecyl group. Accordingly, the second zinc precursor may include a mixed ligand set with two different second organic ligands. The second organic ligand may, for example, include one or more, or two or more carbon-carbon double bonds in the aliphatic hydrocarbon (chain) group. The second organic ligand may include a carboxylate moiety of linolenic acid, a carboxylate moiety of linoleic acid, a carboxylate moiety of oleic acid, a carboxylate moiety of elaidic acid, a carboxylate moiety of stearic acid, a carboxylate moiety of palmitic acid, a carboxylate moiety of myristic acid, or a combination thereof.

In an embodiment, the first organic ligand may include a branched alkyl group, and the second organic ligand may include a linear alkenyl group.

A first carboxylic acid is a carboxylic acid including the first organic ligand. In an embodiment, the first carboxylic acid may be represented by Chemical formula A-1:

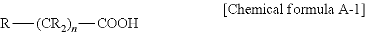

Definitions of R and n are the same as those of Chemical formula A.

The first carboxylic acid may have a pKa of greater than or equal to about 4.8, greater than or equal to about 4.9, greater than or equal to about 5.5, greater than or equal to about 5.8, greater than or equal to about 6.5, or greater than or equal to about 7. The first carboxylic acid may have a pKa lower than that of a second carboxylic acid. In an embodiment, the first carboxylic acid may have a pKa of less than or equal to about 9, less than or equal to about 8.8, less than or equal to about 8.3, less than or equal to about 7.5, less than or equal to about 6.7, less than or equal to about 5.8, or less than or equal to about 4.9.

Examples of the first carboxylic acid may include propionic acid, pentanoic acid, hexanoic acid, octanoic acid, ethylhexanoic acid, nonanoic acid, decanoic acid, dodecanoic acid, myristic acid, palmitic acid, ethylbutyric acid, propylvaleric acid, methylbutyric acid, butyloctanoic acid, or a combination thereof.

A second carboxylic acid is a carboxylic acid including the second organic ligand. In an embodiment, the second carboxylic acid may include linolenic acid, linoleic acid, oleic acid, elaidic acid, stearic acid, myristic acid, palmitic acid, or a combination thereof.

The second carboxylic acid may have a pKa of greater than or equal to about 8.9, greater than or equal to about 9, greater than or equal to about 9.1, greater than or equal to about 9.8, greater than or equal to about 10, greater than or equal to about 10.1, or greater than or equal to about 10.14.

In an embodiment, the first zinc precursor may exhibit the following structure, but is not limited thereto:

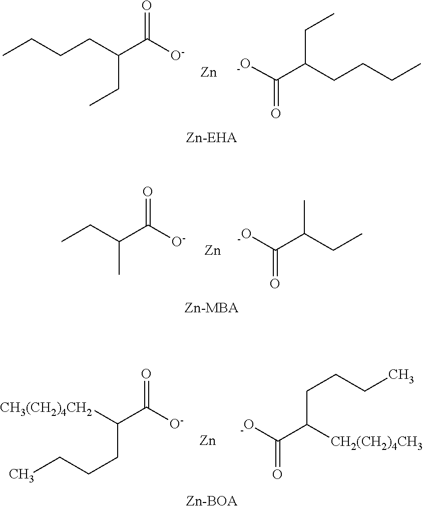

In an embodiment, the second zinc precursor may exhibit the following structure, but is not limited thereto:

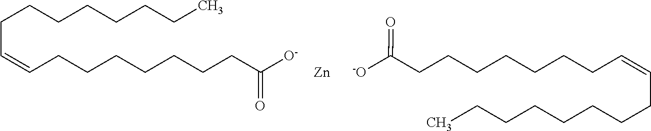

In the method of an embodiment, a reaction medium including an organic solvent and, optionally, an organic ligand may be subjected to vacuum treatment. The organic ligand is as described herein. The vacuum treatment may include heating (or vacuum-treating) the solvent and, optionally, the ligand compound to a predetermined temperature (e.g., greater than or equal to about 100° C.) under vacuum. The vacuum-treated reaction medium may be converted to an inert gas atmosphere and reheated to a predetermined temperature (e.g., greater than or equal to about 120° C. or to a reaction temperature).

In an embodiment, the particle and the sulfur precursor may be added to the reaction medium heated to the predetermined temperature. In an embodiment, after heating the vacuum-treated reaction medium to an injection temperature, the first semiconductor nanocrystal, the first zinc precursor (or the second zinc precursor), and the sulfur precursor may be added, and then the reaction medium may be raised to the reaction temperature. The injection temperature may be lower than the reaction temperature. A difference between the injection temperature and the reaction temperature may be greater than or equal to about 80° C. and less than or equal to about 250° C., greater than or equal to about 80° C. and less than or equal to about 200° C., greater than or equal to about 120° C. and less than or equal to about 180° C., greater than or equal to about 140° C. and less than or equal to about 160° C., or a combination thereof.

In an embodiment, after the first zinc precursor may be added to the reaction medium (once or two or more times) and contacts the sulfur precursor, the second zinc precursor may be added to the reaction medium to contact the sulfur precursor. In an embodiment, after the second zinc precursor is added to the reaction medium (once or two or more times) and first contacts the sulfur precursor, the first zinc precursor may be added to the reaction medium to contact the sulfur precursor.

The first zinc precursor may be added to the reaction medium in a predetermined amount as separate portions (additions), e.g., two or more times. The second zinc precursor may be added to the reaction medium as separate portions (additions), e.g., two or more times.

In the method of an embodiment, after the first zinc precursor contacts the sulfur precursor, the second zinc precursor may contact the sulfur precursor, and the second zinc precursor may be added and mixed (admixing) into the reaction medium before addition of the metal halide.

In the method of an embodiment, after the second zinc precursor contacts the sulfur precursor, the first zinc precursor may contact the sulfur precursor, and the first zinc precursor may be added and mixed (admixing) into the reaction medium before addition of the metal halide.

In the method of an embodiment, an amount of the second zinc precursor relative to 1 mole of the first zinc precursor may be greater than or equal to about 0.01 moles, greater than or equal to about 0.03 moles, greater than or equal to about 0.05 moles, greater than or equal to about 0.07 moles, greater than or equal to about 0.09 moles, greater than or equal to about 0.1 moles, greater than or equal to about 0.2 moles, greater than or equal to about 0.3 moles, greater than or equal to about 0.4 moles, greater than or equal to about 0.5 moles, greater than or equal to about 0.6 moles, greater than or equal to about 0.7 moles, greater than or equal to about 0.8 moles, about 0.9 moles, greater than or equal to about 1 mole, greater than or equal to about 1.2 moles, greater than or equal to about 1.5 moles, greater than or equal to about 1.7 moles, greater than or equal to about 1.9 moles, greater than or equal to about 2 moles, greater than or equal to about 2.1 moles, greater than or equal to about 2.3 moles, greater than or equal to about 2.5 moles, greater than or equal to about 2.7 moles, greater than or equal to about 2.9 moles, greater than or equal to about 3 moles, greater than or equal to about 3.5 moles, greater than or equal to about 4 moles, greater than or equal to about 4.5 moles, greater than or equal to about 5 moles, greater than or equal to about 5.5 moles, greater than or equal to about 6 moles, greater than or equal to about 6.5 moles, greater than or equal to about 7 moles, greater than or equal to about 7.5 moles, greater than or equal to about 8 moles, greater than or equal to about 8.5 moles, greater than or equal to about 9 moles, greater than or equal to about 9.5 moles, greater than or equal to about 10 moles, greater than or equal to about 50 moles, or greater than or equal to about 100 moles

In the method of an embodiment, the amount of the second zinc precursor relative to 1 mole of the first zinc precursor may be less than or equal to about 100 moles, less than or equal to about 90 moles, less than or equal to about 80 moles, less than or equal to about 70 moles, less than or equal to about 60 moles, less than or equal to about 50 moles, less than or equal to about 40 moles, less than or equal to about 30 moles, less than or equal to about 20 moles, less than or equal to about 10 moles, less than or equal to about 9 moles, less than or equal to about 8 moles, less than or equal to about 7 moles, less than or equal to about 6 moles, less than or equal to about 5 moles, less than or equal to about 4 moles, less than or equal to about 3 moles, less than or equal to about 2 moles, less than or equal to about 1 mole, less than or equal to about 0.8 moles, less than or equal to about 0.6 moles, less than or equal to about 0.4 moles, less than or equal to about 0.3 moles, less than or equal to about 0.2 moles, less than or equal to about 0.06 moles, or less than or equal to about 0.03 moles.

A temperature (reaction temperature) for reaction between the zinc precursor and the sulfur precursor may be selected in consideration of types of the precursors. The reaction temperature may be greater than or equal to about 250° C., greater than or equal to about 260° C., greater than or equal to about 270° C., greater than or equal to about 280° C., greater than or equal to about 300° C., greater than or equal to about 320° C., greater than or equal to about 340° C., or greater than or equal to about 350° C. The reaction temperature may be less than or equal to about 400° C., less than or equal to about 390° C., less than or equal to about 380° C., less than or equal to about 370° C., less than or equal to about 360° C., less than or equal to about 350° C., less than or equal to about 345° C., less than or equal to about 340° C., less than or equal to about 330° C., less than or equal to about 320° C., less than or equal to about 310° C., less than or equal to about 290° C., less than or equal to about 280° C., less than or equal to about 270° C., or less than or equal to about 250° C. In the method of an embodiment, the reaction temperature may vary within a range of greater than or equal to about 250° C. and less than or equal to about 340° C.

A reaction time may be appropriately selected in consideration of types of the precursors, the reaction temperature, and a desired thickness of the ZnS shell layer in a final semiconductor nanoparticle. The reaction time may be greater than or equal to about 10 minutes, greater than or equal to about 15 minutes, greater than or equal to about 20 minutes, greater than or equal to about 25 minutes, greater than or equal to about 30 minutes, greater than or equal to about 35 minutes, or greater than or equal to about 40 minutes. The reaction time may be less than or equal to about 5 hours, less than or equal to about 4 hours, less than or equal to about 200 minutes, less than or equal to about 180 minutes, less than or equal to about 160 minutes, less than or equal to about 140 minutes, less than or equal to about 120 minutes, less than or equal to about 100 minutes, less than or equal to about 90 minutes, or less than or equal to about 80 minutes.

By the reaction between the zinc precursor and the sulfur precursor, a semiconductor nanoparticle in which a semiconductor nanocrystal layer (e.g., a shell layer) including zinc and sulfur is formed on the particle may be obtained.

In the method of an embodiment, a metal halide may be added to and mixed with a reaction medium including the formed semiconductor nanoparticle (hereinafter, also referred to as post-treatment). The metal halide includes an organozinc halide and an aluminum halide. The halide may include a chloride, a fluoride, a bromide, an iodide, or a combination thereof. In some non-cadmium-based semiconductor nanoparticles (for example, blue-emitting QDs having a non-cadmium-based ZnSeTe/ZnSe/ZnS structure with a quasi-type II structure), a metal halide compound may contribute to improvement of efficiency and lifetime when used in an electroluminescent (EL) device of such particles. However, the present inventors have found that such metal halides may cause aggregation of semiconductor nanoparticles, and for example, ZnCl₂ may exhibit substantial aggregation with respect to a liquid vehicle for an ink for inkjet printing (e.g., a high-boiling-point solvent such as cyclohexylbenzene).

The present inventors have found that, by using an organozinc halide as described herein (for example, together with an aluminum halide), an organic content of a ZnS-containing shell layer of a semiconductor nanoparticle may be controlled, and accordingly, a lifetime of an EL device including the same may be significantly improved. In addition, it has been confirmed that the semiconductor nanoparticle thus prepared may exhibit improved miscibility with a liquid vehicle (e.g., a high-boiling-point liquid vehicle) in preparation of an ink for inkjet printing, and thus may be well dispersed in such a liquid vehicle.

Accordingly, the method of an embodiment includes use of an organozinc halide during synthesis of a semiconductor nanoparticle. Without wishing to be bound by any theory, according to the method of an embodiment, oxidation and/or defects of a semiconductor nanoparticle may be suppressed. For example, the organozinc halide used in the method of an embodiment may substitute a long-chain ligand moiety while suppressing defect formation on a surface of a ZnS shell formed during synthesis, and thus, unlike an inorganic ligand such as zinc chloride (ZnCl₂), may resolve aggregation issues or dispersion issues during ink formulation. The semiconductor nanoparticle prepared with such dispersion characteristics may exhibit a controlled organic content, and an electroluminescent device including the same in an emission layer may exhibit improved lifetime together with desired electroluminescent properties. When an organometallic zinc halide including a functional group described herein is added to a reaction medium during synthesis in a manner described herein, a final semiconductor nanoparticle may exhibit a reduced mass of organic materials (e.g., ligand mass present on an outermost surface of the particle) as identified, for example, by thermogravimetric analysis, while still exhibiting desired miscibility with a liquid vehicle during ink formulation.

In an embodiment, the organozinc halide may include a substituted or unsubstituted aromatic moiety of C6 to C30 (e.g., a phenyl group, a benzyl group, a naphthyl group, or the like). The aromatic moiety may contribute to improvement of miscibility of the semiconductor nanoparticle with a solvent for inkjet printing. The aromatic moiety may further include, as a substituent, a cyano group, a halogen group (e.g., a chloro group, a fluoro group, a bromo group, an iodo group), or a combination thereof.

In an embodiment, the organozinc halide may include a compound represented by Chemical formula 1:

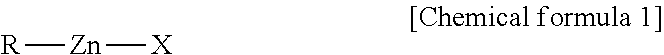

wherein R is a substituted or unsubstituted C1 to C50 (or C3 to C40, C5 to C35, C8 to C30, C9 to C20, or C10 to C16) hydrocarbon group (e.g., an aliphatic, alicyclic, or aromatic hydrocarbon group), and X is a halogen (e.g., F, Cl, Br, or I).

In Chemical formula 1, R may be a substituted or unsubstituted C1 to C50 (or C3 to C40, C5 to C35, C8 to C30, C9 to C20, or C10 to C16) hydrocarbon group, for example, an alkyl group, an alkenyl group, an alkynyl group, or an aryl group (e.g., a phenyl group, a benzyl group, or the like). In Chemical formula 1, R may be substituted with a halogen, a C1 to C10 hydrocarbon group (e.g., an aliphatic hydrocarbon group such as an alkyl group, an alkenyl group, or an alkynyl group), a cyanide group, or a combination thereof. In Chemical formula 1, R may be a substituted or unsubstituted ethylhexyl group, a substituted or unsubstituted methylpropyl group, a substituted or unsubstituted butylpentyl group, a substituted or unsubstituted decenyl group, a substituted or unsubstituted hexylphenyl group, a substituted or unsubstituted methylbenzyl group, a substituted or unsubstituted ethylbenzyl group, a substituted or unsubstituted propylbenzyl group, a substituted or unsubstituted fluorobenzyl group, a substituted or unsubstituted chlorobenzyl group, a substituted or unsubstituted cyanobenzyl group, a substituted or unsubstituted phenylethyl group, or cinnamyl group.

The organozinc halide may include a substituted or unsubstituted benzylzinc halide (e.g., a chloride or a bromide), a substituted or unsubstituted phenylalkylzinc halide (e.g., a chloride or a bromide), a substituted or unsubstituted phenylalkenylzinc halide (e.g., a chloride or a bromide), a substituted or unsubstituted (e.g., linear or branched) alkylzinc halide (e.g., a chloride or a bromide), or a combination thereof. The organozinc halide may include a methylbenzylzinc chloride, a fluorobenzylzinc chloride, a cyanobenzylzinc bromide, a phenylethylzinc bromide, a cinnamylzinc bromide, a decenylzinc bromide, a hexylphenylzinc bromide, or a combination thereof.

The aluminum halide may include aluminum chloride, aluminum bromide, aluminum iodide, or a combination thereof. In an embodiment, using an aluminum halide together with an organozinc halide may further improve a lifetime characteristic of an electroluminescent device including the semiconductor nanoparticle of an embodiment.

The metal halide may be added to the reaction medium after the zinc precursor (e.g., the first zinc precursor or the second zinc precursor) contacts the sulfur precursor (e.g., after formation of a third semiconductor nanocrystal).

In an embodiment, addition and post-treatment of the metal halide may be carried out at a first temperature, and the first temperature may be lower than the reaction temperature. A difference between the first temperature and the reaction temperature may be greater than or equal to about 10° C., greater than or equal to about 20° C., greater than or equal to about 30° C., greater than or equal to about 40° C., or greater than or equal to about 45° C. The difference may be less than or equal to about 150° C., less than or equal to about 130° C., less than or equal to about 120° C., less than or equal to about 100° C., less than or equal to about 90° C., less than or equal to about 80° C., less than or equal to about 70° C., less than or equal to about 60° C., less than or equal to about 50° C., or less than or equal to about 40° C.

In an embodiment, the first temperature may be greater than about 100° C., greater than or equal to about 120° C., greater than or equal to about 140° C., greater than or equal to about 160° C., greater than or equal to about 180° C., greater than or equal to about 200° C., greater than or equal to about 220° C., greater than or equal to about 240° C., greater than or equal to about 260° C., or greater than or equal to about 280° C. The first temperature may be less than or equal to about 320° C., less than or equal to about 310° C., less than or equal to about 300° C., less than or equal to about 290° C., less than or equal to about 280° C., less than or equal to about 260° C., less than or equal to about 250° C., less than or equal to about 240° C., less than or equal to about 230° C., less than or equal to about 220° C., or less than or equal to about 210° C.

In an embodiment, a post-treatment time may be greater than or equal to about 5 minutes, greater than or equal to about 10 minutes, greater than or equal to about 15 minutes, greater than or equal to about 20 minutes, greater than or equal to about 25 minutes, greater than or equal to about 30 minutes, greater than or equal to about 40 minutes, greater than or equal to about 50 minutes, or greater than or equal to about 60 minutes. The post-treatment time may be less than or equal to about 200 minutes, less than or equal to about 190 minutes, less than or equal to about 180 minutes, less than or equal to about 170 minutes, less than or equal to about 160 minutes, less than or equal to about 150 minutes, less than or equal to about 140 minutes, less than or equal to about 130 minutes, less than or equal to about 120 minutes, less than or equal to about 110 minutes, less than or equal to about 100 minutes, less than or equal to about 90 minutes, less than or equal to about 80 minutes, or less than or equal to about 70 minutes.

In the method of an embodiment, an amount of the metal halide per 1 mole of a total zinc precursor (e.g., a total of the first zinc precursor and the second zinc precursor) may be greater than or equal to about 0.01 moles, greater than or equal to about 0.03 moles, greater than or equal to about 0.04 moles, greater than or equal to about 0.05 moles, greater than or equal to about 0.06 moles, greater than or equal to about 0.07 moles, greater than or equal to about 0.08 moles, greater than or equal to about 0.09 moles, greater than or equal to about 0.1 moles, greater than or equal to about 0.11 moles, greater than or equal to about 0.12 moles, greater than or equal to about 0.13 moles, greater than or equal to about 0.14 moles, greater than or equal to about 0.15 moles, greater than or equal to about 0.16 moles, greater than or equal to about 0.17 moles, greater than or equal to about 0.18 moles, greater than or equal to about 0.19 moles, greater than or equal to about 0.2 moles, greater than or equal to about 0.21 moles, greater than or equal to about 0.23 moles, greater than or equal to about 0.25 moles, greater than or equal to about 0.27 moles, greater than or equal to about 0.29 moles, greater than or equal to about 0.3 moles, greater than or equal to about 0.35 moles, greater than or equal to about 0.4 moles, greater than or equal to about 0.45 moles, greater than or equal to about 0.5 moles, greater than or equal to about 0.55 moles, greater than or equal to about 0.6 moles, greater than or equal to about 0.65 moles, greater than or equal to about 0.7 moles, greater than or equal to about 0.75 moles, greater than or equal to about 0.8 moles, greater than or equal to about 0.85 moles, greater than or equal to about 0.9 moles, greater than or equal to about 0.95 moles, greater than or equal to about 1 mole, greater than or equal to about 5 moles, greater than or equal to about 10 moles, greater than or equal to about 50 moles, or greater than or equal to about 100 moles.

In the method of an embodiment, the amount of the metal halide per 1 mole of the total zinc precursor may be less than or equal to about 100 moles, less than or equal to about 90 moles, less than or equal to about 80 moles, less than or equal to about 70 moles, less than or equal to about 60 moles, less than or equal to about 50 moles, less than or equal to about 40 moles, less than or equal to about 30 moles, less than or equal to about 20 moles, less than or equal to about 10 moles, less than or equal to about 9 moles, less than or equal to about 8 moles, less than or equal to about 7 moles, less than or equal to about 6 moles, less than or equal to about 5 moles, less than or equal to about 4 moles, less than or equal to about 3 moles, less than or equal to about 2 moles, less than or equal to about 1 mole, less than or equal to about 0.96 moles, less than or equal to about 0.84 moles, less than or equal to about 0.72 moles, less than or equal to about 0.63 moles, less than or equal to about 0.58 moles, less than or equal to about 0.52 moles, less than or equal to about 0.49 moles, less than or equal to about 0.43 moles, less than or equal to about 0.41 moles, less than or equal to about 0.4 moles, less than or equal to about 0.38 moles, less than or equal to about 0.34 moles, less than or equal to about 0.28 moles, less than or equal to about 0.26 moles, less than or equal to about 0.24 moles, less than or equal to about 0.22 moles, less than or equal to about 0.2 moles, less than or equal to about 0.19 moles, less than or equal to about 0.17 moles, less than or equal to about 0.15 moles, less than or equal to about 0.13 moles, less than or equal to about 0.11 moles, less than or equal to about 0.08 moles, less than or equal to about 0.06 moles, or less than or equal to about 0.03 moles.

In the method of an embodiment, a mole ratio of the organozinc halide to the aluminum halide (organozinc halide:aluminum halide) may be in a range of 1:0.01 to 1:100, 1:0.03 to 1:70, 1:0.1 to 1:14, 1:0.45 to 1:9, 1:0.55 to 1:5.5, 1:0.65 to 1:3.5, 1:0.75 to 1:2.5, 1:0.85 to 1:1.5, 1:0.95 to 1:1.3, 1:0.98 to 1:1.2, or a combination thereof.

An amount of the aluminum halide per 1 mole of the organozinc halide may be greater than or equal to about 0.01 moles, greater than or equal to about 0.05 moles, greater than or equal to about 0.1 moles, greater than or equal to about 0.2 moles, greater than or equal to about 0.3 moles, greater than or equal to about 0.4 moles, greater than or equal to about 0.5 moles, greater than or equal to about 0.6 moles, greater than or equal to about 0.7 moles, greater than or equal to about 0.8 moles, greater than or equal to about 0.9 moles, greater than or equal to about 1 mole, greater than or equal to about 2 moles, greater than or equal to about 3 moles, greater than or equal to about 4 moles, greater than or equal to about 5 moles, greater than or equal to about 6 moles, greater than or equal to about 7 moles, greater than or equal to about 8 moles, greater than or equal to about 9 moles, greater than or equal to about 10 moles, greater than or equal to about 30 moles, greater than or equal to about 50 moles, greater than or equal to about 70 moles, or greater than or equal to about 90 moles. The amount of the aluminum halide per 1 mole of the organozinc halide may be less than or equal to about 100 moles, less than or equal to about 95 moles, less than or equal to about 85 moles, less than or equal to about 75 moles, less than or equal to about 65 moles, less than or equal to about 55 moles, less than or equal to about 45 moles, less than or equal to about 35 moles, less than or equal to about 25 moles, less than or equal to about 15 moles, less than or equal to about 14 moles, less than or equal to about 13 moles, less than or equal to about 12 moles, less than or equal to about 11 moles, less than or equal to about 10 moles, less than or equal to about 5.5 moles, less than or equal to about 4.5 moles, less than or equal to about 3.5 moles, less than or equal to about 2.5 moles, less than or equal to about 1.5 moles, or less than or equal to about 1 mole.

After the reaction is completed, the particle including the first semiconductor nanocrystal or the second semiconductor nanocrystal, or the obtained semiconductor nanoparticle, can be recovered by pouring an excess of a non-solvent to remove excess organic material not coordinated on the surface of the semiconductor nanoparticle, and then centrifuging the resulting mixture. For example, after the reaction is completed, adding a non-solvent to the reaction product can separate the semiconductor nanoparticles coordinated with the ligand compound. The non-solvent can be a polar solvent that is miscible with the solvent used in the core formation and/or shell formation reaction but cannot disperse the manufactured nanocrystal. The non-solvent can be determined according to the solvent used in the reaction and can include, for example, acetone, ethanol, butanol, isopropanol, water, tetrahydrofuran (THF), dimethyl sulfoxide (DMSO), diethyl ether, formaldehyde, acetaldehyde, ethylene glycol, a solvent having a similar solubility parameter to the non-solvents listed above, or a combination thereof, but is not limited thereto. The separation can be performed using centrifugation, precipitation, chromatography, or distillation. The separated nanocrystal can be washed by adding it to a washing solvent as desired. The washing solvent is not particularly limited and can be a solvent having a similar solubility parameter to the ligand, examples of which include hexane, heptane, octane, chloroform, toluene, benzene, and the like.

The semiconductor nanoparticle of an embodiment may undergo a washing process one time or more, two times or more, or three times or more, and may exhibit properties described herein. The washing may include precipitating the semiconductor nanoparticle by adding a non-solvent (e.g., ethanol or acetone) to an organic solvent dispersion of the semiconductor nanoparticle. After washing, the semiconductor nanoparticle may be dispersed in a desired solvent such as hexane, octane, or cyclohexylbenzene.

The semiconductor nanoparticle may be non-dispersible or non-water-soluble with respect to water, the non-solvent described above, or a combination thereof. The semiconductor nanoparticles may be dispersed in the organic solvent described above. In an embodiment, the semiconductor nanoparticles may be dispersed in a C6 to C40 aliphatic hydrocarbon, a substituted or unsubstituted C6 to C40 aromatic hydrocarbon, or a combination thereof.

In an embodiment, a semiconductor nanoparticle includes zinc, selenium, and sulfur, and the semiconductor nanoparticle includes a first semiconductor nanocrystal; and a semiconductor nanocrystal shell disposed on the first semiconductor nanocrystal and including zinc and sulfur. The semiconductor nanocrystal shell may include a third semiconductor nanocrystal including zinc and sulfur. The first semiconductor nanocrystal may include zinc, selenium, and optionally tellurium. The semiconductor nanoparticle may not include cadmium. The semiconductor nanocrystal shell may include a second semiconductor nanocrystal including zinc and selenium. The second semiconductor nanocrystal may be disposed between the third semiconductor nanocrystal and the first semiconductor nanocrystal. The semiconductor nanoparticle further includes aluminum, and in the semiconductor nanoparticle, a mole ratio of aluminum to zinc (Al:Zn) is greater than or equal to about 0.001:1, or greater than or equal to about 0.01:1, and less than or equal to about 0.1:1, or less than or equal to about 0.05:1. The semiconductor nanoparticle may be prepared by the methods described herein.

The semiconductor nanoparticle may have a core-shell structure including a core and a shell (e.g., a semiconductor nanocrystal shell) disposed on the core. The core may include the first semiconductor nanocrystal. The shell may include the third semiconductor nanocrystal and, optionally, the second semiconductor nanocrystal. With respect to the first, second, and third semiconductor nanocrystals, reference may be made to what is described herein.

The semiconductor nanoparticle or the semiconductor nanocrystal shell may include a zinc selenide, a zinc selenide telluride, a zinc selenide sulfide, a zinc sulfide, or a combination thereof. The semiconductor nanocrystal shell may include a first shell layer (including a second semiconductor nanocrystal); and a second shell layer disposed on the first shell layer and including, for example, a third semiconductor nanocrystal. The first shell layer or the second semiconductor nanocrystal may include a zinc selenide, a zinc selenide telluride, a zinc selenide sulfide, or a combination thereof. The second shell layer or the third semiconductor nanocrystal may include a zinc selenide sulfide, a zinc sulfide, or a combination thereof. In an embodiment, the core-shell type semiconductor nanoparticle may include a semiconductor nanocrystal shell on the first semiconductor nanocrystal (or a core including the same). Depending on the composition of the first semiconductor nanocrystal and the semiconductor nanocrystal shell, the semiconductor nanoparticle may have an energy band alignment of type I, type II, or quasi-type II, and may be configured to emit light of a desired wavelength upon application of a voltage.

In an embodiment, the first or the second semiconductor nanocrystal may include a metal including indium, zinc, or a combination thereof, and a nonmetal element including phosphorus, selenium, tellurium, sulfur, or a combination thereof. The second semiconductor nanocrystal may include ZnSe, ZnSeS, ZnS, ZnTeSe, or a combination thereof. In an embodiment, when present, the second semiconductor nanocrystal may include zinc and selenium (for example, ZnSe, ZnSeS, or a combination thereof). The second semiconductor nanocrystal may be disposed on the first semiconductor nanocrystal (or a core including the same). The second semiconductor nanocrystal may be an intermediate shell layer of a semiconductor nanoparticle.

In an embodiment, the semiconductor nanoparticle, the first semiconductor nanocrystal, or the semiconductor nanocrystal shell (e.g., the second semiconductor nanocrystal or the third semiconductor nanocrystal) may each independently include a group II-VI compound, a group III-V compound, a group IV-VI compound, a group IV element or compound, a group II-III-VI compound, a group I-III-VI compound, a group I-II-IV-VI compound, or a combination thereof.

The Group II-VI compound may include a binary element compound such as ZnS, ZnSe, ZnTe, ZnO, HgS, HgSe, HgTe, MgSe, MgS, or a combination thereof; a ternary element compound such as ZnSeS, ZnSeTe, ZnSTe, HgSeS, HgSeTe, HgSTe, HgZnS, HgZnSe, HgZnTe, MgZnSe, MgZnS, or a combination thereof; a quaternary element compound such as HgZnTeS, HgZnSeS, HgZnSeTe, HgZnSTe, or a combination thereof; or a combination thereof. The Group II-VI compound may further include a Group III metal.

The Group III-V compound may include a binary element compound such as GaN, GaP, GaAs, GaSb, AlN, AlP, AlAs, AlSb, InN, InP, InAs, InSb, or a combination thereof; a ternary element compound such as GaNP, GaNAs, GaNSb, GaPAs, GaPSb, AlNP, AlNAs, AlNSb, AlPAs, AlPSb, InNP, InNAs, InNSb, InPAs, InPSb, or a combination thereof; a quaternary element compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or a combination thereof; or a combination thereof. The Group III-V compound may further include a Group II metal (e.g., InZnP).

The Group IV-VI compound may include a binary element compound such as SnS, SnSe, SnTe, PbS, PbSe, PbTe, or a combination thereof; a ternary element compound such as SnSeS, SnSeTe, SnSTe, PbSeS, PbSeTe, PbSTe, SnPbS, SnPbSe, SnPbTe, or a combination thereof; a quaternary element compound such as SnPbSSe, SnPbSeTe, SnPbSTe, or a combination thereof; or a combination thereof.

Examples of the Group I-III-VI compound may include CuInSe₂, CuInS₂, CuInGaSe, and CuInGaS, but are not limited thereto. Examples of the Group I-III-VI compound may include a ternary element compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, AgAlO₂ or a combination thereof; a quaternary element compound such as AgInGaS₂, AgInGaSe₂; or a combination thereof.

Examples of the Group I-II-IV-VI compound may be CuZnSnSe, and CuZnSnS, but are not limited thereto.

The Group IV element or compound may include a single element such as Si or Ge, or a combination thereof; a binary element compound such as SiC, SiGe, or a combination thereof; or a combination thereof.

Each element included in a multi-element compound such as a binary element compound, a ternary element compound, or a quaternary element compound may be present in the particle at a uniform concentration or at a non-uniform concentration. For example, the chemical formula described above means the types of elements included in the compound, and the ratio among the elements in the compound may be different. For example, the chemical formula “AgInGaS₂” may include AgInₓGa₁₋ₓS₂ (x is a real number of greater than 0 to less than 1), but is not limited thereto.

In an embodiment, the shell may include, for example, zinc, sulfur, and optionally selenium in an outermost layer.

In an embodiment, the first semiconductor nanocrystal may include a metal including indium, zinc, or a combination thereof, and a nonmetal including phosphorus, selenium, tellurium, sulfur, or a combination thereof. The first semiconductor nanocrystal may include InP, InZnP, ZnSe, ZnSeS, ZnSeTe, or a combination thereof. The first semiconductor nanocrystal may include zinc and selenium, and may optionally further include tellurium (including a first chalcogenide). The first semiconductor nanocrystal may include ZnTeₓSe₁₋ₓ (wherein x is greater than about 0, greater than or equal to about 0.001, greater than or equal to about 0.003, greater than or equal to about 0.005, greater than or equal to about 0.007, greater than or equal to about 0.009, greater than or equal to about 0.01, greater than or equal to about 0.03, greater than or equal to about 0.05, greater than or equal to about 0.09, and less than or equal to about 0.1, less than or equal to about 0.05, less than or equal to about 0.04, less than or equal to about 0.03, less than or equal to about 0.02, less than or equal to about 0.01, or less than or equal to about 0.008). The core may further include sulfur or may not include sulfur.

In an embodiment, the semiconductor nanoparticle may emit blue or green light and may include a core including ZnSeTe, ZnSe, or a combination thereof, and a shell including a zinc chalcogenide (e.g., ZnS, ZnSe, ZnSeS, or a combination thereof). An amount of sulfur in the shell may increase or decrease in a radial direction (from the core toward the surface), e.g., the amount of sulfur may have a concentration gradient wherein the concentration of sulfur varies radially (e.g., decreases or increases in a direction toward the core).

In an embodiment, the semiconductor nanoparticle may emit red or green light, the core may include InP, InZnP, or a combination thereof, and the shell may include a Group II metal including zinc and a non-metal including sulfur, selenium, or a combination thereof.

In an embodiment, the semiconductor nanoparticle may have a core-shell structure, and on the interface between the core and the shell, an alloyed interlayer may be present or may not be present. The alloyed interlayer layer may include a homogeneous alloy or may have a concentration gradient. The gradient alloy may have a concentration gradient wherein the concentration of an element of the shell varies radially (e.g., decreases or increases in a direction toward the core).

In an embodiment, the shell may have a composition that varies in a radial direction. In an embodiment, the shell may be a multilayered shell including two or more layers. In a multilayered shell, adjacent two layers may have different compositions from each other. In a multilayered shell, a, e.g., at least one, layer may independently include a semiconductor nanocrystal having a single composition. In a multilayered shell, a, e.g., at least one, layer may independently have an alloyed semiconductor nanocrystal. In a multilayered shell, a, e.g., at least one, layer may have a concentration gradient that varies radially in terms of a composition of a semiconductor nanocrystal.

In an embodiment, in the semiconductor nanoparticle having a core-shell structure, a shell material may have a bandgap energy that is greater than that of the core. The materials of the shell may have a bandgap energy that is less than that of the core. In the case of a multilayered shell, the bandgap energy of the outermost layer material of the shell may be greater than the bandgap energies of the core and the inner layer material of the shell (layers that are closer to the core). In the case of a multilayered shell, a semiconductor nanocrystal of each layer is selected to have an appropriate bandgap, thereby effectively exhibiting a quantum confinement effect.

In an embodiment, a semiconductor nanoparticle may exhibit a controlled organic content. In an embodiment, the organic content may be a mass loss exhibited in thermogravimetric analysis in a temperature range of 200° C. to 550° C. The semiconductor nanoparticle may exhibit a relatively reduced organic content as confirmed by thermogravimetric analysis, while exhibiting a desired level of dispersibility in an organic solvent (for example, an octane or another substituted or unsubstituted aliphatic hydrocarbon solvent, or a substituted or unsubstituted aromatic hydrocarbon solvent such as cyclohexyl benzene).

In an embodiment, as confirmed by thermogravimetric analysis, the semiconductor nanoparticle may have an organic content of less than or equal to about 10.5 wt %, less than or equal to about 10.3 wt %, less than or equal to about 10.2 wt %, less than or equal to about 10 wt %, less than or equal to about 9.9 wt %, less than or equal to about 9.8 wt %, less than or equal to about 9.7 wt %, less than or equal to about 9.6 wt %, less than or equal to about 9.5 wt %, less than or equal to about 9.4 wt %, less than or equal to about 9.3 wt %, less than or equal to about 9.2 wt %, less than or equal to about 9.1 wt %, less than or equal to about 9 wt %, less than or equal to about 8.5 wt %, or less than or equal to about 8 wt %, based on a total weight of the semiconductor nanoparticle. The organic content may be greater than or equal to about 7 wt %, greater than or equal to about 7.5 wt %, greater than or equal to about 8 wt %, greater than or equal to about 8.5 wt %, or greater than or equal to about 9 wt %. The organic content may be, based on the total weight of the semiconductor nanoparticle, greater than or equal to about 7.5 wt % or greater than or equal to about 8 wt % and less than or equal to about 10 wt %, or less than or equal to about 9.7 wt %.

The semiconductor nanoparticle may have, in thermogravimetric analysis, a residue content at a temperatures of 550° C. or higher (e.g., at 600° C.) of greater than or equal to about 85 wt %, greater than or equal to about 87 wt %, greater than or equal to about 88 wt %, greater than or equal to about 88.5 wt %, greater than or equal to about 89 wt %, greater than or equal to about 90 wt %, greater than or equal to about 91 wt %, or greater than or equal to about 92 wt %, based on the total weight of the semiconductor nanoparticle. The residue content may be less than or equal to about 99 wt %, less than or equal to about 97 wt %, less than or equal to about 95 wt %, less than or equal to about 93 wt %, less than or equal to about 92 wt %, less than or equal to about 91 wt %, or less than or equal to about 90 wt %.

In an embodiment, the semiconductor nanoparticle may further include aluminum.

In the semiconductor nanoparticle, a mole ratio of aluminum to zinc (Al:Zn) may be greater than or equal to about 0.001:1, greater than or equal to about 0.003:1, greater than or equal to about 0.005:1, greater than or equal to about 0.007:1, greater than or equal to about 0.009:1, greater than or equal to about 0.010:1, greater than or equal to about 0.013:1, greater than or equal to about 0.014:1, greater than or equal to about 0.015:1, greater than or equal to about 0.017:1, greater than or equal to about 0.019:1, greater than or equal to about 0.020:1, greater than or equal to about 0.023:1, greater than or equal to about 0.025:1, greater than or equal to about 0.027:1, greater than or equal to about 0.029:1, greater than or equal to about 0.030:1, greater than or equal to about 0.033:1, greater than or equal to about 0.035:1, greater than or equal to about 0.037:1, greater than or equal to about 0.039:1, or greater than or equal to about 0.040:1. In the semiconductor nanoparticle, the mole ratio of aluminum to zinc (Al:Zn) may be less than or equal to about 0.1:1, less than or equal to about 0.045:1, less than or equal to about 0.043:1, less than or equal to about 0.041:1, less than or equal to about 0.040:1, less than or equal to about 0.038:1, less than or equal to about 0.036:1, less than or equal to about 0.034:1, less than or equal to about 0.032:1, less than or equal to about 0.030:1, less than or equal to about 0.028:1, less than or equal to about 0.026:1, less than or equal to about 0.024:1, less than or equal to about 0.022:1, less than or equal to about 0.020:1, less than or equal to about 0.019:1, less than or equal to about 0.018:1, less than or equal to about 0.016:1, less than or equal to about 0.014:1, less than or equal to about 0.012:1, less than or equal to about 0.010:1, less than or equal to about 0.008:1, less than or equal to about 0.006:1, less than or equal to about 0.004:1, less than or equal to about 0.002:1, or less than or equal to about 0.0015:1.

In the semiconductor nanoparticle, a mole ratio of aluminum to selenium (Al:Se) may be greater than or equal to about 0.001:1, greater than or equal to about 0.003:1, greater than or equal to about 0.005:1, greater than or equal to about 0.007:1, greater than or equal to about 0.009:1, greater than or equal to about 0.010:1, greater than or equal to about 0.012:1, greater than or equal to about 0.013:1, greater than or equal to about 0.015:1, greater than or equal to about 0.017:1, greater than or equal to about 0.019:1, greater than or equal to about 0.020:1, greater than or equal to about 0.021:1, greater than or equal to about 0.023:1, greater than or equal to about 0.025:1, greater than or equal to about 0.027:1, greater than or equal to about 0.028:1, greater than or equal to about 0.029:1, greater than or equal to about 0.030:1, greater than or equal to about 0.031:1, greater than or equal to about 0.033:1, greater than or equal to about 0.035:1, greater than or equal to about 0.037:1, or greater than or equal to about 0.039:1. In the semiconductor nanoparticle, the mole ratio of aluminum to selenium (Al:Se) may be less than or equal to about 0.07:1, less than or equal to about 0.06:1, less than or equal to about 0.058:1, less than or equal to about 0.056:1, less than or equal to about 0.054:1, less than or equal to about 0.052:1, less than or equal to about 0.050:1, less than or equal to about 0.049:1, less than or equal to about 0.047:1, less than or equal to about 0.045:1, less than or equal to about 0.043:1, less than or equal to about 0.041:1, less than or equal to about 0.040:1, less than or equal to about 0.038:1, less than or equal to about 0.036:1, less than or equal to about 0.034:1, less than or equal to about 0.032:1, less than or equal to about 0.030:1, less than or equal to about 0.028:1, less than or equal to about 0.026:1, less than or equal to about 0.024:1, less than or equal to about 0.022:1, less than or equal to about 0.020:1, less than or equal to about 0.019:1, less than or equal to about 0.018:1, less than or equal to about 0.016:1, less than or equal to about 0.014:1, less than or equal to about 0.012:1, less than or equal to about 0.010:1, less than or equal to about 0.008:1, less than or equal to about 0.006:1, less than or equal to about 0.004:1, less than or equal to about 0.002:1, or less than or equal to about 0.0015:1.

In the semiconductor nanoparticle, a mole ratio of aluminum to sulfur (Al:S) may be greater than or equal to about 0.001:1, greater than or equal to about 0.003:1, greater than or equal to about 0.005:1, greater than or equal to about 0.007:1, greater than or equal to about 0.009:1, greater than or equal to about 0.010:1, greater than or equal to about 0.013:1, greater than or equal to about 0.015:1, greater than or equal to about 0.017:1, greater than or equal to about 0.019:1, greater than or equal to about 0.020:1, greater than or equal to about 0.023:1, greater than or equal to about 0.025:1, greater than or equal to about 0.027:1, greater than or equal to about 0.029:1, greater than or equal to about 0.030:1, greater than or equal to about 0.033:1, greater than or equal to about 0.035:1, greater than or equal to about 0.037:1, greater than or equal to about 0.039:1, greater than or equal to about 0.040:1, greater than or equal to about 0.041:1, greater than or equal to about 0.043:1, greater than or equal to about 0.045:1, greater than or equal to about 0.047:1, greater than or equal to about 0.049:1, greater than or equal to about 0.050:1, greater than or equal to about 0.051:1, greater than or equal to about 0.053:1, greater than or equal to about 0.055:1, greater than or equal to about 0.057:1, greater than or equal to about 0.059:1, or greater than or equal to about 0.060:1. In the semiconductor nanoparticle, the mole ratio of aluminum to sulfur (Al:S) may be less than or equal to about 0.1:1, less than or equal to about 0.095:1, less than or equal to about 0.09:1, less than or equal to about 0.085:1, less than or equal to about 0.08:1, less than or equal to about 0.078:1, less than or equal to about 0.076:1, less than or equal to about 0.074:1, less than or equal to about 0.072:1, less than or equal to about 0.071:1, less than or equal to about 0.07:1, less than or equal to about 0.068:1, less than or equal to about 0.066:1, less than or equal to about 0.064:1, less than or equal to about 0.062:1, less than or equal to about 0.061:1, less than or equal to about 0.060:1, less than or equal to about 0.058:1, less than or equal to about 0.056:1, less than or equal to about 0.054:1, less than or equal to about 0.052:1, less than or equal to about 0.050:1, less than or equal to about 0.049:1, less than or equal to about 0.047:1, less than or equal to about 0.045:1, less than or equal to about 0.043:1, less than or equal to about 0.041:1, less than or equal to about 0.040:1, less than or equal to about 0.038:1, less than or equal to about 0.036:1, less than or equal to about 0.034:1, less than or equal to about 0.032:1, less than or equal to about 0.030:1, less than or equal to about 0.028:1, less than or equal to about 0.026:1, less than or equal to about 0.024:1, less than or equal to about 0.022:1, less than or equal to about 0.020:1, less than or equal to about 0.019:1, less than or equal to about 0.018:1, less than or equal to about 0.016:1, less than or equal to about 0.014:1, less than or equal to about 0.012:1, less than or equal to about 0.010:1, less than or equal to about 0.008:1, less than or equal to about 0.006:1, less than or equal to about 0.004:1, less than or equal to about 0.002:1, or less than or equal to about 0.0015:1.

In the semiconductor nanoparticles of an embodiment, a mole ratio of selenium to a total of selenium and sulfur [Se/(Se+S)] may be greater than or equal to about 0.55:1, greater than or equal to about 0.56:1, greater than or equal to about 0.565:1, greater than or equal to about 0.57:1, greater than or equal to about 0.575:1, greater than or equal to about 0.58:1, greater than or equal to about 0.585:1, greater than or equal to about 0.59:1, greater than or equal to about 0.595:1, greater than or equal to about 0.6:1, greater than or equal to about 0.61:1, greater than or equal to about 0.62:1, greater than or equal to about 0.63:1, greater than or equal to about 0.64:1, or greater than or equal to about 0.65:1. The mole ratio of selenium to the total of selenium and sulfur [Se/(Se+S)] may be less than or equal to about 0.99:1, less than or equal to about 0.97:1, less than or equal to about 0.95:1, less than or equal to about 0.94:1, less than or equal to about 0.92:1, less than or equal to about 0.88:1, less than or equal to about 0.86:1, less than or equal to about 0.84:1, less than or equal to about 0.82:1, less than or equal to about 0.78:1, less than or equal to about 0.76:1, less than or equal to about 0.74:1, less than or equal to about 0.72:1, less than or equal to about 0.7:1, less than or equal to about 0.68:1, less than or equal to about 0.66:1, less than or equal to about 0.64:1, less than or equal to about 0.62:1, less than or equal to about 0.61:1, less than or equal to about 0.6:1, less than or equal to about 0.58:1, or less than or equal to about 0.56:1.

In the semiconductor nanoparticles, a mole ratio of tellurium to sulfur (Te:S) may be greater than or equal to about 0.005:1, greater than or equal to about 0.0056:1, greater than or equal to about 0.006:1, greater than or equal to about 0.007:1, greater than or equal to about 0.008:1, greater than or equal to about 0.009:1, or greater than or equal to about 0.01:1. The mole ratio of tellurium to sulfur (Te:S) may be less than or equal to about 0.1:1, less than or equal to about 0.09:1, less than or equal to about 0.08:1, less than or equal to about 0.07:1, less than or equal to about 0.06:1, less than or equal to about 0.05:1, less than or equal to about 0.04:1, less than or equal to about 0.03:1, less than or equal to about 0.02:1, less than or equal to about 0.015:1, less than or equal to about 0.013:1, less than or equal to about 0.012:1, less than or equal to about 0.011:1, or less than or equal to about 0.01:1.

In the semiconductor nanoparticle, a mole ratio of tellurium to selenium (Te:Se) may be less than or equal to about 0.01:1, less than or equal to about 0.009:1, less than or equal to about 0.008:1, less than or equal to about 0.007:1, less than or equal to about 0.006:1, less than or equal to about 0.005:1, less than or equal to about 0.004:1, less than or equal to about 0.003:1, or less than or equal to about 0.002:1. The mole ratio of tellurium to selenium (Te:Se) may be greater than or equal to about 0.0001:1, greater than or equal to about 0.00015:1, greater than or equal to about 0.0002:1, greater than or equal to about 0.00025:1, greater than or equal to about 0.0003:1, greater than or equal to about 0.00035:1, greater than or equal to about 0.0004:1, greater than or equal to about 0.00045:1, greater than or equal to about 0.0005:1, greater than or equal to about 0.00055:1, greater than or equal to about 0.0006:1, greater than or equal to about 0.00065:1, greater than or equal to about 0.0007:1, greater than or equal to about 0.00075:1, greater than or equal to about 0.0008:1, greater than or equal to about 0.00085:1, greater than or equal to about 0.0009:1, greater than or equal to about 0.00095:1, greater than or equal to about 0.001:1, greater than or equal to about 0.0015:1, greater than or equal to about 0.002:1, greater than or equal to about 0.0025:1, greater than or equal to about 0.003:1, greater than or equal to about 0.0035:1, greater than or equal to about 0.004:1, greater than or equal to about 0.0045:1, greater than or equal to about 0.005:1, greater than or equal to about 0.0055:1, greater than or equal to about 0.006:1, greater than or equal to about 0.0065:1, or greater than or equal to about 0.007:1. In an embodiment, the mole ratio of tellurium to selenium (Te:Se) may be about 0.001:1 to about 0.009:1, about 0.002:1 to about 0.008:1, about 0.003:1 to about 0.007:1, about 0.004:1 to about 0.006:1, about 0.0045:1 to about 0.0055:1, or a combination thereof.

In the semiconductor nanoparticle, a mole ratio of tellurium to zinc (Te:Zn) may be less than or equal to about 0.009:1, less than or equal to about 0.0085:1, less than or equal to about 0.008:1, less than or equal to about 0.0075:1, less than or equal to about 0.007:1, less than or equal to about 0.0065:1, less than or equal to about 0.006:1, less than or equal to about 0.0055:1, less than or equal to about 0.005:1, less than or equal to about 0.0045:1, or less than or equal to about 0.004:1. The mole ratio of tellurium to zinc (Te:Zn) may be greater than or equal to about 0.0001:1, greater than or equal to about 0.0003:1, greater than or equal to about 0.0005:1, greater than or equal to about 0.0007:1, greater than or equal to about 0.0009:1, greater than or equal to about 0.001:1, greater than or equal to about 0.0012:1, greater than or equal to about 0.0014:1, greater than or equal to about 0.0016:1, greater than or equal to about 0.0018:1, greater than or equal to about 0.0019:1, greater than or equal to about 0.002:1, greater than or equal to about 0.0021:1, greater than or equal to about 0.0022:1, greater than or equal to about 0.0023:1, greater than or equal to about 0.0024:1, greater than or equal to about 0.0025:1, greater than or equal to about 0.0026:1, greater than or equal to about 0.0027:1, greater than or equal to about 0.0028:1, greater than or equal to about 0.0029:1, greater than or equal to about 0.003:1, greater than or equal to about 0.0031:1, greater than or equal to about 0.0032:1, greater than or equal to about 0.0033:1, greater than or equal to about 0.0034:1, greater than or equal to about 0.0035:1, greater than or equal to about 0.0036:1, greater than or equal to about 0.0037:1, greater than or equal to about 0.0038:1, greater than or equal to about 0.0039:1, or greater than or equal to about 0.004:1.

In the semiconductor nanoparticle, a mole ratio of selenium to zinc (Se:Zn) may be less than about 1:1, for example, less than or equal to about 0.7:1, less than or equal to about 0.6:1, less than or equal to about 0.55:1, less than or equal to about 0.5:1, less than or equal to about 0.45:1, or less than or equal to about 0.4:1. The mole ratio of selenium to zinc (Se:Zn) may be greater than or equal to about 0.1:1, for example, greater than or equal to about 0.2:1, greater than or equal to about 0.3:1, greater than or equal to about 0.4:1, greater than or equal to about 0.45:1, greater than or equal to about 0.46:1, greater than or equal to about 0.48:1, greater than or equal to about 0.5:1, greater than or equal to about 0.51:1, greater than or equal to about 0.52:1, greater than or equal to about 0.53:1, greater than or equal to about 0.54:1, greater than or equal to about 0.55:1, greater than or equal to about 0.56:1, greater than or equal to about 0.57:1, greater than or equal to about 0.58:1, greater than or equal to about 0.59:1, or greater than or equal to about 0.6:1.

In the semiconductor nanoparticle, a mole ratio of a total of selenium and sulfur to zinc [(Se+S):Zn] may be greater than or equal to about 0.5:1, greater than or equal to about 0.6:1, greater than or equal to about 0.7:1, greater than or equal to about 0.8:1, greater than or equal to about 0.81:1, greater than or equal to about 0.82:1, greater than or equal to about 0.83:1, greater than or equal to about 0.84:1, greater than or equal to about 0.85:1, greater than or equal to about 0.86:1, greater than or equal to about 0.87:1, greater than or equal to about 0.88:1, greater than or equal to about 0.89:1, greater than or equal to about 0.9:1, greater than or equal to about 0.91:1, greater than or equal to about 0.92:1, greater than or equal to about 0.93:1, greater than or equal to about 0.94:1, greater than or equal to about 0.95:1, greater than or equal to about 0.96:1, greater than or equal to about 0.97:1, greater than or equal to about 0.98:1, greater than or equal to about 0.99:1, or greater than or equal to about 1:1. The mole ratio of the total of selenium and sulfur to zinc [(Se+S):Zn] may be less than or equal to about 1.5:1, less than or equal to about 1.2:1, less than or equal to about 1:1, less than or equal to about 0.95:1, less than or equal to about 0.92:1, less than or equal to about 0.87:1, less than or equal to about 0.86:1, less than or equal to about 0.85:1, or less than or equal to about 0.83:1.

In the semiconductor nanoparticle, a mole ratio of sulfur to selenium (S:Se) may be less than or equal to about 0.8:1, less than or equal to about 0.77:1, less than or equal to about 0.75:1, less than or equal to about 0.73:1, less than or equal to about 0.7:1, less than or equal to about 0.69:1, less than or equal to about 0.68:1, less than or equal to about 0.67:1, less than or equal to about 0.66:1, less than or equal to about 0.65:1, less than or equal to about 0.64:1, less than or equal to about 0.63:1, less than or equal to about 0.62:1, or less than or equal to about 0.61:1. In an embodiment, the mole ratio of sulfur to selenium may be greater than or equal to about 0.3:1, greater than or equal to about 0.35:1, greater than or equal to about 0.4:1, greater than or equal to about 0.45:1, greater than or equal to about 0.5:1, greater than or equal to about 0.55:1, greater than or equal to about 0.59:1, greater than or equal to about 0.6:1, greater than or equal to about 0.62:1, greater than or equal to about 0.64:1, greater than or equal to about 0.65:1, greater than or equal to about 0.67:1, greater than or equal to about 0.7:1, greater than or equal to about 0.74:1, or greater than or equal to about 0.76:1.

The semiconductor nanoparticle may further include a halogen. The halogen may be fluorine, chlorine, bromine, iodine, or a combination thereof. In an embodiment, the halogen may be chlorine.

In the semiconductor nanoparticle, a mole ratio of halogen to zinc may be greater than or equal to about 0.005:1, greater than or equal to about 0.01:1, greater than or equal to about 0.02:1, greater than or equal to about 0.03:1, greater than or equal to about 0.04:1, greater than or equal to about 0.05:1, greater than or equal to about 0.08:1, greater than or equal to about 0.1:1, greater than or equal to about 0.15:1, or greater than or equal to about 0.2:1. The mole ratio of halogen to zinc may be less than or equal to about 1:1, less than or equal to about 0.9:1, less than or equal to about 0.7:1, less than or equal to about 0.6:1, less than or equal to about 0.4:1, less than or equal to about 0.2:1, less than or equal to about 0.12:1, less than or equal to about 0.09:1, less than or equal to about 0.07:1, less than or equal to about 0.06:1, or less than or equal to about 0.05:1.

In the semiconductor nanoparticle, a mole ratio of halogen to selenium may be greater than or equal to about 0.005:1, greater than or equal to about 0.01:1, greater than or equal to about 0.02:1, greater than or equal to about 0.03:1, greater than or equal to about 0.04:1, greater than or equal to about 0.05:1, greater than or equal to about 0.08:1, greater than or equal to about 0.1:1, greater than or equal to about 0.15:1, or greater than or equal to about 0.2:1. The mole ratio of halogen to selenium may be less than or equal to about 1:1, less than or equal to about 0.9:1, less than or equal to about 0.7:1, less than or equal to about 0.6:1, less than or equal to about 0.4:1, less than or equal to about 0.2:1, less than or equal to about 0.12:1, less than or equal to about 0.09:1, less than or equal to about 0.07:1, less than or equal to about 0.06:1, or less than or equal to about 0.05:1.

In the semiconductor nanoparticle, a mole ratio of carbon to zinc (C:Zn) may be greater than or equal to about 0.005:1, greater than or equal to about 0.01:1, greater than or equal to about 0.05:1, greater than or equal to about 0.1:1, greater than or equal to about 0.15:1, greater than or equal to about 0.2:1, greater than or equal to about 0.25:1, greater than or equal to about 0.3:1, greater than or equal to about 0.35:1, greater than or equal to about 0.4:1, or greater than or equal to about 0.45:1. In the semiconductor nanoparticle, the mole ratio of carbon to zinc (C:Zn) may be less than or equal to about 1:1, less than or equal to about 0.9:1, less than or equal to about 0.7:1, or less than or equal to about 0.5:1.

In the semiconductor nanoparticle, a mole ratio of carbon to selenium (C:Se) may be greater than or equal to about 0.5:1, greater than or equal to about 0.7:1, greater than or equal to about 0.8:1, greater than or equal to about 0.9:1, greater than or equal to about 0.95:1, greater than or equal to about 1:1, or greater than or equal to about 1.2:1. In the semiconductor nanoparticle, the mole ratio of carbon to selenium (C:Se) may be less than or equal to about 2:1, less than or equal to about 1.5:1, less than or equal to about 1:1, less than or equal to about 0.9:1, less than or equal to about 0.7:1, or less than or equal to about 0.5:1.

In the present specification, mole ratios between elements may be confirmed by suitable analysis means (for example, inductively coupled plasma atomic emission spectroscopy (ICP-AES), X-ray photoelectron spectroscopy (XPS), transmission electron microscopy-energy dispersive X-ray spectroscopy (TEM-EDX), scanning electron microscopy-energy dispersive X-ray spectroscopy (SEM-EDX), X-ray fluorescence (XRF), or the like).

The semiconductor nanoparticle may further include an organic ligand (for example, an organic ligand system including a plurality of organic ligands). The organic ligand (or the organic ligand system) may include a first organic ligand and a second organic ligand. The plurality of organic ligands or the ligand system may be bonded or disposed on a surface of the semiconductor nanocrystal. The semiconductor nanoparticle or the ligand system may further include a halogen (for example, a halide).

In the plurality of organic ligands or the ligand system, a total number of carbon atoms may be greater than or equal to about 20, greater than or equal to about 22, greater than or equal to about 24, greater than or equal to about 28, or greater than or equal to about 29. The total number of carbon atoms may be less than or equal to about 34, less than or equal to about 32, less than or equal to about 30, less than or equal to about 28, or less than or equal to about 27. Details of the first organic ligand and the second organic ligand are as described herein.

In an embodiment, the semiconductor nanoparticles may exhibit, in gas chromatography (GC) analysis, a first peak assigned to the first organic ligand and a second peak assigned to the second organic ligand.

In an embodiment, the semiconductor nanoparticles may include the first organic ligand and the second organic ligand and thus may exhibit, in gas chromatography (GC) analysis (for example, in a chromatogram obtained by gas chromatography analysis), a first peak assigned to the first organic ligand and a second peak assigned to the second organic ligand. In the semiconductor nanoparticles of an embodiment, an area percentage of the first peak relative to the second peak may be greater than or equal to about 1%, or greater than or equal to about 3% and less than or equal to about 200%, or less than or equal to about 99%. In an embodiment, the area percentage of the first peak relative to the second peak may be greater than or equal to about 5%, greater than or equal to about 7%, greater than or equal to about 10%, greater than or equal to about 15%, greater than or equal to about 17%, greater than or equal to about 19%, greater than or equal to about 20%, greater than or equal to about 21%, greater than or equal to about 23%, greater than or equal to about 25%, greater than or equal to about 27%, greater than or equal to about 29%, greater than or equal to about 30%, greater than or equal to about 31%, greater than or equal to about 33%, greater than or equal to about 35%, greater than or equal to about 37%, greater than or equal to about 39%, greater than or equal to about 40%, greater than or equal to about 41%, greater than or equal to about 43%, greater than or equal to about 45%, greater than or equal to about 47%, greater than or equal to about 49%, greater than or equal to about 50%, greater than or equal to about 51%, greater than or equal to about 53%, greater than or equal to about 55%, greater than or equal to about 57%, greater than or equal to about 59%, greater than or equal to about 60%, greater than or equal to about 61%, greater than or equal to about 63%, greater than or equal to about 65%, greater than or equal to about 67%, greater than or equal to about 69%, greater than or equal to about 70%, greater than or equal to about 71%, greater than or equal to about 73%, greater than or equal to about 75%, greater than or equal to about 77%, greater than or equal to about 79%, greater than or equal to about 81%, greater than or equal to about 83%, greater than or equal to about 85%, greater than or equal to about 87%, greater than or equal to about 89%, greater than or equal to about 90%, greater than or equal to about 91%, greater than or equal to about 93%, greater than or equal to about 95%, greater than or equal to about 97%, greater than or equal to about 99%, greater than or equal to about 100%, greater than or equal to about 101%, greater than or equal to about 103%, greater than or equal to about 105%, greater than or equal to about 107%, greater than or equal to about 109%, or greater than or equal to about 110%. The area percentage of the first peak relative to the second peak may be less than or equal to about 400%, less than or equal to about 350%, less than or equal to about 300%, less than or equal to about 250%, less than or equal to about 200%, less than or equal to about 190%, less than or equal to about 180%, less than or equal to about 170%, less than or equal to about 160%, less than or equal to about 150%, less than or equal to about 140%, less than or equal to about 130%, less than or equal to about 120%, less than or equal to about 110%, less than or equal to about 98%, or less than or equal to about 97%.

A retention time of the second peak may be greater than a retention time of the first peak. A ratio of the retention time of the first peak (a peak elution time of the first organic ligand) to the retention time of the second peak (a peak elution time of the second organic ligand) may be greater than or equal to about 0.1, greater than or equal to about 0.2, greater than or equal to about 0.3, greater than or equal to about 0.4, greater than or equal to about 0.5, greater than or equal to about 0.6, or greater than or equal to about 0.7. The ratio between the retention times may be less than or equal to about 1, less than or equal to about 0.9, less than or equal to about 0.8, or less than or equal to about 0.7. A difference between the retention time of the second peak and the retention time of the first peak may be greater than or equal to about 2 minutes, greater than or equal to about 3 minutes, greater than or equal to about 4 minutes, greater than or equal to about 5 minutes, greater than or equal to about 6 minutes, greater than or equal to about 8 minutes, greater than or equal to about 9 minutes, or greater than or equal to about 10 minutes. The difference between the retention time of the second peak and the retention time of the first peak may be less than or equal to about 15 minutes, less than or equal to about 13 minutes, less than or equal to about 12 minutes, less than or equal to about 11 minutes, less than or equal to about 10 minutes, less than or equal to about 9 minutes, less than or equal to about 7 minutes, or less than or equal to about 2 minutes.

A gas chromatography (GC) is an analytical technique that may be used to separate, identify, and quantify individual chemical components in complex mixtures. In the GC, a gas carries a sample through the GC instrument. In an embodiment, a carrier gas or a mobile phase is not particularly limited and may be a high-purity helium, hydrogen, or nitrogen. In an embodiment, the gas chromatography analysis apparatus may include an injector (e.g., split/splitless (SSL) injector), a column (e.g., a wall-coated open tubular (WCOT) capillary column including a thin layer of dimethylpolysiloxane stationary phase), and a detector (e.g., flame ionization detector (FID), or mass spectrometry (MS)), but is not limited thereto. In an embodiment, the GC column may be a capillary column and may be a fused silica capillary tube including a polymer outer coating. In the chromatogram obtained by GC, the x-axis represents retention time (typically in minutes) and the y-axis represents detector response. In an embodiment, the GC apparatus may be Pyrolysis-gas chromatography/mass spectrometry (py-GC/MS). In the GC, the temperature of the pyrolyzer may be 400° C. to 600° C. or 450° C. to 550° C. The GC apparatus may include a capillary column. The capillary column may include a stationary phase of polysiloxane (e.g., dimethylpolysiloxane, 5% to 65% diphenyldimethylpolysiloxane, polyethylene glycol, etc.), and the polarity may be appropriately selected.

The flow rate of the mobile phase (gas) may be appropriately selected and may be in the range of 0.5 milliliter per minute (mL/min) to 10 mL/min, or 1 mL/min to 5 mL/min, or 1.5 mL/min to 3 mL/min. The inlet temperature of the GC apparatus may be appropriately selected and may be in the range of 100° C. to 400° C., 150° C. to 300° C., or 200° C. to 250° C. The GC oven temperature may be appropriately controlled. The analyzer may be a quadrupole (range: 10~550 mass-to-charge ratio (m/z)).

The semiconductor nanoparticle may not substantially exhibit a peak assigned to a thiol in a gas chromatogram. In the gas chromatogram, an area ratio of a peak assigned to a thiol relative to the second peak may be less than or equal to about 10%, less than or equal to about 5%, less than or equal to about 2%, or less than or equal to about 1%.

A ratio of a retention time (in minutes) of the first peak to a retention time (in minutes) of the second peak may be greater than or equal to about 0.1, greater than or equal to about 0.5, or greater than or equal to about 0.7 and less than or equal to about 1, or less than or equal to about 0.9. The retention time of the second peak may be longer than the retention time of the first peak. A difference between the retention time of the second peak and the retention time of the first peak may be greater than or equal to about 2 minutes or greater than or equal to about 5 minutes. The difference between the retention time of the second peak and the retention time of the first peak may be less than or equal to about 12 minutes or less than or equal to about 10 minutes.

In an embodiment, a peak emission wavelength of the semiconductor nanoparticle or a light emission layer (or the light emitted from the electroluminescent device) may be in a wavelength range from ultraviolet to infrared. In an embodiment, the peak emission wavelength of the semiconductor nanoparticle or the emission layer (or the light emitted from the electroluminescent device) may be greater than or equal to about 300 nm, greater than or equal to about 500 nm, greater than or equal to about 510 nm, greater than or equal to about 520 nm, greater than or equal to about 530 nm, greater than or equal to about 540 nm, greater than or equal to about 550 nm, greater than or equal to about 560 nm, greater than or equal to about 570 nm, greater than or equal to about 580 nm, greater than or equal to about 590 nm, greater than or equal to about 600 nm, or greater than or equal to about 610 nm. The peak emission wavelength may be less than or equal to about 800 nm, less than or equal to about 650 nm, less than or equal to about 640 nm, less than or equal to about 630 nm, less than or equal to about 620 nm, less than or equal to about 610 nm, less than or equal to about 600 nm, less than or equal to about 590 nm, less than or equal to about 580 nm, less than or equal to about 570 nm, less than or equal to about 560 nm, less than or equal to about 550 nm, or less than or equal to about 540 nm. The peak emission wavelength may be from about 500 nm to about 650 nm.

The semiconductor nanoparticle, the light-emitting layer, or the electroluminescent device may emit a green light (for example, on an application of a voltage or irradiation with light) and a peak emission wavelength thereof may be in the range of greater than or equal to about 500 nm (for example, greater than or equal to about 510 nm, or greater than or equal to about 515 nm) and less than or equal to about 560 nm, for example, less than or equal to about 540 nm, or less than or equal to about 530 nm. The semiconductor nanoparticle, the light-emitting layer, or the electroluminescent device may emit a red light (for example, on an application of voltage or irradiation with light), and a peak emission wavelength thereof may be in the range of greater than or equal to about 600 nm, for example, greater than or equal to about 610 nm and less than or equal to about 650 nm, or less than or equal to about 640 nm. The semiconductor nanoparticle, the light-emitting layer, or the electroluminescent device may emit a blue light (for example, on an application of voltage or irradiation with light), and a peak emission wavelength thereof may be greater than or equal to about 430 nm (for example, greater than or equal to about 450 nm, greater than or equal to about 455 nm, greater than or equal to about 460 nm, or greater than or equal to about 465 nm) and less than or equal to about 480 nm (for example, less than or equal to about 475 nm, less than or equal to about 470 nm, less than or equal to about 465 nm, or less than or equal to about 463 nm).

In an embodiment, the semiconductor nanoparticle, the light-emitting layer, or the electroluminescent device may exhibit a luminescent spectrum (e.g., photoluminescent or electroluminescent spectrum) with a relatively narrow full width at half maximum. In an embodiment, in the photoluminescent or electroluminescent spectrum, the semiconductor nanoparticle, the light-emitting layer, or the electroluminescent device may exhibit a full width at half maximum of less than or equal to about 45 nm, less than or equal to about 44 nm, less than or equal to about 43 nm, less than or equal to about 42 nm, less than or equal to about 41 nm, less than or equal to about 40 nm, less than or equal to about 39 nm, less than or equal to about 38 nm, less than or equal to about 37 nm, less than or equal to about 36 nm, or less than or equal to about 35 nm. The full width at half maximum may be greater than or equal to about 10 nm, greater than or equal to about 15 nm, greater than or equal to about 20 nm, or greater than or equal to about 25 nm.

The semiconductor nanoparticle may have a quantum yield of greater than or equal to about 10%, for example, greater than or equal to about 20%, greater than or equal to about 30%, greater than or equal to about 40%, greater than or equal to about 50%, greater than or equal to about 60%, greater than or equal to about 70%, greater than or equal to about 80%, greater than or equal to about 90%, or even about 100% (e.g., configured to achieve this). In an embodiment, the semiconductor nanoparticle may have a quantum yield (or absolute quantum yield) of greater than or equal to about 91%, greater than or equal to about 92%, greater than or equal to about 93%, greater than or equal to about 94%, greater than or equal to about 95%, greater than or equal to about 96%, or greater than or equal to about 97%.

The semiconductor nanoparticle may have a size or an average size, (hereinafter, may be simply referred to as “size”) of greater than or equal to about 1 nm and less than or equal to about 100 nm. The size may be a diameter or equivalent diameter converted by assuming a spherical shape from an electron microscope image when not spherical. The size may be calculated from a result of an inductively coupled plasma atomic emission spectroscopy (ICP-AES) analysis. In an embodiment, the semiconductor nanoparticle may have a size of from about 1 nm to about 50 nm, for example, from about 2 nm (or about 3 nm) to about 35 nm. In an embodiment, a size (or an average size) of the semiconductor nanoparticle may be greater than or equal to about 3 nm, greater than or equal to about 4 nm, greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm. In an embodiment, the size of the semiconductor nanoparticle may be less than or equal to about 50 nm, less than or equal to about 40 nm, less than or equal to about 30 nm, less than or equal to about 25 nm, less than or equal to about 20 nm, less than or equal to about 19 nm, less than or equal to about 18 nm, less than or equal to about 17 nm, less than or equal to about 16 nm, less than or equal to about 15 nm, less than or equal to about 14 nm, less than or equal to about 13 nm, or less than or equal to about 12 nm.

A shape of the semiconductor nanoparticle or the semiconductor nanostructure is not particularly limited. For example, the shape of the semiconductor nanoparticle may include, but is not limited to, a sphere, a polyhedron, a pyramid, a multi-pod shape, a hexahedron, a cube, a cuboid, a nanotube, a nanorod, a nanowire, or a nanosheet.

The semiconductor nanoparticle may exhibit improved dispersibility in an organic solvent (for example, an aliphatic hydrocarbon solvent such as octane or a high-boiling-point liquid vehicle). The semiconductor nanoparticle may form a colloidal dispersion in a liquid medium without assistance of another cosolvent (for example, an additional solvent). Accordingly, an embodiment relates to an ink composition including a liquid medium (for example, a liquid vehicle) and (post-treated) semiconductor nanoparticles dispersed in the liquid medium.

In an embodiment, details of the semiconductor nanoparticle are as described herein. In an embodiment, details of the liquid medium (or liquid vehicle) are as described herein. In an embodiment, after dispersing the semiconductor nanoparticles in a predetermined solvent, the semiconductor nanoparticles may exhibit a dynamic light scattering (DLS) particle diameter of less than about 300 nm as measured by dynamic light scattering analysis. The DLS particle diameter may be less than or equal to about 200 nm, less than or equal to about 100 nm, less than or equal to about 80 nm, less than or equal to about 60 nm, less than or equal to about 50 nm, less than or equal to about 40 nm, less than or equal to about 30 nm, or less than or equal to about 20 nm. The DLS particle diameter may be greater than or equal to about 5 nm, greater than or equal to about 7 nm, greater than or equal to about 10 nm, greater than or equal to about 15 nm, or greater than or equal to about 20 nm. The predetermined solvent may be a high-boiling-point solvent (liquid vehicle) usable for an inkjet printing ink.

The liquid medium may include one or more (for example, two or more) organic solvents. The organic solvent may include the solvents described herein. The organic solvent may be an organic solvent having a relatively high boiling point at normal pressure or atmospheric pressure. A boiling point of the organic solvent or the liquid medium may be greater than or equal to about 120° C., greater than or equal to about 127° C., greater than or equal to about 129° C., greater than or equal to about 130° C., greater than or equal to about 135° C., greater than or equal to about 140° C., greater than or equal to about 145° C., greater than or equal to about 150° C., greater than or equal to about 155° C., greater than or equal to about 160° C., greater than or equal to about 165° C., greater than or equal to about 170° C., greater than or equal to about 175° C., or greater than or equal to about 180° C. A boiling point of the organic solvent may be less than or equal to about 400° C., less than or equal to about 380° C., less than or equal to about 370° C., less than or equal to about 360° C., less than or equal to about 350° C., less than or equal to about 340° C., less than or equal to about 330° C., less than or equal to about 320° C., less than or equal to about 310° C., less than or equal to about 300° C., less than or equal to about 280° C., less than or equal to about 270° C., less than or equal to about 250° C., or less than or equal to about 200° C.

The liquid medium or the organic solvent may include a substituted or unsubstituted C6 to C40 aromatic hydrocarbon solvent; a substituted or unsubstituted C6 to C15 aliphatic hydrocarbon solvent; a substituted or unsubstituted C6 to C50 amine solvent; or a combination thereof. The liquid medium or the organic solvent may include a substituted or unsubstituted C6 to C40 or C12 to C24 aromatic hydrocarbon solvent such as cyclohexyl benzene; a substituted or unsubstituted C6 to C15 aliphatic hydrocarbon solvent such as decane, nonane, or dodecane of C10 to C40 or C12 to C24; a substituted or unsubstituted C6 to C50 amine solvent such as trioctylamine or tridecylamine; or a combination thereof.

In an embodiment, the liquid medium or the organic solvent may be a mixed solvent including two or more organic solvents, and a mixing ratio thereof may be adjusted in consideration of conditions for an inkjet process (for example, boiling point and viscosity) or the reaction conditions described herein. For example, when using a mixed solvent of an aromatic solvent and an aliphatic solvent, the ratio may be adjusted to 1:0.1 to 1:10, 1:0.3 to 1:3, or 1:0.5 to 1:2 (volume:volume), but is not limited thereto. The liquid medium or the organic solvent may include cyclohexyl benzene, trioctylamine, or a combination thereof.

In an embodiment, an amount of the semiconductor nanoparticles in the ink composition may be appropriately selected. In the ink composition of an embodiment, the amount of the semiconductor nanoparticles may be, based on a total weight of the composition, greater than or equal to about 1 wt %, greater than or equal to about 5 wt %, greater than or equal to about 10 wt %, greater than or equal to about 15 wt %, greater than or equal to about 20 wt %, greater than or equal to about 25 wt %, greater than or equal to about 30 wt %, greater than or equal to about 35 wt %, or greater than or equal to about 40 wt %. In the ink composition of an embodiment, the amount of the semiconductor nanoparticles may be, based on the total weight of the composition, less than or equal to about 99 wt %, less than or equal to about 95 wt %, less than or equal to about 90 wt %, less than or equal to about 85 wt %, less than or equal to about 80 wt %, less than or equal to about 75 wt %, less than or equal to about 70 wt %, less than or equal to about 65 wt %, or less than or equal to about 60 wt %.

In an embodiment, the semiconductor nanoparticles may be included in the ink composition such that the composition exhibits an appropriate viscosity. The viscosity may be in a range of 0.5 cPs to 30 cPs, 1 cPs to 15 cPs, 1.5 cPs to 10 cPs, 2 cPs to 8 cPs, 2.5 cPs to 5 cPs, 2.8 cPs to 3.5 cPs, or a combination thereof.

The ink composition of an embodiment may exhibit surface tension or wettability with respect to a common layer included in an electroluminescent device described below, for example, a hole auxiliary layer or an electron auxiliary layer. The surface tension may be in a range of 10 mN/m to 100 mN/m, 15 mN/m to 80 mN/m, 20 mN/m to 50 mN/m, 25 mN/m to 45 mN/m, 30 mN/m to 40 mN/m, 33 mN/m to 38 mN/m, or a combination thereof.

In an embodiment, the semiconductor nanoparticles may be included in an emission layer in an electronic device, for example, an electroluminescent device, and may contribute to improvement of device lifetime or the like. Accordingly, an embodiment relates to an electroluminescent device including the semiconductor nanoparticles.

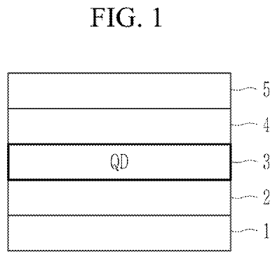

In an embodiment, an electroluminescent device may include a first electrode 1 and a second electrode 5 spaced apart from each other (e.g., each having a surface opposite the other, i.e., each with a surface facing each other); and an emission layer 3 disposed between the first electrode 1 and the second electrode 5. (See FIG. 1.) The emission layer may include the semiconductor nanoparticle. The emission layer or the semiconductor nanoparticle may not include cadmium. The first electrode may include an anode, and the second electrode may include a cathode. The first electrode may include a cathode and the second electrode may include an anode. In an embodiment, the electroluminescent device may further include a hole auxiliary layer 2 between the emission layer and the first electrode. In an embodiment, the electroluminescent device may further include an electron auxiliary layer 4 between the emission layer and the second electrode.

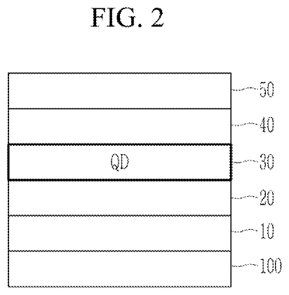

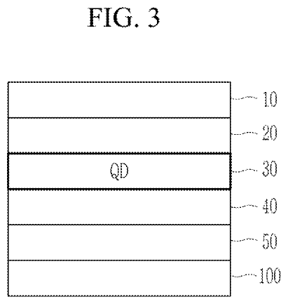

In the electroluminescent device of an embodiment, the first electrode 10 or the second electrode 50 may be disposed on a (transparent) substrate 100. The transparent substrate may be a light extraction surface. (See FIGS. 2 and 3).

Referring to FIG. 2 and FIG. 3, in a light emitting device of an embodiment, a emission layer 30 may be disposed between a first electrode (e.g., anode) 10 and a second electrode (e.g., cathode) 50. The cathode 50 may include an electron injection conductor. The anode 10 may include a hole injection conductor. The work functions of the electron/hole injection conductors included in the cathode and the anode may be appropriately adjusted and are not particularly limited. For example, the cathode may have a small work function and the anode may have a relatively large work function, or vice versa.

The electron/hole injection conductors may include a metal-based material (e.g., a metal, a metal compound, an alloy, or a combination thereof) (e.g., aluminum, magnesium, tungsten, nickel, cobalt, platinum, palladium, calcium, LiF, etc.), a metal oxide such as gallium indium oxide or indium tin oxide (ITO), or a conductive polymer (e.g., having a relatively high work function) such as polyethylene dioxythiophene, but are not limited thereto.

The first electrode, the second electrode, or a combination thereof may be a light-transmitting electrode or a transparent electrode. In an embodiment, both the first electrode and the second electrode may be a light-transmitting electrode. The electrode(s) may be patterned. The first electrode, the second electrode, or a combination thereof may be disposed on a (e.g., insulating) substrate. The substrate may be optically transparent (e.g., may have a light transmittance of greater than or equal to about 50%, greater than or equal to about 60%, greater than or equal to about 70%, greater than or equal to about 80%, greater than or equal to about 85%, or greater than or equal to about 90% and, for example, less than or equal to about 99%, or less than or equal to about 95%). The substrate may include a region for a blue pixel, a region for a red pixel, a region for a green pixel, or a combination thereof. A thin film transistor may be disposed in each region of the substrate, and one of a source electrode and a drain electrode of the thin film transistor may be electrically connected to the first electrode or the second electrode.

The light-transmitting electrode may be disposed on a (e.g., insulating) transparent substrate. The substrate may be a rigid or a flexible substrate. The substrate may include a plastic or organic material such as a polymer, an inorganic material such as a glass, or a metal.

The light-transmitting electrode may have a light transmittance of greater than or equal to about 50%, greater than or equal to about 60%, greater than or equal to about 70%, greater than or equal to about 80%, or greater than or equal to about 90%, for example, from about 80% to about 100%, from about 85% to about 95%, or a combination thereof.

The light-transmitting electrode may be made of, for example, a transparent conductor such as indium tin oxide (ITO) or indium zinc oxide (“IZO”), gallium indium tin oxide, zinc indium tin oxide, titanium nitride, polyaniline, LiF/Mg:Ag, or the like, or a metal thin film of a single layer or a plurality of layers, but is not limited thereto. If one of the first electrode and the second electrode is an opaque electrode, the opaque electrode may be made of an opaque conductor such as aluminum (Al), a lithium-aluminum (Li:Al) alloy, a magnesium-silver (Mg:Ag) alloy, or a lithium fluoride-aluminum (LiF:Al) compound. In the case of the alloy electrode, the ratio between each material may be appropriately adjusted, for example, in the range of from about 1:0.1 to about 1:10, from about 1:0.2 to about 1:5, from about 1:0.3 to about 1:3, or a combination thereof.

In an embodiment, a first electrode or a second electrode may be a multilayer electrode. In an embodiment, the first electrode (or an anode) may be a multilayer electrode including electrode materials of greater than or equal to about 2 layers, or greater than or equal to about 3 layers, and less than or equal to about 10 layers or less than or equal to about 5 layers. In an embodiment, the second electrode (or a cathode) may be a multilayer electrode including electrode materials of greater than or equal to about 2 layers, or greater than or equal to about 3 layers, and less than or equal to about 10 layers or less than or equal to about 5 layers.

The multilayer electrode may include, for example, a translucent conductive material such as an indium tin oxide, an opaque conductive material such as an aluminum (or a reflective electrode material), or a combination thereof. In an embodiment, the electrode (e.g., an anode or a cathode) may have a structure in which an opaque conductive material (or a reflective electrode material layer) is disposed between translucent conductive materials (e.g., translucent conductive material layers). In an embodiment, the electrode (an anode or a cathode) may have a structure in which a translucent conductive material (e.g., a translucent conductive material layer) is disposed between opaque conductive materials (or reflective electrode materials).

As a voltage is applied between the first electrode and the second electrode, the emission layer may emit light upward, downward, or a combination thereof by an electric field, and the light traveling to the reflective electrode may be reflected and emitted in an opposite direction.

In an embodiment, the light may be emitted toward the cathode. In an embodiment, light may be emitted toward the anode.

A thickness of each of the electrodes (the first electrode, the second electrode, or each of the first electrode and the second electrode) is not particularly limited and may be appropriately selected taking into consideration device efficiency. For example, the thickness of the electrode may be greater than or equal to about 5 nm, greater than or equal to about 10 nm, greater than or equal to about 20 nm, greater than or equal to about 30 nm, greater than or equal to about 40 nm, or greater than or equal to about 50 nm. For example, the thickness of the electrode may be less than or equal to about 100 micrometers (μm), less than or equal to about 90 μm, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 10 μm, less than or equal to about 1 μm, less than or equal to about 900 nm, less than or equal to about 500 nm, less than or equal to about 100 nm, less than or equal to about 90 nm, less than or equal to about 80 nm, less than or equal to about 70 nm, or less than or equal to about 60 nm.

The method of forming the electrode is not particularly limited and may be appropriately selected according to the material. In an embodiment, the electrode may be formed by a vapor deposition, a coating, or a combination thereof, but is not limited thereto.

The emission layer 3 or 30 disposed between the first electrode 1 and the second electrode 5 (e.g., the anode 10 and the cathode 50) may include a semiconductor nanoparticle (e.g., a blue light emitting nanoparticle, a red light emitting nanoparticle, a green light emitting nanoparticle, or a combination thereof). The emission layer may include one or more (e.g., 2 or more or 3 or more and 10 or less) monolayers of a plurality of nanostructures.

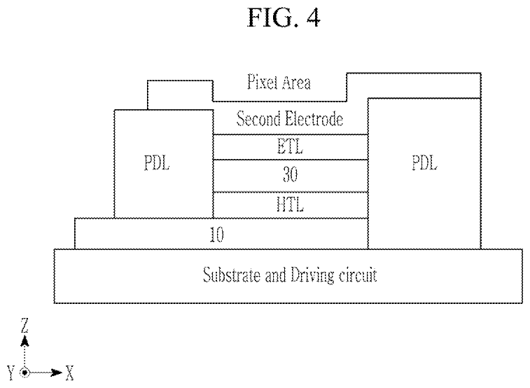

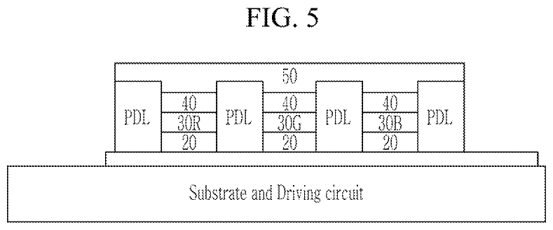

The emission layer may be patterned. In an embodiment, the patterned emission layer may include a blue emission layer 30B disposed in the blue pixel, a red emission layer 30R disposed in the red pixel, a green emission layer 30G disposed in the green pixel, or a combination thereof. Each of the (e.g., red, green, or blue) light emitting layers may be (e.g., optically) separated from an adjacent emission layer by a partition wall. In an embodiment, a partition wall such as a black matrix or a pixel defining layer (PDL) may be disposed between the red light emitting layer(s), the green light emitting layer(s), and the blue light emitting layer(s). (See FIG. 4 and FIG. 5). The red light emitting layer, the green light emitting layer, and the blue emission layer may be optically isolated from each other.

The emission layer or the semiconductor nanoparticles may not include cadmium. The emission layer or the semiconductor nanoparticles may not include lead, mercury, or a combination thereof. The semiconductor nanoparticle may further include or may not include copper, manganese, or a combination thereof. The semiconductor nanoparticle included in the emission layer may include a post-treated semiconductor nanoparticle as described herein.

Formation of the emission layer may be performed by any wet method (for example, coating or inkjet printing). Formation of the emission layer may include applying the ink composition according to an embodiment onto a substrate (for example, a hole auxiliary layer or an electron auxiliary layer) by an appropriate method and, optionally, removing a liquid vehicle.

Forming the emission layer by an inkjet printing manner may include putting or accommodating the ink composition containing the semiconductor nanoparticle in equipment equipped with an inkjet printing nozzle, and ejecting/depositing droplets of the composition from the nozzle toward a desired location (e.g., a hole transport layer or electron transport layer surface defined by a partition wall or bank such as a pixel defining layer (PDL)). (See FIG. 4 and FIG. 5).

In an electroluminescent device of an embodiment, a thickness of the emission layer may be selected appropriately. In an embodiment, the emission layer 3 or 30 may include a monolayer of semiconductor nanoparticles. In an embodiment, the emission layer 3 or 30 may include a monolayer of semiconductor nanoparticles, e.g., one or more, two or more, three or more, or four or more and 20 or less, 10 or less, 9 or less, 8 or less, 7 or less, or 6 or less, monolayers of semiconductor nanoparticles. The emission layer 3 or 30 may have a thickness of greater than or equal to about 5 nm, for example, greater than or equal to about 10 nm, greater than or equal to about 20 nm, or greater than or equal to about 30 nm and less than or equal to about 200 nm, for example, less than or equal to about 150 nm, less than or equal to about 100 nm, less than or equal to about 90 nm, less than or equal to about 80 nm, less than or equal to about 70 nm, less than or equal to about 60 nm, or less than or equal to about 50 nm. The emission layer 3 or 30 may have a thickness of, for example, about 10 nm to about 150 nm, about 20 nm to about 100 nm, about 30 nm to about 50 nm, or a combination thereof.

The formation of the emission layer may be performed by preparing a composition including nanostructures (configured to emit a desired light) and applying or depositing the composition on a substrate, for example, including an electrode or a charge auxiliary layer in, e.g., by, an appropriate method (e.g., spin coating, inkjet printing, and the like).

The forming of the emission layer may further include heat-treating the coated or deposited semiconductor nanoparticle layer. The heat-treating (e.g., thermal treatment, or heat treatment) temperature is not particularly limited, and it can be appropriately selected taking into consideration the boiling point of the organic solvent. For example, the heat treatment temperature may be greater than or equal to about 60° C., or greater than or equal to about 70° C., and less than or equal to about 250° C., or less than or equal to about 180° C. A type of the organic solvent for the coating liquid is not particularly limited and may be selected appropriately. In an embodiment, the organic solvent may include a substituted or unsubstituted aliphatic hydrocarbon organic solvent, a substituted or unsubstituted aromatic hydrocarbon solvent, a substituted or unsubstituted alicyclic hydrocarbon solvent, an acetate solvent, or a combination thereof.

In an embodiment, the emission layer may be a single layer or a multi-layered structure having at least two layers. In the multi-layered structure, adjacent layers (e.g., a first emission layer and a second light-emitting layer) may be configured to emit a first light (e.g., green light, blue light, or red light). In the multi-layered structure, adjacent layers (e.g., a first emission layer and a second light-emitting layer) may have the same or different composition, ligands, or a combination thereof. In an embodiment, the (multi-layered) emission layer may have a halogen amount that varies (increase or decrease) in a thickness direction. In an embodiment, in the (multi-layered) light-emitting layer, the amount of the halogen may increase in a direction toward the electron auxiliary layer. In the (multi-layered) light-emitting layer, an amount, or a content of an organic ligand may decrease in the direction toward the electron auxiliary layer. In the (multi-layered) light-emitting layer, the amount, or the content of the organic ligand may increase in the direction toward the electron auxiliary layer.

The electroluminescent device may further include a charge (hole or electron) auxiliary layer between the first electrode and the second electrode (e.g., an anode and a cathode). In an embodiment, the electroluminescent device may include a hole auxiliary layer 20 or an electron auxiliary layer 40 between the anode 10 and the emission layer 30 and/or between the cathode 50 and the emission layer 30. (See FIGS. 2 and 3).

The light emitting device according to an embodiment may further include a hole auxiliary layer. The hole auxiliary layer 20 may be disposed between the first electrode 10 and the emission layer 30. The hole auxiliary layer 20 may include a hole injection layer, a hole transport layer, an electron blocking layer, or a combination thereof. The hole auxiliary layer 20 may be a layer of a single component or a multilayer structure in which adjacent layers include different components.

The hole auxiliary layer 20 may have a HOMO energy level that may be matched with the HOMO energy level of the emission layer 30 in order to enhance mobility of holes transferred from the hole auxiliary layer 20 to the emission layer 30. In an embodiment, the hole auxiliary layer 20 may include a hole injection layer close to the first electrode 10 and a hole transport layer close to the emission layer 30.

The material included in the hole auxiliary layer 20 (e.g., a hole transport layer, a hole injection layer, or an electron blocking layer) is not particularly limited, and may include, for example, poly(9,9-dioctyl-fluorene-co-N-(4-butylphenyl)-diphenylamine) (“TFB”), polyarylamine, poly(N-vinylcarbazole), poly(3,4-ethylenedioxythiophene) (‘PEDOT”), poly(3,4-ethylenedioxythiophene):polystyrene sulfonate (“PEDOT:PSS”), polyaniline, polypyrrole, N,N,N′,N′-tetrakis(4-methoxyphenyl)-benzidine (“TPD”), 4,4′-bis[N-(1-naphthyl)-N-phenyl-amino]biphenyl (“a-NPD”), 4,4′,4″-Tris[phenyl(m-tolyl)amino]triphenylamine (m-MTDATA), 4,4′,4″-tris(N-carbazolyl)-triphenylamine (“TCTA”), 1,1-bis[(di-4-toylamino)phenyl]cyclohexane (“TAPC”), a p-type metal oxide (e.g., NiO, WO₃, MoO₃, etc.), a carbon-based material such as graphene oxide, or a combination thereof, but is not limited thereto.

In the hole auxiliary layer(s), the thickness of each layer may be appropriately selected. For example, the thickness of each layer may be greater than or equal to about 5 nm, greater than or equal to about 10 nm, greater than or equal to about 15 nm, or greater than or equal to about 20 nm and less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 35 nm, or less than or equal to about 30 nm, but is not limited thereto.

The electron auxiliary layer 40 may be disposed between the emission layer 30 and the second electrode 50. The electron auxiliary layer 40 may include, for example, an electron injection layer, an electron transport layer, a hole blocking layer, or a combination thereof. The electron auxiliary layer may include, for example, an electron injection layer (“EIL”) that facilitates injection of electrons, an electron transport layer (“ETL”) that facilitates transport of electrons, a hole blocking layer (“HBL”) that blocks the movement of holes, or a combination thereof.

In an embodiment, the electron injection layer may be disposed between the electron transport layer and the cathode. For example, the hole blocking layer may be disposed between the emission layer and the electron transport (injection) layer but is not limited thereto. The thickness of each layer may be selected appropriately. For example, the thickness of each layer may be greater than or equal to about 1 nm and less than or equal to about 500 nm, but is not limited thereto. The electron injection layer may be an organic layer formed by vapor deposition. The electron transport layer may include an inorganic oxide nanoparticle or may be an organic layer formed by vapor deposition.

The electron transport layer (“ETL”), the electron injection layer, the hole blocking layer, or a combination thereof may include, for example, 1,4,5,8-naphthalene-tetracarboxylic dianhydride (“NTCDA”), bathocuproine (“BCP”), tris[3-(3-pyridyl)-mesityl]borane (“3TPYMB”), LiF, tris(8-hydroxyquinoline)aluminum (“Alq₃”), tris(8-hydroxyquinoline) gallium (“Gaq₃”), tris-(8-hydroxyquinoline) indium (“Inq₃”), bis(8-hydroxyquinoline) zinc (“Znq₂”), bis(2-(2-hydroxyphenyl)benzothiazolate) zinc (“Zn(BTZ)₂”), bis(10-hydroxybenzo[h]quinolinato) beryllium (“BeBq₂”), 8-(4-(4,6-di(naphthalen-2-yl)-1,3,5-triazin-2-yl)phenyl) quinolone (“ET204”), 8-hydroxyquinolinato lithium (“Liq”), an n-type metal oxide (e.g., ZnO, HfO₂, etc.) or a combination thereof, but is not limited thereto.

The electron auxiliary layer 40 may include an electron transport layer. The electron transport layer may include a plurality of nanoparticles. The plurality of nanoparticles may include a metal oxide containing zinc.

The metal oxide may include zinc oxide, zinc magnesium oxide, or a combination thereof. The metal oxide may include Zn₁₋ₓMₓO, wherein M is Mg, Ca, Zr, W, Li, Ti, Y, Al, or a combination thereof and 0≤x≤0.5. In an embodiment, the M in the formula Zn₁₋ₓMₓO may be magnesium (Mg). In an embodiment, in the formula Zn₁₋ₓMₓO, the x may be greater than or equal to about 0.01 and less than or equal to about 0.3, for example, less than or equal to about 0.25, less than or equal to about 0.2, or less than or equal to about 0.15.

The absolute value of the LUMO of the aforementioned nanostructures included in the emission layer may be greater or smaller than the absolute value of the LUMO of the metal oxide. The average size of the nanoparticles may be greater than or equal to about 1 nm, for example, greater than or equal to about 1.5 nm, greater than or equal to about 2 nm, greater than or equal to about 2.5 nm, or greater than or equal to about 3 nm and less than or equal to about 10 nm, less than or equal to about 9 nm, less than or equal to about 8 nm, less than or equal to about 7 nm, less than or equal to about 6 nm, or less than or equal to about 5 nm.

In an embodiment, each thickness of the electron auxiliary layer 40 (e.g., electron injection layer, electron transport layer, or hole blocking layer) may be greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, or greater than or equal to about 20 nm, and less than or equal to about 120 nm, less than or equal to about 110 nm, less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 30 nm, or less than or equal to about 25 nm, but is not limited thereto.

A device according to an embodiment may have a normal structure. In an embodiment, in the device, the anode 10 disposed on the transparent substrate 100 may include a metal oxide-based transparent electrode (e.g., an ITO electrode), and the cathode 50 facing the anode 10 may include a conductive metal (e.g., having a relatively low work function, such as Mg, Al, etc.). The hole auxiliary layer 20 (e.g., a hole injection layer such as PEDOT:PSS, p-type metal oxide, or a combination thereof; a hole transport layer such as TFB, polyvinylcarbazole (“PVK”), or a combination thereof; or a combination thereof) may be provided between the transparent electrode 10 and the emission layer 30. The hole injection layer may be disposed close to the transparent electrode and the hole transport layer may be disposed close to the light emitting layer. The electron auxiliary layer 40 such as an electron injection/transport layer may be disposed between the emission layer 30 and the cathode 50. (See FIG. 2).

A device according to an embodiment may have an inverted structure. Herein, the cathode 50 disposed on the transparent substrate 100 may include a metal oxide-based transparent electrode (e.g., ITO), and the anode 10 facing the cathode 50 may include a metal (e.g., having a relatively high work function, such as Au, Ag, etc.). For example, an (optionally doped) n-type metal oxide (crystalline Zn metal oxide) or the like may be disposed as an electron auxiliary layer 40 (e.g., an electron transport layer) between the transparent electrode 50 and the emission layer 30, a hole auxiliary layer 20 (e.g., a hole transport layer including TFB, PVK, or a combination thereof; a hole injection layer including MoO₃ or other p-type metal oxide; or a combination thereof) may be disposed between the metal anode 10 and the emission layer 30. (See FIG. 3)

The aforementioned device may be manufactured by an appropriate method. For example, the electroluminescent device may be manufactured by optionally forming a hole auxiliary layer (e.g., by deposition or coating) on a substrate on which an electrode is disposed, forming a emission layer including nanostructures (e.g., a pattern of the aforementioned nanostructures), and forming (optionally, an electron auxiliary layer and) an electrode (e.g., by vapor deposition or coating) on the light emitting layer. A method of forming the electrode/hole auxiliary layer/electron auxiliary layer may be appropriately selected and is not particularly limited.

In an embodiment, each layer included in the hole transport region, the light-emitting layer, and each layer included in the electron transport region may be formed in a predetermined region using various methods such as vacuum deposition, spin coating, casting, Langmuir-Blodgett (LB) method, inkjet printing, laser printing, and Laser Induced Thermal Imaging (LITI). For example, the emission layer may be formed by inkjet printing. The inkjet printing process is as described herein.

When each layer included in the hole transport region, the light-emitting layer, and each layer included in the electron transport region is formed by vacuum deposition, the deposition conditions may be appropriately selected. For example, the deposition temperature may be about 100° C. to about 500° C., the vacuum degree may be about 10\hat{ }-8 to about 10\hat{ }-3 torr, and the deposition rate range may be about 0.01 to about 100 angstroms per second (Å/sec). The deposition conditions may be selected in consideration of the material to be included in the layer to be formed and the structure of the layer to be formed.

The electroluminescent device may be configured to emit blue light. The wavelength range of the blue light is as described herein. The electroluminescent device may be configured to emit green light. The wavelength range of the green light is as described herein. The electroluminescent device may be configured to emit red light. The wavelength range of the red light is as described herein.

In the electroluminescent device of an embodiment, a maximum external quantum efficiency (“EQE”) may be greater than or equal to about 4%, greater than or equal to about 5%, greater than or equal to about 6%, greater than or equal to about 7%, greater than or equal to about 8%, greater than or equal to about 9%, greater than or equal to about 10%, greater than or equal to about 10.5%, greater than or equal to about 11%, greater than or equal to about 11.5%, greater than or equal to about 12%, greater than or equal to about 12.5%, greater than or equal to about 13%, greater than or equal to about 13.5%, or greater than or equal to about 14%. In the electroluminescent device of an embodiment, a maximum external quantum efficiency (‘EQE”) may be less than or equal to about 50%, less than or equal to about 40%, less than or equal to about 30%, or less than or equal to about 20%.

The electroluminescent device may have a maximum luminance of greater than or equal to about 10,000 nits (cd/m²), greater than or equal to about 20,000 nits, greater than or equal to about 30,000 nits, greater than or equal to about 50,000 nits, greater than or equal to about 60,000 nits, greater than or equal to about 70,000 nits, greater than or equal to about 80,000 nits, greater than or equal to about 90,000 nits, greater than or equal to about 95,000 nits, greater than or equal to about 100,000 nits, greater than or equal to about 105,000 nits, greater than or equal to about 110,000 nits, greater than or equal to about 115,000 nits, greater than or equal to about 120,000 nits, or greater than or equal to about 125,000 nits. The maximum luminance may be in the range of about 3,000 nits to about 500,000 nits.

The electroluminescent device may exhibit improved lifespan. In an embodiment, the lifespan of the electroluminescent device may be measured while being driven at a predetermined initial luminance (e.g., 146 nits or 650 nits).

The lifespan T50 of the electroluminescent device may be greater than or equal to about 10 hours, greater than or equal to about 50 hours, greater than or equal to about 80 hours, greater than or equal to about 100 hours, greater than or equal to about 120 hours, greater than or equal to about 130 hours, greater than or equal to about 150 hours, greater than or equal to about 300 hours, greater than or equal to about 310 hours, greater than or equal to about 350 hours, greater than or equal to about 380 hours, greater than or equal to about 400 hours, greater than or equal to about 450 hours, greater than or equal to about 500 hours, greater than or equal to about 600 hours, greater than or equal to about 700 hours, greater than or equal to about 800 hours, greater than or equal to about 900 hours, greater than or equal to about 1,000 hours, greater than or equal to about 1,500 hours, or more.

The lifespan T90 of the electroluminescent device may be greater than or equal to about 10 hours, greater than or equal to about 15 hours, greater than or equal to about 20 hours, greater than or equal to about 25 hours, greater than or equal to about 30 hours, greater than or equal to about 35 hours, greater than or equal to about 40 hours, greater than or equal to about 50 hours, greater than or equal to about 75 hours, greater than or equal to about 100 hours, greater than or equal to about 125 hours, greater than or equal to about 150 hours, greater than or equal to about 175 hours, greater than or equal to about 200 hours, greater than or equal to about 300 hours, greater than or equal to about 310 hours, greater than or equal to about 350 hours, greater than or equal to about 380 hours, greater than or equal to about 400 hours, greater than or equal to about 450 hours, greater than or equal to about 500 hours, greater than or equal to about 600 hours, greater than or equal to about 700 hours, greater than or equal to about 800 hours, greater than or equal to about 900 hours, greater than or equal to about 1,000 hours, greater than or equal to about 1,500 hours, or more.

In an embodiment, T50 may be in the range of about 150 hours to about 5,000 hours, about 400 hours to about 4,000 hours, about 500 hours to about 3,500 hours, about 750 hours to about 2,000 hours, about 1,000 hours to about 1,500 hours, or a combination thereof.

In an embodiment, T90 may be in the range of about 13 hours to about 5,000 hours, about 15 hours to about 2,800 hours, about 18 hours to about 1,200 hours, about 22 hours to about 1,000 hours, about 31 hours to about 800 hours, about 50 hours to about 700 hours, about 60 hours to about 500 hours, about 80 hours to about 400 hours, or a combination thereof.

In an embodiment, a display device includes the electroluminescent device described herein.

The display device may include a first pixel and a second pixel that is configured to emit light different from the light of the first pixel.

The display device (e.g., a display panel) may include a first pixel and a second pixel configured to emit light of a color different from that of the first pixel. In one embodiment, the first light emitted from the emission layer may be extracted through the second electrode (e.g., in the Z direction) (see FIG. 4 or FIG. 5). In an embodiment, the first light may be extracted through the (transparent) first electrode and optionally through the substrate 100 (see FIG. 3). The emission layer may be disposed within a pixel (or subpixel) in the display device (display panel) as described below (see FIG. 4 or FIG. 5).

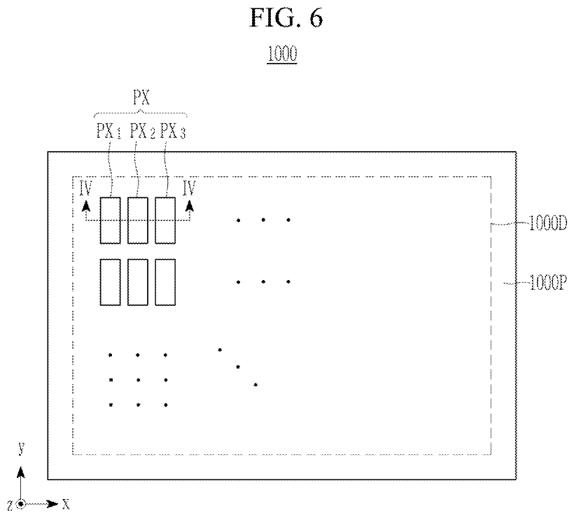

Referring to FIG. 6, a display panel 1000 according to an embodiment may include a display area 1000D for displaying an image and a non-display area 1000P disposed around the display area 1000D, in which the binding element may be located.

The display area 1000D may include a plurality of pixels PXs arranged along a row (e.g., x direction) and/or a column (e.g., y direction), and each pixel PX may include a plurality of sub-pixels PX₁, PX₂, and PX₃ displaying different colors. As an example, a configuration in which three sub-pixels PX₁, PX₂, and PX₃ constitute one pixel PX is illustrated, but the configuration is not limited thereto. An additional sub-pixel such as a white sub-pixel may be further included, and one or more sub-pixel displaying the same color may be included. The plurality of pixels PXs may be arranged in, for example, a Bayer matrix, a PenTile matrix, and/or a diamond matrix, but is not limited thereto.

Each of the sub-pixels PX₁, PX₂, and PX₃ may be configured to display a color of three primary colors or a combination of three primary colors, for example, red, green, blue, or a combination thereof (e.g., white light). For example, the first sub-pixel PX₁ may be configured to display red, the second sub-pixel PX₂ may be configured to display green, and the third sub-pixel PX₃ may be configured to display blue.

In the figure, each of the sub-pixels are depicted to have the same size, but the present disclosure is not limited thereto. For example, at least one of the sub-pixels may be larger or smaller, or have a different shape, than another sub-pixel.

In an embodiment, the display panel of an embodiment may include a light emitting panel which may include a lower substrate 110, a buffer layer 111, a thin film transistor TFT, and a light emitting element 180. The display panel may further include a circuit element for switching and/or driving each of the light emitting elements.

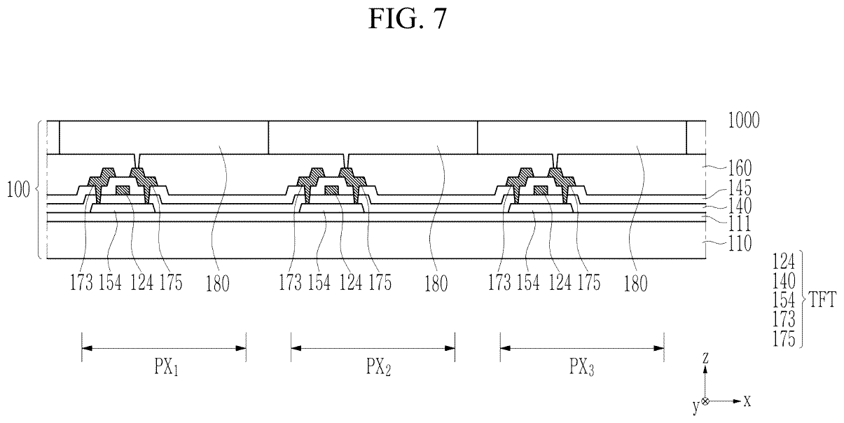

Referring to FIG. 7, in the light emitting panel of an embodiment, the light emitting element 180 may be disposed for each sub-pixel PX₁, PX₂, and PX₃. The light emitting element 180 disposed in each sub-pixel PX₁, PX₂, and PX₃ may be independently driven. The subpixel may include a blue subpixel, red subpixel, or a green subpixel. At least one of the light emitting element 180 may be an electroluminescent device according to an embodiment described herein.

Details of the substrate are the same as described herein. The buffer layer 111 may include an organic material, an inorganic material, or an organic-inorganic material. The buffer layer 111 may include, for example, an oxide, a nitride, or an oxynitride, and may include, for example, silicon oxide, silicon nitride, silicon oxynitride, or a combination thereof, but is not limited thereto. The buffer layer 111 may be one layer or two or more layers and may cover a portion of or the entire surface of the lower substrate 110. The buffer layer 111 may be omitted.

The thin film transistor TFT may be a three terminal element for switching and/or driving the light emitting element 180, and one or two or more thin film transistors TFT may be included for each sub-pixel. The thin film transistor TFT may include a gate electrode 124, a semiconductor layer 154 overlapped with the gate electrode 124, a gate insulating layer 140 between the gate electrode 124 and the semiconductor layer 154, and a source electrode 173 and a drain electrode 175 electrically connected to the semiconductor layer 154. A coplanar top gate structure is shown as an example, but the structure is not limited thereto and thin film transistors TFT may have various structures.

The gate electrode 124 is electrically connected to a gate line (not shown), and may include, for example, a low-resistance metal such as aluminum (AI), molybdenum (Mo), copper (Cu), titanium (Ti), silver (Ag), gold (Au), an alloy thereof, or a combination thereof, but is not limited thereto.

The semiconductor layer 154 may be an inorganic semiconductor such as amorphous silicon, polycrystalline silicon, or oxide semiconductor; an organic semiconductor; an organic-inorganic semiconductor; or a combination thereof. For example, the semiconductor layer 154 may include an oxide semiconductor including at least one of indium (In), zinc (Zn), tin (Sn), and gallium (Ga), and the oxide semiconductor may include, for example, indium-gallium-zinc oxide, zinc-tin oxide, or a combination thereof, but they are not limited thereto. The semiconductor layer 154 may include a channel region and doped regions disposed on both sides of the channel region and electrically connected to the source electrode 173 and the drain electrode 175, respectively.

The gate insulating layer 140 may include an organic material, an inorganic material, or an organic-inorganic material, and may include, for example, an oxide, a nitride, or an oxynitride, and may include, for example, silicon oxide, silicon nitride, silicon oxynitride, or a combination thereof, but is not limited thereto. In the drawing, an example in which the gate insulating layer 140 is formed on the entire surface of the lower substrate 110 is illustrated, but the present disclosure is not limited thereto and the gate insulating layer 140 may be selectively formed between the gate electrode 124 and the semiconductor layer 154. The gate insulating layer 140 may be formed of one or two or more layers.

The source electrode 173 and the drain electrode 175 may include, for example, a low-resistance metal such as aluminum (Al), molybdenum (Mo), copper (Cu), titanium (Ti), silver (Ag), gold (Au), an alloy thereof, or a combination thereof, but are not limited thereto. The source electrode 173 and the drain electrode 175 may be electrically connected to the doped regions of the semiconductor layer 154, respectively. The source electrode 173 may be electrically connected to a data line (not shown), and the drain electrode 175 is electrically connected to a light emitting element 180.

An interlayer insulating layer 145 may be additionally formed between the gate electrode 124 and the source/drain electrodes 173 and 175. The interlayer insulating layer 145 may include an organic material, an inorganic material, or an organic-inorganic material, for example, oxide, nitride, or oxynitride, for example, silicon oxide, silicon nitride, silicon oxynitride, or a combination thereof, but is not limited thereto. The interlayer insulating layer 145 may be formed of one or two or more layers.

A protective layer 160 may be formed on the thin film transistor TFT. The protective layer 160 may be, for example, a passivation layer. The protective layer 160 may include an organic material, an inorganic material, or an organic-inorganic material, for example, polyacrylic, polyimide, polyamide, poly(amide-imide), or a combination thereof, but is not limited thereto. The protective layer 160 may be formed of one or two or three or more layers.

In an embodiment, one of the first electrode 1, 10 and the second electrode 5, 50, may be a pixel electrode linked to the TFT and the other of them may be a common electrode.

In an embodiment, the light emitting device or the display device including the same may be used in a top emission type, a bottom emission type, a dual emission type, or a combination thereof.

In an embodiment, the first electrode 1, 10 may be a light transmitting electrode and the second electrode 5, 50 may be a reflective electrode, and the display panel may be a bottom emission type display panel that emits light toward the first electrode 1, 10 and the lower substrate 100 or 110, if present. In an embodiment, the first electrode 1, 10 may be a reflective electrode and the second electrode 5, 50 may be a light transmitting electrode, and the display panel may be a top emission type display panel that emits light to the opposite side of the first electrode 1, 10 and the lower substrate 100 or 110 if present. In an embodiment, both the first electrode and the second electrode may be translucent electrodes, and the display panel 1000 may be a both side emission type display panel that emits light on the substrate side and on the opposite side of the substrate.

The display device or an electronic apparatus may include (or may be) a device or apparatus such as a television, a virtual reality/augmented reality (VR/AR), a handheld terminal, a monitor, a notebook computer, an electronic display board, a camera, or a part for an automatic, e.g., autonomous, vehicle.

Specific examples are described below. However, the examples described below are only for specifically illustrating or explaining the disclosure, and the scope of the disclosure is not limited thereto.

### EXAMPLES

### 1. Photoluminescence (PL) Analysis

The photoluminescence spectrum and absolute QY of the nanoparticles were obtained at room temperature with an excitation wavelength of 372 nm using a Hitachi F-7000 spectrophotometer or a Hamamatsu QY instrument (Quantaurus-QY Absolute PL quantum yield spectrophotometer C11347-11).

### 2. Thermogravimetric Analysis (TGA)

A thermogravimetric analysis was performed using a Trios V3.2 system (TA Instruments) under nitrogen gas at a heating rate of 10° C./min from 20° C. to 600° C. The weight loss from 200° C. to 550° C. was measured as the organic content.

### 3. Measurement of Electroluminescence Properties and Lifespan

A current according to an applied voltage is measured with a Keithley 2635B source meter, and a CS2000 spectrometer is used to measure electroluminescent properties (e.g., luminance and EQE) of a light-emitting device.

T90(h): The time (hours) it takes for the luminance to decrease to 90% of the initial luminance when a device is driven at a predetermined luminance (e.g., 650 nits or 146 nits) was measured.

T50(h): The time (hours) it takes for the luminance to decrease to 50% of the initial luminance when a device is driven at a predetermined luminance (e.g., 650 nits or 146 nits) was measured.

### 4. ICP Analysis

Inductively coupled plasma atomic emission spectroscopic analysis (ICP-AES) was performed using a Shimadzu ICPS-8100 manufactured by Shimadzu Corporation

### 5. GC Analysis

Gas chromatography analysis was performed using an Agilent GC-MS 7890B/5977A. No standard substances were used. After separating the crude containing the manufactured semiconductor nanoparticles twice with ethanol (EtOH) and vacuum drying, 0.1 mg of the manufactured semiconductor nanoparticles and 1 microliter (μL) of TMAH (tetramethylammonium hydroxide) were mixed and left in the hood for 2 minutes before performing py-GC/MS measurement.
Pyrolyzer temperature: 450° C.
Column: 30 m×0.25 mm×0.25 mm (UA5)
Flow: He (1 mL/min)
Inlet temperature: 300° C.
Oven temperature: 50° C. (held for 2 min), increases up to 320° C. at 20° C./min (held for 10 min). Analyzer: quadrupole (range: 10 to 550 m/z)

The following synthesis is performed under an inert gas atmosphere (e.g., under nitrogen) unless otherwise specified. A precursor content is provided as a molar content, unless otherwise specified.

### Reference Example 1: Preparation of Particle Containing First Semiconductor Nanocrystal and Second Semiconductor Nanocrystal

Selenium (Se), sulfur(S), and tellurium (Te) were dispersed in trioctylphosphine (TOP) to obtain a 2 molar (M) Se/TOP stock solution, a 1M S/TOP stock solution, and a 0.1M Te/TOP stock solution, respectively.

In a 300 milliliter (mL) reaction flask containing trioctylamine (TOA), 4.5 millimole (mmol) of zinc acetate was added with oleic acid and heated to 120° C. under vacuum. After 1 hour, an inert gas (e.g., nitrogen gas) was introduced into the reaction flask. After heating the reaction flask to 240° C. to 300° C., the prepared Se/TOP stock solution and Te/TOP stock solution were quickly injected at a Te:Se mole ratio of 1:15. The reaction was carried out for 40 minutes. Ethanol was then added to the reaction solution, which was quickly cooled to room temperature. The resulting solid precipitate was centrifuged to obtain ZnTeSe semiconductor nanocrystals. The obtained precipitate was dispersed in hexane to obtain ZnSeTe cores. An average size of the cores was approximately 3 nm.

In a 300 mL reaction flask containing trioctylamine (TOA), zinc acetate and oleic acid were added and vacuum-treated at 120° C. The nitrogen (N₂) was flowed into the flask, and then the flask was heated to the reaction temperature of 340° C. The hexane dispersion of the ZnSeTe cores was quickly added to the reaction flask at 340° C., followed by the addition of the Se/TOP stock solution, and a reaction proceeded. Regarding the formation of the ZnSe shell, the amount of selenium precursor added relative to 1 mole of the zinc precursor was 0.67 moles.

After the reaction was completed, the reactor was cooled to room temperature, and ethanol was added to the reaction solution to precipitate a particle containing the first semiconductor nanocrystal (ZnTeSe) and the second semiconductor nanocrystal (ZnSe). The particle was recovered by centrifugation, and it was confirmed that the obtained particles could be dispersed in a hydrocarbon solvent such as octane.

### Reference Example 2: Synthesis of ZnMgO Nanoparticles

Zinc acetate dihydrate and magnesium acetate tetrahydrate were added to a reactor containing dimethylsulfoxide and heated at 60° C. in air. Subsequently, an ethanol solution of tetramethylammonium hydroxide pentahydrate was added to the reactor. After stirring the mixture for 1 hour, a precipitate form and was separated from the reaction mixture with a centrifuge. The precipitate was dispersed in ethanol to obtain Zn₁₋ₓMgₓO nanoparticles (x=0.15). The obtained nanoparticles are subjected to a transmission electron microscope analysis. The particles have an average size of about 3 nm.

### Preparation Example 1

In trioctylamine, zinc acetate and ethyl hexanoic acid (CAS No. 149-57-5, Sigma-Aldrich, Molecular weight: 144.24 g/mol) of the following structure were each added (at a mole ratio between zinc acetate and ethyl hexanoic acid of 1:2) and heated to 120° C. under vacuum for 1 hour to prepare the first zinc precursor:

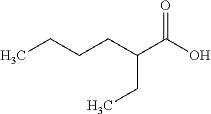

In trioctylamine, zinc acetate and oleic acid were each added (at a mole ratio between zinc acetate and oleic acid of 1:2) and heated to 120° C. under vacuum for 1 hour to prepare the second zinc precursor.

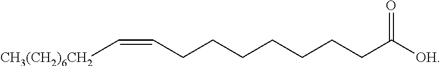

Trioctylamine was added to a 300 mL reaction flask and heated to 120° C. under vacuum for 1 hour, after which nitrogen (N₂) was added into the flask. During the flask temperature was increased to a reaction temperature of 340° C., the octane dispersion of the particles prepared in the reference example 1 was added. This was followed by the addition of the first zinc precursor and dodecanethiol (a sulfur precursor), each of which was injected into the flask in two portions. After 20 minutes, the second zinc precursor and the sulfur precursor were injected at the reaction temperature.

After 20 minutes had elapsed, while maintaining a reaction temperature in a range of greater than or equal to about 250° C. to less than or equal to about 300° C., an organic zinc chloride (i.e., an organic zinc halide) having the following formula (that is, 4-methylbenzylzinc chloride (4MBZC)) and aluminum chloride (AlCl₃) were added, and the reaction was further carried out for 1 hour.

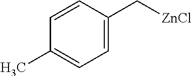

A total reaction time was approximately 120 minutes.

A mole ratio of a first zinc precursor, a second zinc precursor, and a sulfur precursor (first zinc precursor:second zinc precursor:sulfur precursor) was 2.1:0.4:1.4.

A mole ratio of a total of the zinc precursors as used to the metal halide was 2.5:0.4.

A mole ratio between the organic zinc chloride and the aluminum chloride was 1:1.

The reactor was cooled to room temperature. A recovery and washing process wherein ethanol was added to a reaction solution (or a dispersion) to promote precipitation of semiconductor nanoparticles, and the semiconductor nanoparticles were separated and recovered by centrifugation, and were dispersed in hexane (i.e., washed in hexane) was repeated three times. The obtained semiconductor nanoparticles were dispersed in octane or cyclohexylbenzene.

For the obtained semiconductor nanoparticles, photoluminescence spectroscopic analysis and TGA analysis were performed, and the results were summarized in Table 1 and Table 2.

For the obtained semiconductor nanoparticles, ICP-AES analysis was performed, and the results were summarized in Table 3.

### Preparation Example 2

Semiconductor nanoparticles were prepared in the same manner as in Preparation Example 1, except that phenylethylzinc bromide (PEZB) having the following structure was used as an organic zinc halide instead of 4-methylbenzylzinc chloride.

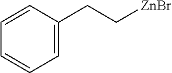

For the obtained semiconductor nanoparticles, photoluminescence spectroscopic analysis and TGA analysis were performed, and the results were summarized in Table 1 and Table 2.

For the obtained semiconductor nanoparticles, ICP-AES analysis was performed, and the results were summarized in Table 3.

### Preparation Example 3

Semiconductor nanoparticles were prepared in the same manner as in Preparation Example 1, except that 2-ethylhexylzinc bromide (EHZBr) having the following structure was used as an organic zinc halide instead of 4-methylbenzylzinc chloride.

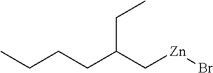

For the obtained semiconductor nanoparticles, photoluminescence spectroscopic analysis and TGA analysis were performed, and the results were summarized in Table 1 and Table 2.

### Preparation Example 4

Semiconductor nanoparticles were prepared in the same manner as in Preparation Example 1, except that 4-fluorobenzylzinc chloride (4FBZC) having the following structure was used as an organic zinc halide instead of 4-methylbenzylzinc chloride.

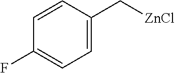

For the obtained semiconductor nanoparticles, photoluminescence spectroscopic analysis and TGA analysis were performed, and the results were summarized in Table 1 and Table 2.

For the obtained semiconductor nanoparticles, ICP-AES analysis was performed, and the results were summarized in Table 3.

### Preparation Example 5

Semiconductor nanoparticles were prepared in the same manner as in Preparation Example 1, except that 4-cyanobenzylzinc bromide (CNBZB) having the following structure was used as an organic zinc halide instead of 4-methylbenzylzinc chloride.

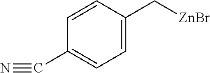

For the obtained semiconductor nanoparticles, photoluminescence spectroscopic analysis and TGA analysis were performed, and the results were summarized in Table 1 and Table 2.

For the obtained semiconductor nanoparticles, ICP-AES analysis was performed, and the results were summarized in Table 3.

### Preparation Example 6

Semiconductor nanoparticles were prepared in the same manner as in Preparation Example 1, except that dec-9-enylzinc bromide (DEZB) having the following structure was used as an organic zinc halide instead of 4-methylbenzylzinc chloride.

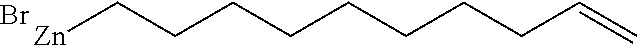

### Preparation Example 7

Semiconductor nanoparticles were prepared in the same manner as in Preparation Example 1, except that 4-n-hexylphenylzinc bromide (4HPZB) having the following structure was used as an organic zinc halide instead of 4-methylbenzylzinc chloride.

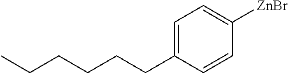

### Preparation Example 8

Semiconductor nanoparticles were prepared in the same manner as in Preparation Example 1, except that cinnamylzinc bromide (CNZB) having the following structure was used as an organic zinc halide instead of 4-methylbenzylzinc chloride.

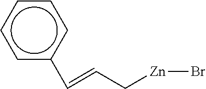

### Comparative Preparation Example 1

Semiconductor nanoparticles were prepared in the same manner as in Preparation Example 1, except that ZnCl₂ was used instead of 4-methylbenzylzinc chloride.

For the obtained semiconductor nanoparticles, photoluminescence spectroscopic analysis and TGA analysis were performed, and the results are summarized in Table 1 and Table 2.

For the obtained semiconductor nanoparticles, ICP-AES analysis was performed, and the results are summarized in Table 3.

### Comparative Preparation Example 2

Semiconductor nanoparticles were prepared in the same manner as in Preparation Example 1, except that a post-treatment temperature was maintained at greater than or equal to about 50° C. to less than or equal to about 100° C.

TABLE 1

| | | PWL | FWHM | |
|---|---|---|---|---|
| | Zinc halide | (nm) | (nm) | QY (%) |
| Preparation | 4-methylbenzyl zinc | 463 | 43 | 91 |
| Example 1 | chloride | | | |
| Preparation | Phenylethyl zinc | 463 | 43 | 90 |
| Example 2 | bromide | | | |
| Preparation | 2-ethylhexyl zinc | 462 | 43 | 88 |
| Example 3 | bromide | | | |
| Preparation | 4-Fluorobenzyl zinc | 464 | 42 | 88 |
| Example 4 | chloride | | | |
| Preparation | 4-Cyanobenzyl zinc | 464 | 44 | 71 |
| Example 5 | bromide | | | |
| Comp. | ZnCl₂ | 460 | 41 | 90 |
| Preparation | | | | |
| Example 1 | | | | |

PWL: Emission Peak Wavelength
FWHM: Full Width at Half Maximum
QY: Quantum Yield

TABLE 2

| | | | Residue amount |
|---|---|---|---|
| | Organic content ^{(note 1)} | | (at 600° C.)(wt %) |
| Prep. Example 1 | 9.6 | wt % | 89.35 |
| Prep. Example 2 | 9.9 | wt % | 89.1 |
| Prep. Example 3 | 9.9 | wt % | 89.76 |
| Prep. Example 4 | 9.4 | wt % | 89.1 |
| Prep. Example 5 | 9.3 | wt % | 89.6 |
| Comp. Prep. Example 1 | 10.7 | wt % | 88 |

^{(Note 1)}:
The organic content is a mass loss in thermogravimetric analysis in a temperature range of 200° C. to 550° C.

From the results of Table 2, it was confirmed that the semiconductor nanoparticles of Preparation Examples 1 to 5 exhibited an organic content of less than about 10 wt %.

TABLE 3

| | (S + Se)/Zn | Te/Se | S/Se | Al/Zn | Al/Se | Al/S |
|---|---|---|---|---|---|---|
| Prep. Example 1 | 0.8593 | 0.0066 | 0.5200 | 0.0131 | 0.0233 | 0.0446 |
| Prep. Example 2 | 0.8396 | 0.0072 | 0.6200 | 0.0205 | 0.0396 | 0.0640 |
| Prep. Example 4 | 0.8553 | 0.0072 | 0.6300 | 0.0150 | 0.0287 | 0.0455 |
| Prep. Example 5 | 0.8677 | 0.0072 | 0.6500 | 0.0189 | 0.0358 | 0.0556 |
| Comp. Prep. Example 1 | 0.9010 | 0.0065 | 0.054 | 0 | 0 | 0 |

From the results of Table 3, it can be confirmed that the semiconductor nanoparticles of the Preparation Examples include aluminum in an amount within the range defined herein.

### Experimental Example 1

### (1) Infrared Spectroscopic Analysis

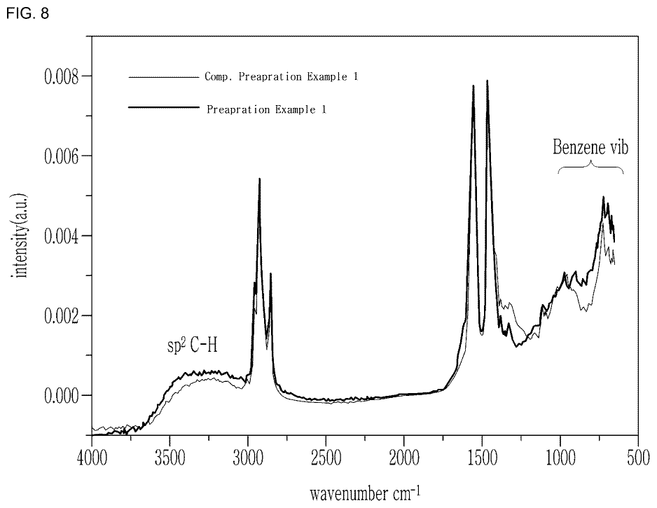

Infrared spectroscopic analysis was performed on the semiconductor nanoparticles prepared in Preparation Example 1 and the semiconductor nanoparticles of Preparation Comparative Example 1, and the results are shown in FIG. 8. From the results of FIG. 8, it can be confirmed that the semiconductor nanoparticles synthesized in Preparation Example 1 exhibited a peak due to benzene vibration in a wavenumber range of greater than or equal to about 500 cm⁻¹ to less than or equal to about 1000 cm⁻¹.

### (2) Gas Chromatography Analysis

GC analysis was performed on the obtained semiconductor nanoparticles. A first peak assigned to an ethylhexanoate moiety at a retention time of approximately 6 minutes to 7 minutes and a second peak assigned to an oleate moiety at a retention time of approximately 13 minutes to 13.5 minutes were respectively confirmed. An area percentage of the second peak relative to the first peak (100%) is summarized in Table 4.

TABLE 4

| | Second ligand |
|---|---|
| | (peak area percentage) |
| Comp. Prep. Example 1 | 38.81% |
| Prep. Example 1 | 34.11% |
| Prep. Example 2 | 25.23% |
| Prep. Example 3 | 34.20% |
| Prep. Example 4 | 64.50% |
| Prep. Example 5 | 45.95% |

### Experimental Example 2: Photostability in a CHB Ink Solution

An ink was prepared by dispersing the semiconductor nanoparticles prepared in Preparation Example 1, the semiconductor nanoparticles prepared in Preparation Example 2, the semiconductor nanoparticles prepared in Preparation Example 4, and the semiconductor nanoparticles of Preparation Comparative Example 1 in cyclohexylbenzene. The prepared ink was stored at room temperature for 3 days, and then emission efficiency was measured. The results are summarized in Table 5.

TABLE 5

| | QY retention |
|---|---|
| | after 3 days |
| Prep. Example 1 | 26% |
| Prep. Example 2 | 24% |
| Prep. Example 4 | 33% |
| Comp. Prep. Example 1 | 20% |

QY retention after 3 days = [quantum yield of a dispersion after 3 days had elapsed/an initial quantum yield of the dispersion] × 100 (%).

From the results of Table 5, it can be confirmed that the semiconductor nanoparticles of the Preparation Examples exhibited remarkably improved stability (e.g., storage stability) as compared with the semiconductor nanoparticles prepared in accordance with Comparative Preparation Example.

### DEVICE EXAMPLE

### Example 1

Using the semiconductor nanoparticles prepared in Preparation Example 1, an electroluminescent device with the structure ITO/PEDOT:PSS (300 Å)/TFB (250 Å)/semiconductor nanoparticle emitting layer (360 Å)/ZnMgO (240 Å)/AI was fabricated, and the electroluminescent properties were measured as follows:

On a glass substrate with an ITO electrode (first electrode) deposited, PEDOT:PSS and TFB layers were formed as a hole injection layer and a hole transport layer by spin coating. The semiconductor nanoparticle solution prepared in Preparation Example 1 was spin-coated on the formed TFB layer (25 nm) to form the light emitting layer. On the light emitting layer, a zinc magnesium oxide nanoparticle layer was formed as the electron auxiliary layer, and then an Al electrode was deposited to fabricate the electroluminescent device.

For the fabricated device, electroluminescent properties and lifetime were measured, and the results are summarized in Table 6.

### Example 2

Except for using the semiconductor nanoparticles prepared in Preparation Example 2, the electroluminescent device was fabricated in the same manner as in Example 1.

For the fabricated device, electroluminescent properties and lifetime were measured, and the results were summarized in Table 6.

### Example 3

Except for using the semiconductor nanoparticles prepared in Preparation Example 3, the electroluminescent device was fabricated in the same manner as in Example 1.

For the fabricated device, electroluminescent properties and lifetime were measured, and the results were summarized in Table 6.

### Example 4

Except for using the semiconductor nanoparticles prepared in Preparation Example 4, the electroluminescent device was fabricated in the same manner as in Example 1.

For the fabricated device, electroluminescent properties and lifetime were measured, and the results were summarized in Table 6.

### Example 5

Except for using the semiconductor nanoparticles prepared in Preparation Example 5, the electroluminescent device was fabricated in the same manner as in Example 1.

For the fabricated device, electroluminescent properties and lifetime were measured, and the results were summarized in Table 6.

### Example 6

An electroluminescent device was fabricated in the same manner as in Example 1, except that the semiconductor nanoparticles prepared in Preparation Example 6 were used.

For the fabricated device, electroluminescent properties and lifetime were measured, and the results were summarized in Table 6.

### Example 7

An electroluminescent device was fabricated in the same manner as in Example 1, except that the semiconductor nanoparticles prepared in Preparation Example 7 were used.

For the fabricated device, electroluminescent properties and lifetime were measured, and the results were summarized in Table 6.

### Example 8

An electroluminescent device was fabricated in the same manner as in Example 1, except that the semiconductor nanoparticles prepared in Preparation Example 8 were used.

For the fabricated device, electroluminescent properties and lifetime were measured, and the results were summarized in Table 6.

### Comparative Example 1

An electroluminescent device was fabricated in the same manner as in Example 1, except that the semiconductor nanoparticles prepared in Comparative Preparation Example 1 were used.

For the fabricated device, electroluminescent properties and lifetime were measured, and the results were summarized in Table 6.

### Comparative Example 2

An electroluminescent device was fabricated in the same manner as in Example 1, except that the semiconductor nanoparticles prepared in Comparative Preparation Example 2 were used.

For the fabricated device, electroluminescent properties and lifetime were measured, and the results are summarized in Table 6.

TABLE 6

| | Relative EQE | Relative lifetime |
|---|---|---|
| Example 1 | 102% | 363% |
| Example 2 | 101% | 392% |
| Example 3 | 100% | 183% |
| Example 4 | about 100% | 130% |
| Example 5 | 108% | 121% |
| Example 6 | 110% | 156% |
| Example 7 | 112% | 156% |
| Example 8 | about 100% | 156% |
| Comp. Example 1 | 100% | 100% |
| Comp. Example 2 | 45% | 25% |

Relative EQE: [Maximum EQE of a given device/Maximum EQE of the device of Comparative Example 1] × 100 (%).
Relative lifetime: [T90 (hours) of a given device/T90 (hours) of the device of Comparative Example 1] × 100 (%).

From the results of Table 6, it can be confirmed that an electroluminescent device including the semiconductor nanoparticles of the Preparation Examples in an emission layer exhibit significantly improved electroluminescent properties or an extended lifetime, as compared with the device of Comparative Example 1.

### Experimental Example 3: Fabrication of an HOD Device

An HOD was fabricated in the same manner as in Example 4, Example 5, and Comparative Example 1, except that a hole auxiliary layer formed using a small-molecule organic hole transport material (e.g., an HAT-based material such as HAT-CN) was used instead of an electron transport layer, and a thickness of a semiconductor nanoparticle-containing emission layer was 40 nm.

An experiment of measuring current while applying a voltage to the fabricated HOD was conducted. The results for the HOD are summarized in Table 7.

TABLE 7

| | Semiconductor | Relative current |
|---|---|---|
| Device | nanoparticle | density (8 volts) |
| Comp. Device 1 | Comp. Prep. Example 1 | 1 |
| Device 1 | Prep. Example 4 | 2.45 |
| Device 2 | Prep. Example 5 | 2.45 |

Relative current density = current density of a corresponding device/current density of the device of Comparative Example 1.

From the results of Table 7, it can be confirmed that a device including the semiconductor nanoparticles of the Preparation Examples exhibit a relative current density (that is, hole transport capability) that is significantly increased as compared with a device including the semiconductor nanoparticles of the Comparative Preparation Examples.

An embodiment provides a method of preparing a semiconductor nanoparticle, the method including; providing a reaction medium including an organic solvent; adding a zinc precursor, a sulfur precursor, and a particle including a first semiconductor nanocrystal to the reaction medium; heating the reaction medium to a reaction temperature to provide a semiconductor nanoparticle; and adding a metal halide to the reaction medium including the semiconductor nanoparticle. The metal halide may include an organozinc halide and an aluminum halide. The addition of the metal halide may be performed at a temperature of greater than or equal to about 100° C. and less than or equal to about 280° C. (e.g., a first temperature).

The reaction medium may further include an organic ligand. The first semiconductor nanocrystal may include zinc, selenium, and optionally tellurium (including a first zinc chalcogenide).

The particle may further include a second semiconductor nanocrystal. The second semiconductor nanocrystal may include zinc and selenium (including a second zinc chalcogenide).

The particle may not include an indium phosphide or a Group III-V compound.

The zinc precursor may include a first zinc precursor including a first organic ligand and zinc, e.g., a zinc ion, and a second zinc precursor including a second organic ligand and zinc, e.g., a zinc ion, the second organic ligand different from the first organic ligand. The first organic ligand and the second organic ligand may include a carboxylate group.

The first organic ligand may have a molecular weight of greater than or equal to about 90 g/mol, or greater than or equal to about 100 g/mol and less than or equal to about 260 g/mol, less than or equal to about 230 g/mol, less than or equal to about 210 g/mol, less than or equal to about 205 g/mol, less than or equal to about 200 g/mol, or less than or equal to about 170 g/mol.

The second organic ligand may have a molecular weight of greater than about 200 g/mol, greater than or equal to about 225 g/mol, greater than or equal to about 250 g/mol, or greater than or equal to about 280 g/mol, and less than or equal to about 500 g/mol, or less than or equal to about 250 g/mol.

The first organic ligand may include a substituted or unsubstituted C6 to C12 aromatic hydrocarbon group, a substituted or unsubstituted C3 to C12, C5 to C9, C4 to C8, or C6 to C7 linear or branched aliphatic hydrocarbon group (e.g., an alkyl group, an alkenyl group, or an alkynyl group), or a combination thereof.

The first organic ligand may include a hexanoate moiety substituted with a C1-C3 alkyl group, a butanoate moiety substituted with a C1-C3 alkyl group, a pentanoate moiety substituted with a C1-C3 alkyl group, an octanoate moiety substituted with a C1-C4 alkyl group, or a combination thereof.

The first organic ligand may include a hexanoate group, a methylbutanoate group, a butyloctanoate group, or a combination thereof.

The second organic ligand may include a linear or branched aliphatic hydrocarbon group of C13-C25, C14-C23, C15-C22, C16-C21, C17-C20, or C18-C19 (e.g., an alkyl group, an alkenyl group, or an alkynyl group). The second organic ligand may include an aliphatic hydrocarbon group having 17 or more carbon atoms.

The second organic ligand may include, for example, one or more carbon-carbon double bonds, or two or more carbon-carbon double bonds, in the aliphatic hydrocarbon group chain.

The first organic ligand may include a branched alkyl group, and the second organic ligand may include a linear alkenyl group.

In an embodiment, the metal halide may be added at a first temperature, and the first temperature may be greater than or equal to 100° C. and less than or equal to 280° C.

A difference between the first temperature and the reaction temperature may be greater than or equal to about 10° C. and less than or equal to about 100° C.

The adding and mixing of the metal halide may occur after the first zinc precursor and/or the second zinc precursor contacts the sulfur precursor.

The organozinc halide may include an aromatic moiety of C6 to C30.

The organozinc halide may include a compound represented by Chemical formula 1:

R—Zn—X Chemical formula 1
wherein R is a substituted or unsubstituted C3 to C50 (or C5 to C20) hydrocarbon group (e.g., an aliphatic, alicyclic, or aromatic hydrocarbon group), and X is a halogen (e.g., F, Cl, Br, or I).

In Chemical formula 1, R may be substituted with a halogen, a C1 to C10 hydrocarbon group (e.g., an aliphatic hydrocarbon group such as an alkyl group, an alkenyl group, or an alkynyl group), a cyanide group, or a combination thereof.

The organozinc halide may include a substituted or unsubstituted benzylzinc halide (e.g., a chloride or a bromide), a substituted or unsubstituted phenylalkylzinc halide (e.g., a chloride or a bromide), a substituted or unsubstituted phenylalkenylzinc halide (e.g., a chloride or a bromide), a substituted or unsubstituted (e.g., linear or branched) alkylzinc halide (e.g., a chloride or a bromide), or a combination thereof.

The aluminum halide may include aluminum chloride, aluminum bromide, aluminum iodide, or a combination thereof.

In an embodiment of the method, an amount of the metal halide may be greater than or equal to about 0.01 moles, greater than or equal to about 0.05 moles, greater than or equal to about 0.1 moles, greater than or equal to about 0.15 moles, greater than or equal to about 0.5 moles, greater than or equal to about 1 mole, greater than or equal to about 5 moles, greater than or equal to about 10 moles, greater than or equal to about 50 moles, or greater than or equal to about 100 moles, per 1 mole of the zinc precursor.

In an embodiment of the method, the amount of the metal halide may be less than or equal to about 100 moles, less than or equal to about 70 moles, less than or equal to about 40 moles, less than or equal to about 10 moles, less than or equal to about 3 moles, less than or equal to about 1 mole, less than or equal to about 0.4 moles, less than or equal to about 0.2 moles, less than or equal to about 0.06 moles, or less than or equal to about 0.03 moles, per 1 mole of the zinc precursor.

An amount of the aluminum halide may be greater than or equal to about 0.1 moles, or greater than or equal to about 0.5 moles, and less than or equal to about 20 moles, or less than or equal to about 15 moles, per 1 mole of the organozinc halide.

In an embodiment, the semiconductor nanoparticle includes zinc, selenium, and sulfur, wherein the semiconductor nanoparticle includes a first semiconductor nanocrystal; and a semiconductor nanocrystal shell disposed on the first semiconductor nanocrystal and including zinc and sulfur,
the first semiconductor nanocrystal includes zinc and selenium, the semiconductor nanoparticle does not include cadmium, and the semiconductor nanoparticle further includes aluminum. In the semiconductor nanoparticle, a mole ratio of aluminum to zinc is greater than or equal to about 0.001, or greater than or equal to about 0.01 and less than or equal to about 0.1, or less than or equal to about 0.05.

The semiconductor nanoparticle may further include an organic ligand (e.g., an organic ligand system including a plurality of organic ligands).

In the semiconductor nanoparticle, as confirmed by thermogravimetric analysis, an organic content (e.g., corresponding to a mass loss in a temperature range of greater than or equal to about 200° C. to less than or equal to about 550° C.) may be greater than or equal to about 7 wt % and less than or equal to about 10.5 wt %, based on a total weight of the semiconductor nanoparticle. The organic content may be greater than or equal to about 7.5 wt %, or greater than or equal to about 8 wt % and less than or equal to about 10 wt %, or less than or equal to about 9.7 wt %, based on the total weight of the semiconductor nanoparticle.

In the semiconductor nanoparticle, a mole ratio of aluminum to zinc may be greater than or equal to about 0.005, or greater than or equal to about 0.012, and less than or equal to about 0.04.

In the semiconductor nanoparticle, a mole ratio of aluminum to selenium may be greater than or equal to about 0.001, or greater than or equal to about 0.005 and less than or equal to about 0.074, or less than or equal to about 0.07.

In the semiconductor nanoparticle, a mole ratio of aluminum to sulfur may be greater than or equal to about 0.001, or greater than or equal to about 0.01 and less than or equal to about 0.1.

The semiconductor nanoparticle may include a first organic ligand having a carboxylate moiety; and a second organic ligand having a carboxylate moiety and different from the first organic ligand. In gas chromatography (GC) analysis, the semiconductor nanoparticle may exhibit a first peak assigned to the first organic ligand and a second peak assigned to the second organic ligand. An area percentage of the first peak relative to the second peak may be greater than or equal to about 1%, greater than or equal to about 5%, or greater than or equal to about 10%, and less than or equal to about 300%, less than or equal to about 150%, or less than or equal to about 100%.

The second organic ligand may have a larger molecular weight than the first organic ligand. The second organic ligand may have a number of carbon atoms of greater than or equal to about 15, greater than or equal to about 16, or greater than or equal to about 17.

The semiconductor nanoparticle or the semiconductor nanocrystal shell may include zinc selenide, zinc selenide telluride, zinc selenide sulfide, zinc sulfide, or a combination thereof.

The semiconductor nanocrystal shell may include a first shell layer; and a second shell layer disposed on the first shell layer. The first shell layer may include zinc selenide, zinc selenide telluride, zinc selenide sulfide, or a combination thereof. The second shell layer may include zinc selenide sulfide, zinc sulfide, or a combination thereof.

The semiconductor nanoparticle may not include lead. The semiconductor nanoparticle may not include copper. The semiconductor nanoparticle or the first semiconductor nanocrystal may not include indium phosphide.

The semiconductor nanoparticle may be configured to emit a first light.

The first light may exhibit a blue-light spectrum. The first light may have a full width at half maximum of a peak emission wavelength of greater than or equal to about 1 nm and less than or equal to about 55 nm. A peak emission wavelength of the first light or the blue light may be greater than or equal to about 440 nm and less than or equal to about 480 nm.

The semiconductor nanoparticle may be configured to emit blue light. The blue light may have a peak emission wavelength of greater than or equal to about 440 nm, greater than or equal to about 450 nm, greater than or equal to about 460 nm, or greater than or equal to about 465 nm, and less than or equal to about 480 nm, or less than or equal to about 475 nm.

In an embodiment, a peak emission wavelength of the first light or the semiconductor nanoparticle may be greater than or equal to about 500 nm, or greater than or equal to about 510 nm and less than or equal to about 580 nm, or less than or equal to about 540 nm.

In an embodiment, a peak emission wavelength of the first light or the semiconductor nanoparticle may be greater than or equal to about 600 nm, or greater than or equal to about 610 nm and less than or equal to about 680 nm, or less than or equal to about 635 nm.

In thermogravimetric analysis, the semiconductor nanoparticle may have a residue content at a temperature of greater than or equal to about 550° C. of greater than or equal to about 82%, greater than or equal to about 87%, greater than or equal to about 88%, or greater than or equal to about 89% and less than or equal to about 99%, less than or equal to about 93%, or less than or equal to about 91%, based on a total weight of the semiconductor nanoparticle.

The semiconductor nanoparticle may be dispersed in a liquid vehicle including an organic solvent having a boiling point of greater than or equal to about 120° C. (or greater than or equal to about 180° C.) to form a dispersion, and in dynamic light scattering analysis of the dispersion, may exhibit a DLS particle diameter of less than about 300 nm. The DLS particle diameter may be less than or equal to about 200 nm, less than or equal to about 100 nm, or less than or equal to about 50 nm. The DLS particle diameter may be greater than or equal to about 10 nm, or greater than or equal to about 15 nm.

In the dispersion state, when left at room temperature for 3 days, the semiconductor nanoparticle may exhibit a quantum efficiency retention rate of greater than or equal to about 20%, greater than or equal to about 23%, or greater than or equal to about 25%.

In an embodiment, an electroluminescent device includes a first electrode and a second electrode that are spaced apart from each other, and an emission layer disposed between the first electrode and the second electrode, and the emission layer includes the aforementioned semiconductor nanoparticle.

Details of the semiconductor nanoparticle are as described herein.

The emission layer may be configured to emit first light by application of a voltage.

Details of the first light are as described herein. In an embodiment, a peak emission wavelength of the first light or the semiconductor nanoparticle (electroluminescence or photoluminescence) may be greater than or equal to about 440 nm, or greater than or equal to about 460 nm and less than or equal to about 480 nm, or less than or equal to about 470 nm.

In an embodiment, a peak emission wavelength of the first light or the semiconductor nanoparticle may be greater than or equal to about 500 nm, or greater than or equal to about 510 nm and less than or equal to about 580 nm, or less than or equal to about 540 nm. In an embodiment, a peak emission wavelength of the first light or the semiconductor nanoparticle may be greater than or equal to about 600 nm, or greater than or equal to about 610 nm and less than or equal to about 680 nm, or less than or equal to about 635 nm.

The first electrode may be an anode, and the second electrode may be a cathode.

The electroluminescent device may further include a charge auxiliary layer between the emission layer and the first electrode, between the emission layer and the second electrode, or both.

The electroluminescent device may further include a hole auxiliary layer between the emission layer and the first electrode. The electroluminescent device may further include an electron auxiliary layer between the emission layer and the second electrode.

The charge auxiliary layer may include a hole auxiliary layer including an organic compound, an electron auxiliary layer including metal oxide fine particles, or a combination thereof.

The electroluminescent device may have a maximum luminance of greater than or equal to about 10,000 candela per square meter (cd/m²), greater than or equal to about 30,000 cd/m², or greater than or equal to about 50,000 cd/m².

The electroluminescent device may have a maximum external quantum efficiency of greater than or equal to about 9%, greater than or equal to about 10%, or greater than or equal to about 11%.

An embodiment relates to an electronic device or a display panel/device including the electroluminescent device.

The display device or the electronic device may include a virtual reality display device, an augmented reality display device, a portable terminal device, a monitor, a notebook computer, a television, a signboard, a camera, or an automotive electronic component.

While this disclosure has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

What is claimed is:

1. A method of preparing a semiconductor nanoparticle, the method comprising:
providing a reaction medium including an organic solvent;
adding a zinc precursor, a sulfur precursor, and a particle including a first semiconductor nanocrystal to the reaction medium,
heating the reaction medium to a reaction temperature to provide a semiconductor nanoparticle; and
adding a metal halide to the reaction medium including the semiconductor nanoparticle,
wherein the metal halide comprises an organozinc halide and an aluminum halide.

2. The method of claim 1, wherein the particle does not include an indium phosphide.

3. The method of claim 1, wherein the first semiconductor nanocrystal comprises zinc, selenium, and optionally tellurium, and
the particle further comprises a second semiconductor nanocrystal,
wherein the second semiconductor nanocrystal comprises zinc and selenium.

4. The method of claim 1, wherein the zinc precursor comprises a first zinc precursor including a first organic ligand and zinc, and a second zinc precursor including a second organic ligand and zinc, the second organic ligand different from the first organic ligand.

5. The method of claim 4, wherein the first organic ligand comprises a hexanoate moiety substituted with a C1-C3 alkyl group, a butanoate moiety substituted with a C1-C3 alkyl group, a pentanoate moiety substituted with a C1-C3 alkyl group, an octanoate moiety substituted with a C1-C4 alkyl group, or a combination thereof, and
the second organic ligand comprises an aliphatic hydrocarbon group of C13-C25.

6. The method of claim 1, wherein the adding of the metal halide is conducted at a first temperature, and
the first temperature is greater than or equal to about 100° C. and less than or equal to about 280° C.

7. The method of claim 1, wherein the organozinc halide comprises a compound represented by Chemical formula 1:
R—Zn—X Chemical formula 1
wherein R is a substituted or unsubstituted C3 to C50 hydrocarbon group, and X is a halogen.

8. The method of claim 1, wherein the organozinc halide comprises a substituted or unsubstituted benzylzinc halide, a substituted or unsubstituted phenylalkylzinc halide, a substituted or unsubstituted phenylalkenylzinc halide, a substituted or unsubstituted alkylzinc halide, or a combination thereof, and
the aluminum halide comprises aluminum chloride, aluminum bromide, aluminum iodide, or a combination thereof.

9. The method of claim 1, wherein an amount of the metal halide is greater than or equal to 0.01 moles and less than or equal to about 100 moles per 1 mole of the zinc precursor, and
an amount of the aluminum halide is greater than or equal to about 0.01 moles and less than or equal to about 100 moles per 1 mole of the organozinc halide.

10. A semiconductor nanoparticle including zinc, selenium, sulfur, and aluminum, wherein the semiconductor nanoparticle comprises:
a first semiconductor nanocrystal; and a semiconductor nanocrystal shell disposed on the first semiconductor nanocrystal and comprising zinc and sulfur;
wherein the first semiconductor nanocrystal comprises zinc and selenium,
the semiconductor nanoparticle does not comprise cadmium, and
in the semiconductor nanoparticle, a mole ratio of aluminum to zinc (Al:Zn) is greater than or equal to about 0.001:1 and less than or equal to about 0.1:1.

11. The semiconductor nanoparticle of claim 10, further comprising an organic ligand, wherein an organic content of the semiconductor nanoparticle is greater than or equal to about 7 wt % and less than or equal to about 10.5 wt %, based on a total weight of the semiconductor nanoparticle as determined by thermogravimetric analysis.

12. The semiconductor nanoparticle of claim 10, further comprising an organic ligand, wherein a residue content at 600° C. is greater than or equal to about 87 wt % as determined by thermogravimetric analysis.

13. The semiconductor nanoparticle of claim 10, wherein, in the semiconductor nanoparticle, a mole ratio of aluminum to selenium (Al:Se) is greater than or equal to about 0.001:1 and less than or equal to about 0.07:1.

14. The semiconductor nanoparticle of claim 10, wherein, in the semiconductor nanoparticle, a mole ratio of aluminum to sulfur (Al:S) is greater than or equal to about 0.001:1 and less than or equal to about 0.1:1.

15. The semiconductor nanoparticle of claim 10, further comprising: a first organic ligand having a carboxylate moiety; and a second organic ligand having a carboxylate moiety, the second organic ligand different from the first organic ligand,
wherein the first organic ligand comprises an aliphatic hydrocarbon group of C3 to C12, and
the second organic ligand comprises an aliphatic hydrocarbon group of C13-C25.

16. The semiconductor nanoparticle of claim 10, wherein the semiconductor nanoparticle does not comprise indium phosphide.

17. The semiconductor nanoparticle of claim 10, wherein the semiconductor nanoparticle is configured to emit blue light, and the blue light has a peak emission wavelength of greater than or equal to about 440 nm and less than or equal to about 480 nm.

18. An ink composition comprising the semiconductor nanoparticle of claim 10 and a liquid vehicle,
wherein the liquid vehicle includes an organic solvent having a boiling point of greater than or equal to about 180° C. and less than or equal to about 380° C.

19. An electroluminescent device comprising a first electrode and a second electrode that are spaced apart from each other, and an emission layer disposed between the first electrode and the second electrode, wherein the emission layer comprises a semiconductor nanoparticle,
wherein the semiconductor nanoparticle comprises: a first semiconductor nanocrystal; and a semiconductor nanocrystal shell comprising zinc and sulfur, and disposed on the first semiconductor nanocrystal,
wherein the first semiconductor nanocrystal comprises zinc, selenium, and optionally tellurium,
the semiconductor nanoparticle does not comprise cadmium, and
a mole ratio of aluminum to zinc (Al:Zn) is greater than or equal to about 0.001:1 and less than or equal to about 0.1:1.

20. The electroluminescent device of claim 19,
wherein the mole ratio of aluminum to zinc (Al:Zn) is greater than or equal to about 0.01:1, and
wherein, in the semiconductor nanoparticle,
a mole ratio of aluminum to selenium (Al:Se) is greater than or equal to about 0.001:1 and less than or equal to about 0.07:1, and
a mole ratio of aluminum to sulfur (Al:S) is greater than or equal to about 0.001:1, and less than or equal to about 0.1:1; and
wherein the first semiconductor nanocrystal does not comprise an indium phosphide.
